(19) United States
(12) Patent Application Publication
(10) Pub. No.: US 2023/0077781 A1
(43) Pub. Date: Mar. 16, 2023

(54) ELECTRIC POWER INDUSTRY STRUCTURE MONITOR

(71) Applicant: UBICQUIA, INC., Fort Lauderdale, FL (US)

(72) Inventors: Bradford Brian Hutson, Vero Beach, FL (US); Jeffrey T. Root, Howell, MI (US); Yevgeny Frenkel, Titusville, FL (US); William R. Drouin, Melbourne, FL (US); Tyler Edison Cone, Melbourne, FL (US)

(21) Appl. No.: 17/796,242

(22) PCT Filed: Jan. 28, 2021
(86) PCT No.: PCT/US2021/015515

§ 371 Date: Jul. 28, 2022

Related U.S. Application Data
(60) Provisional application No. 62/966,919, filed on Jan. 28, 2020.

(51) Int. Cl. G01R 31/62; G01J 5/00; G01P 15/18; H02J 50/00

(52) U.S. Cl. CPC G01R 31/62; G01J 5/00; G01P 15/18; H02J 50/001; G01J 2005/0077

(57) ABSTRACT

In at least some cases, an embodiment of an electric power industry structure monitor is arranged as a distribution transformer monitor. In at least some cases, an electric power industry structure monitor is arranged as a tilt sensor monitor. In at least some cases an electric power industry structure monitor is arranged as a high-voltage tower (e.g., power pole) monitor. In some cases, the electric power industry structure monitor includes a housing arranged for positioning on an electric power industry structure, and a sensor arranged in the housing. The sensor is positioned to generate digital data associated with at least one environmental condition that exists proximal to the electric power industry structure monitor. The monitor also includes a processing circuit arranged to determine from the generated digital data that the at least one environmental condition has crossed a threshold.

This application claims the priority benefit of U.S. Provisional Patent Application No. 62/966,919, filed Jan. 28, 2020, which application is hereby incorporated by reference in its entirety.

This application is associated with U.S. Provisional Application No. 62/875,411 filed Jul. 17, 2019, and Patent Cooperation Treaty Application PCT/US2020/042653, filed Jul. 17, 2020, which applications are hereby incorporated by reference in its entirety.

### BACKGROUND

### Technical Field

The present disclosure generally relates to a monitor arranged for mounting on a power pole type of structure. More particularly, but not exclusively, the present disclosure relates to an electronic device arranged to monitor one or more conditions that may occur on a power pole.

### Description of the Related Art

After a centralized power plant generates electricity, the electricity must be delivered to the end-user. Power delivery from a centralized power plant typically occurs in three steps. First, the generated power is transmitted to a substation; second, the power is conditioned at the substation; and third, the conditioned power is distributed to the location where it will be consumed.

The electric power grid, as it is conventionally known, includes the power generation means, the transmission lines, the substations, and all the supporting structures necessary to the pass and ultimately deliver the generated power. As it is also known, failures in any part of the electric grid may put lives and property in danger. Storms, wildfires, natural wear and tear of equipment, defective equipment, vandalism, and other such events all contribute toward failures that may occur in the electric power grid.

FIG. 1A is an electric power grid 10a. The electric power grid 10a includes any suitable number of means of generating electricity. For example, the electric power grid 10a includes a centralized power generation plant 12a, which uses any one or more of a wide variety of energy sources (e.g., coal, natural gas, nuclear elements and the like). Other means of generating electricity include hydroelectric power plants 12b, such as dams or wave energy facilities, wind generation plants 12c, waste-to-energy plants 12d, and solar power generation structures 12e.

Generated power is communicated from a source (e.g., a power generation means 12a-12e) to a destination via electrically conductive wires, which are generally referred to as power lines 14a, 14b. In some cases, high power lines 14a carry substantial amounts of power (e.g., high voltage, high current, or both high voltage and high current) over long power transmission distances (e.g., hundreds or thousands of feet) from a centralized power generation plant 12a, 12b, 12c to a substation 18. These high power lines 14a may be suspended above the earth by high power poles 16a. In other cases, distribution power lines 14b carry power from a substation 18 to an end point such as an industrial facility 20a, an office facility 20b, a dwelling 20c, or some other destination and point. These distribution power lines 14b may be suspended above the earth by distribution power poles 16b.

In many cases, high power lines 14a have a larger diameter, higher weight, and different composition of materials (e.g., electricity carrying elements, insulation, and the like) than distribution power lines 14b. In many cases, high power poles 16a are taller and mechanically stronger than distribution power poles 16b. Despite these differences, either or both high power lines 14a and distribution power lines 14b may be referred to in the present disclosure as power lines 14. Correspondingly, either or both high power poles 16a and distribution power poles 16b may be referred to in the present disclosure as power poles 16.

FIG. 1B is a portion 10b of the electric power grid 10a in more detail identified over a particular geographic area. For simplicity, a single utility's power grid is represented in FIG. 1b. It is recognized, however, that two or more public, private, or quasi-private power utility operators may have electric power grids that an adjacent, proximate, or partially overlapping the electric power grid of another entity.

The hexagonal shaped cells shown in FIG. 1 are a preferred representation of a “grid,” but it is understood that the actual shapes merely represent a power availability coverage pattern that depends on terrain, transmission and reception characteristics, access to desirable tower locations, population density, and the like.

Representations of power lines 14, which are along the lines of high power lines 14a and distribution power lines 14b of FIG. 1A, are included in the electric power grid 10a. Representations of power poles 16, which are along the lines of high power poles 16a and distribution power poles 16b, are also included in the electric power grid 10a of FIG. 1A. In at least some cases, the power poles 16 support electric lines that carry electricity measurable in the hundreds of thousands of volts. In at least some cases, the power poles 16, support electric lines that carry distribution power, which is also used to power streetlights, traffic signals, warning signals, and the like.

All of the subject matter discussed in the Background section is not necessarily prior art and should not be assumed to be prior art merely as a result of its discussion in the Background section. Along these lines, any recognition of problems in the prior art discussed in the Background section or associated with such subject matter should not be treated as prior art unless expressly stated to be prior art. Instead, the discussion of any subject matter in the Background section should be treated as part of the inventor's approach to the particular problem, which, in and of itself, may also be inventive.

### BRIEF SUMMARY

The following is a summary of the present disclosure to provide an introductory understanding of some features and context. This summary is not intended to identify key or critical elements of the present disclosure or to delineate the scope of the disclosure. This summary presents certain concepts of the present disclosure in a simplified form as a prelude to the more detailed description that is later presented.

The device, method, and system embodiments described in this disclosure (i.e., the teachings of this disclosure) enable deployment of particular electric power industry structure monitors. In many cases, the monitors generate, aggregate, and analyze first order data to produce interim data, and the monitors further aggregate and analyze the interim data to produce second order data. Aggregation and analysis may be performed locally or remotely. As one example, an electric power industry structure monitor generates video data, such as infrared video data and aggregates and analyzes the video data to produce temperature data associated with a cooling medium such as oil in a distribution transformer vessel. As another example, an electric power industry structure monitor generates audio data and aggregates and analyzes the audio data to produce signature data associated with a temperature of a cooling medium in a distribution transformer. In still other cases, an electric power industry structure monitor generates data representing a three-dimensional orientation such as tilt of a power pole. Many other electric power industry monitor teachings are also contemplated and described in the present disclosure.

An embodiment of an electric power industry structure monitor, includes a housing arranged for positioning on an electric power industry structure; a sensor arranged in the housing, the sensor positioned to generate digital data associated with at least one environmental condition that exists proximal to the electric power industry structure monitor; and a processing circuit arranged to determine from the generated digital data that the at least one environmental condition has crossed a threshold.

In some cases, the electric power industry structure is a distribution transformer arranged to monitor pressure within a vessel that contains the distribution transformer. In some cases, the housing is formed from an ultraviolet (UV) radiation resistant material having an operating range that includes 140 degrees Fahrenheit. In these or other cases, the housing includes a coating arranged as a protective barrier to protect against animal damage, insect damage, and vandalism. Sometimes in the electric power industry structure monitor, the sensor includes at least one infrared (IR) image sensor having an IR field of view cone arranged to be aimed at a portion of a wall of the distribution transformer vessel when the electric power industry structure monitor is deployed, the IR field of view cone formed to window a determined level of non-conductive medium contained in the distribution transformer vessel. And sometimes, the sensor is an infrared (IR) image sensor deployed to detect a determined level of non-conductive medium in the distribution transformer vessel based on a difference in temperature of the non-conductive medium and temperature of a void in the distribution transformer vessel above the non-conductive medium. In at least some cases, the sensor includes a plurality micro electromechanical systems (MEMS) microphones arranged to capture data in a respective plurality of data collection areas, a first data collection area representing a first volume of the distribution transformer vessel that is substantially above a determined level of non-conductive medium in the distribution transformer vessel, and a second data collection area representing a second volume of the distribution transformer vessel that is substantially below the determined level of nonconductive medium, and wherein the processing circuit is arranged to produce a signature that represents a determined level of the nonconductive medium within the distribution transformer vessel.

In other embodiments of an electric power industry structure monitor, the electric power industry structure is a distribution power pole arranged to support electric power transmission lines that carry electricity having a voltage of 600 volts (600V) or less, and the electric power industry structure monitor is arranged to monitor a tilt of the distribution power pole. In these cases, the monitor may further include at least one energy harvesting circuit arranged to power the electric power industry structure monitor, wherein once deployed, the electric power industry structure monitor is not physically, electrically wired to any external power source. Sometimes, the at least one energy harvesting circuit includes at least one solar cell and at least one rechargeable storage circuit electrically coupled to the at least one solar cell.

In some cases, the electric power industry structure monitor further includes electronic control circuitry arranged to determine a tilt of the electric power industry structure; electronic communication circuitry arranged to communicate tilt information from the electric power industry structure monitor; at least one antenna coupled to the electronic communication circuitry; at least one rechargeable energy storage device; and at least one energy harvesting circuit electrically coupled to the at least one rechargeable energy storage device, wherein power generated by the at least one energy harvesting circuit is arranged to power the electric power industry structure monitor, and wherein once deployed, the electric power industry structure monitor is not physically, electrically wired to any external power source.

In some cases of the electric power industry structure monitor, the electronic control circuitry further includes at least one accelerometer circuit; a processor; and memory coupled to the processor, said memory storing instructions that, when executed by the processor, cause the electric power industry structure monitor to: produce shock information based on data generated by the at least one accelerometer circuit; produce the tilt information based on data generated by the at least one accelerometer circuit; and direct the electronic communication circuitry to communicate at least one of the shock information and the tilt information to a remote computing device.

In these or other cases, the electronic control circuitry further includes at least one thermometer circuit arranged to generate temperature measurement data, the least one thermometer circuit communicatively coupled to the processor, wherein the memory further stores instructions that, when executed by the processor, cause the electric power industry structure monitor to direct communication of at least some of the temperature measurement data to the remote computing device. And in some cases, the at least one accelerometer circuit includes at least one 3-axis accelerometer circuit arranged to detect motion due to tilt, sway, deflection, shock, falling, or displacement caused by at least one of wind, earthquake, structural impact, flooding, age-related failure, or vandalism. And sometimes, the memory further stores instructions of a calibration routine that, when executed by the processor, cause the electric power industry structure monitor to compensate for a non-vertical positioning of the electric power industry structure monitor on the distribution power pole.

In other embodiments of an electric power industry structure monitor, the electric power industry structure is a high-voltage power pole, the high-voltage power pole arranged to support electric power transmission lines that carry electricity having a voltage of ten thousand volts (10 kV) or more.

In these and other cases, the electric power industry structure is arranged for mounting at least 50 feet above ground level. Sometimes, the electric power industry structure monitor is a self-powering device further including at least one harvested wireless power source, the at least one harvested wireless power source including one or more solar cells, one or more power induction coils, or one or more thermoelectric modules arranged to generate power sufficient to operate circuitry of the electric power industry structure monitor. And sometimes, the electric power industry structure monitor is arranged to capture vibration information, tilt information, and water saturation information associated with an area under the high-voltage power pole. In still other cases, the electric power industry structure monitor is arranged to capture vandalism information, gunshot detection information, weather information, and environmental condition information proximate the high-voltage power pole.

This Brief Summary has been provided to describe certain concepts in a simplified form that are further described in more detail in the Detailed Description. The Brief Summary does not limit the scope of the claimed subject matter, but rather the words of the claims themselves determine the scope of the claimed subject matter.

### BRIEF DESCRIPTION OF THE SEVERAL VIEWS OF THE DRAWINGS

Non-limiting and non-exhaustive embodiments are described with reference to the following drawings, wherein like labels refer to like parts throughout the various views unless otherwise specified. The sizes and relative positions of elements in the drawings are not necessarily drawn to scale. For example, the shapes of various elements are selected, enlarged, and positioned to improve drawing legibility. The particular shapes of the elements as drawn have been selected for ease of recognition in the drawings. One or more embodiments are described hereinafter with reference to the accompanying drawings in which:

FIG. 1A is an electric power grid;

FIG. 1B is a portion of the electric power grid in more detail;

FIG. 1C is a system level deployment or a portion of an electric power grid having at least one monitor structure coupled to a power pole;

FIG. 1D is another partial system level deployment of a power grid;

FIG. 1E is a closer view of one portion of the partial system level deployment of FIG. 1D;

FIG. 2A is a perspective view of a first embodiment of an electric power industry structure monitor arranged as a distribution transformer monitor;

FIG. 2B is a perspective view of a first portion of the electric power industry structure monitor of FIG. 2A mounted on a distribution transformer vessel;

FIG. 2C is a front facing view of the first portion of the electric power industry structure monitor of FIG. 2B;

FIG. 2D is another perspective view of a second portion of the first embodiment of the electric power industry structure monitor arranged as the distribution transformer monitor of FIG. 2A;

FIG. 3A is a cross-sectional view of the housing of the first embodiment of the electric power industry structure monitor arranged as the distribution transformer monitor of FIG. 2A;

FIG. 3B is another cross-sectional view of the housing of FIG. 3A;

FIG. 4 is a schematic of a system that implements a first embodiment of an electric power industry structure monitor;

FIG. 5 is a data flow embodiment representing certain operations of a system of electric power industry structure monitors;

FIG. 6A is a bottom-side perspective view of a second embodiment of an electric power industry structure monitor arranged as a tilt sensor;

FIG. 6B is a top-side perspective view of the second embodiment of an electric power industry structure monitor;

FIG. 6C is a break-out perspective view of the second embodiment of an electric power industry structure monitor;

FIG. 6D is a power pole having one embodiment of an electric power industry structure monitor arranged as a tilt sensor mounted thereon;

FIG. 6E is a power pole having another embodiment of an electric power industry structure monitor arranged as a tilt sensor mounted thereon;

FIGS. 7A-7D present an alternate configuration of the second embodiment of an electric power industry structure monitor;

FIG. 8 is a schematic of a system that implements a second embodiment, third embodiment, or second and third embodiment of an electric power industry structure monitor; and

FIG. 9 is an embodiment of a high-voltage power pole.

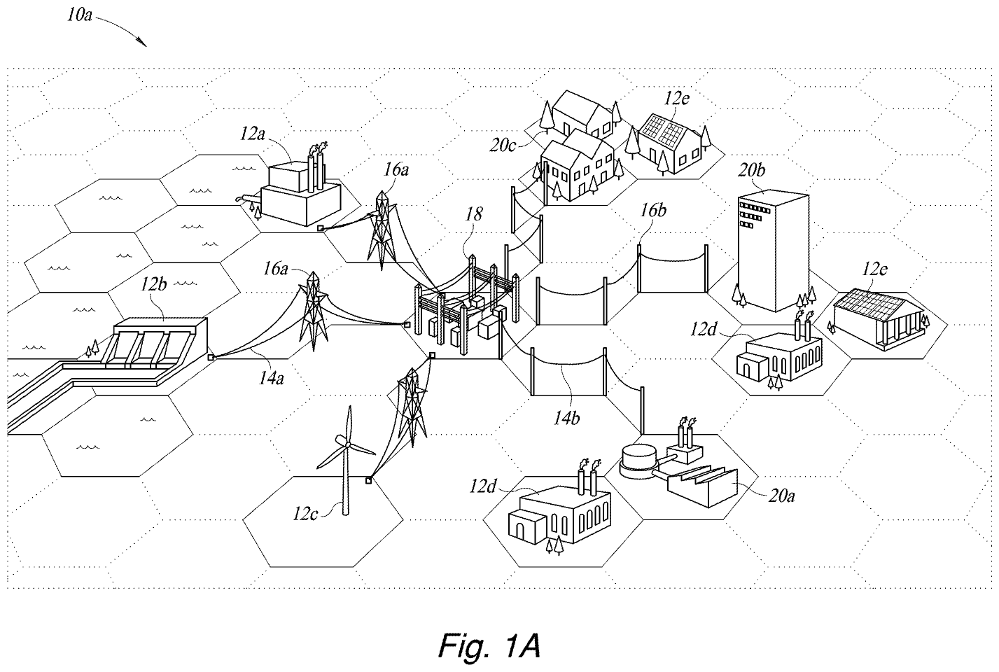

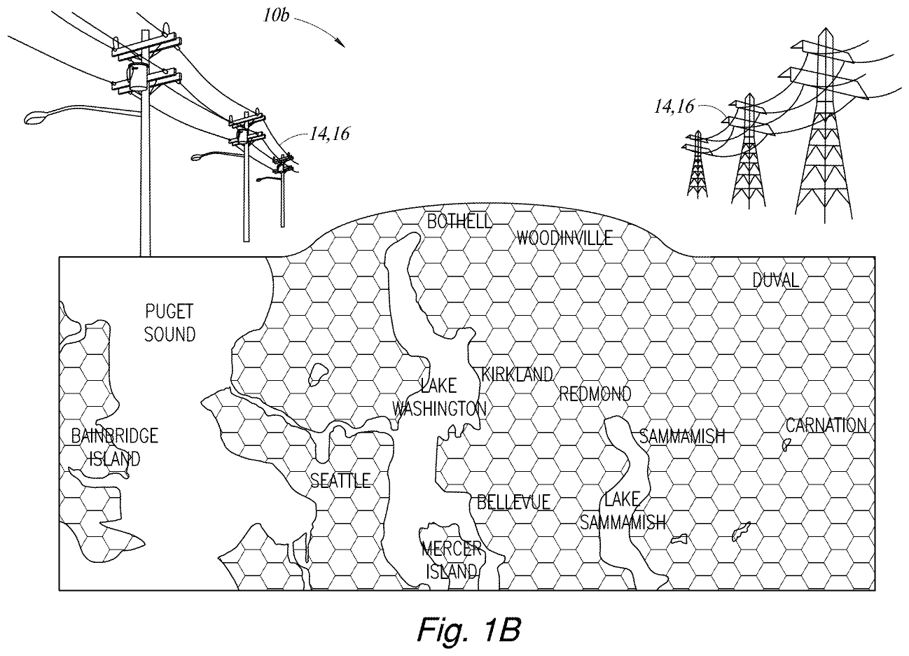

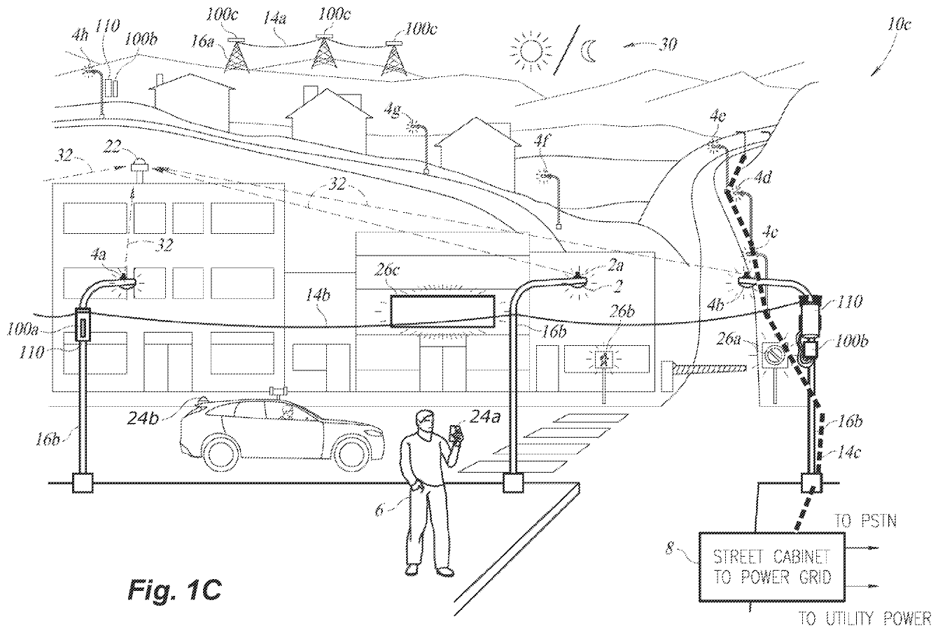

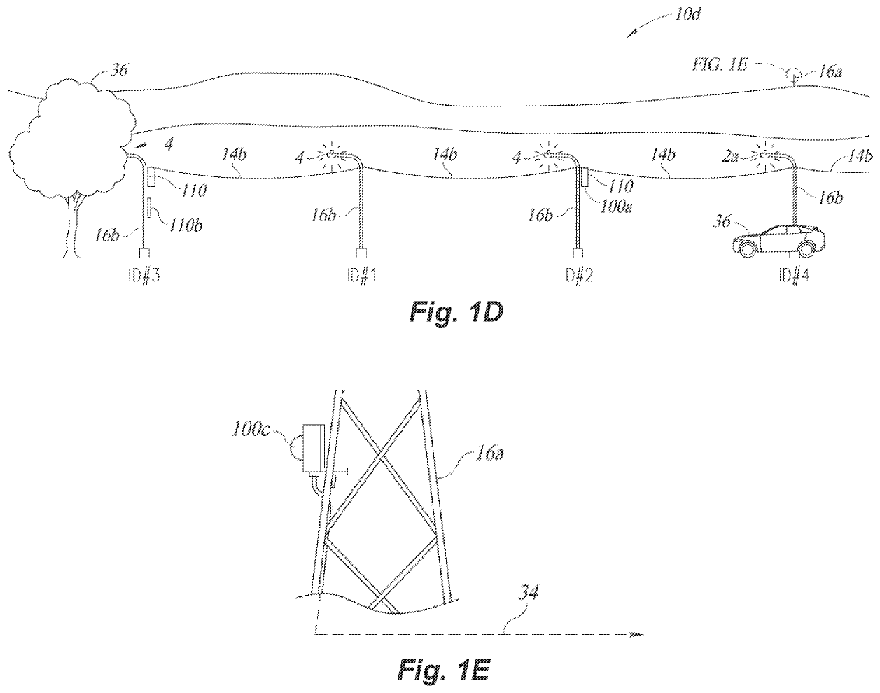

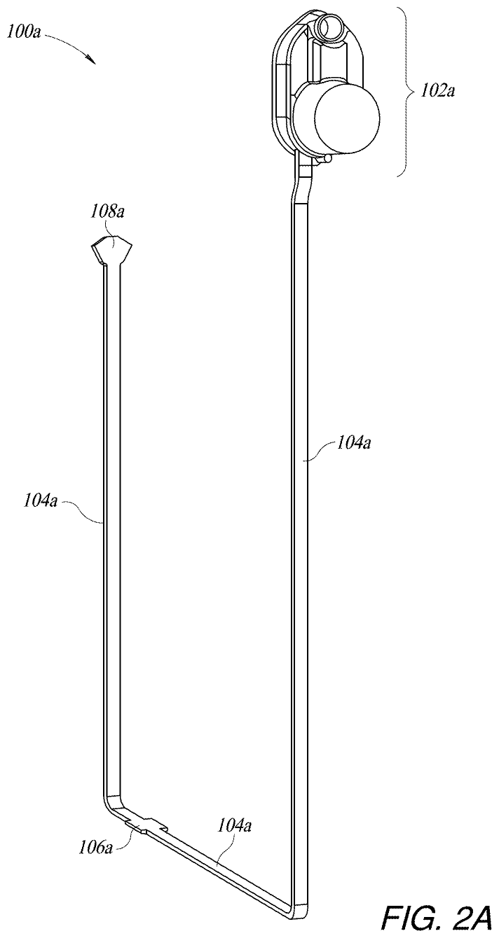

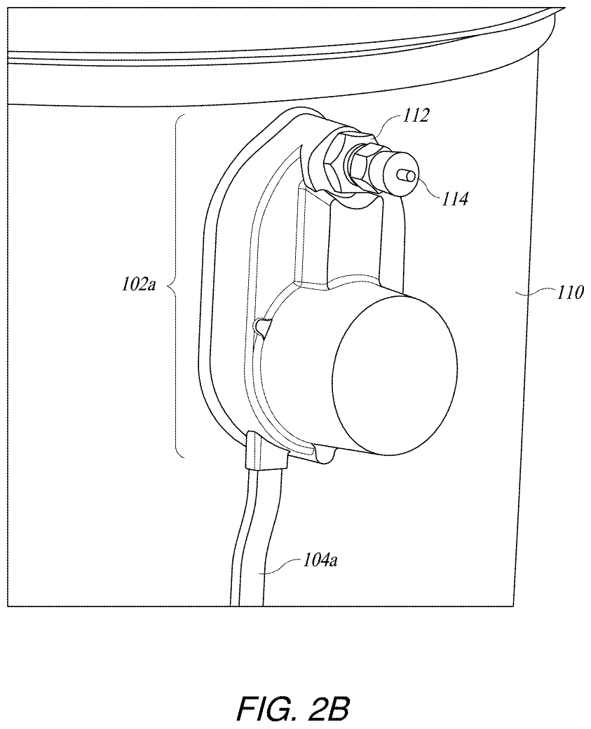

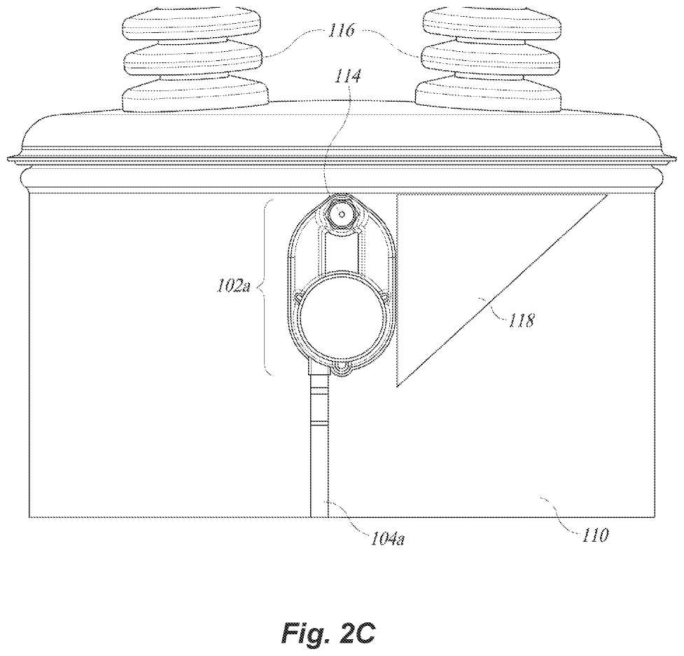

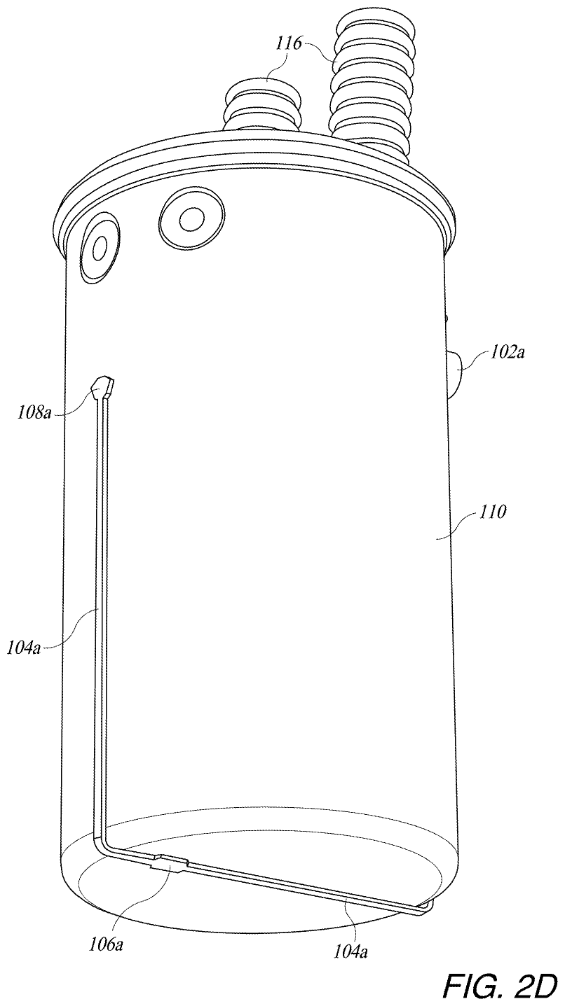

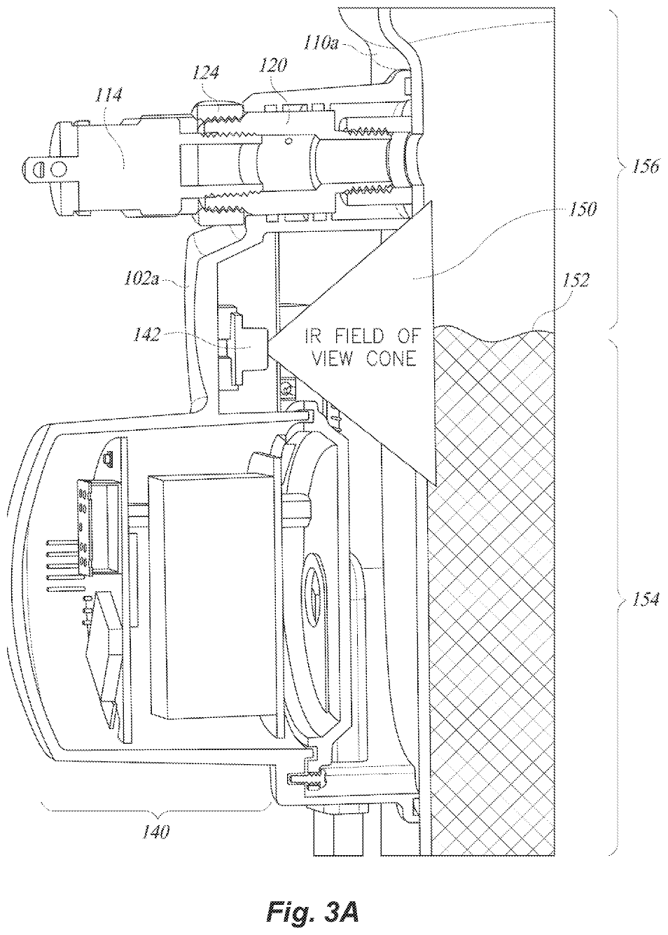

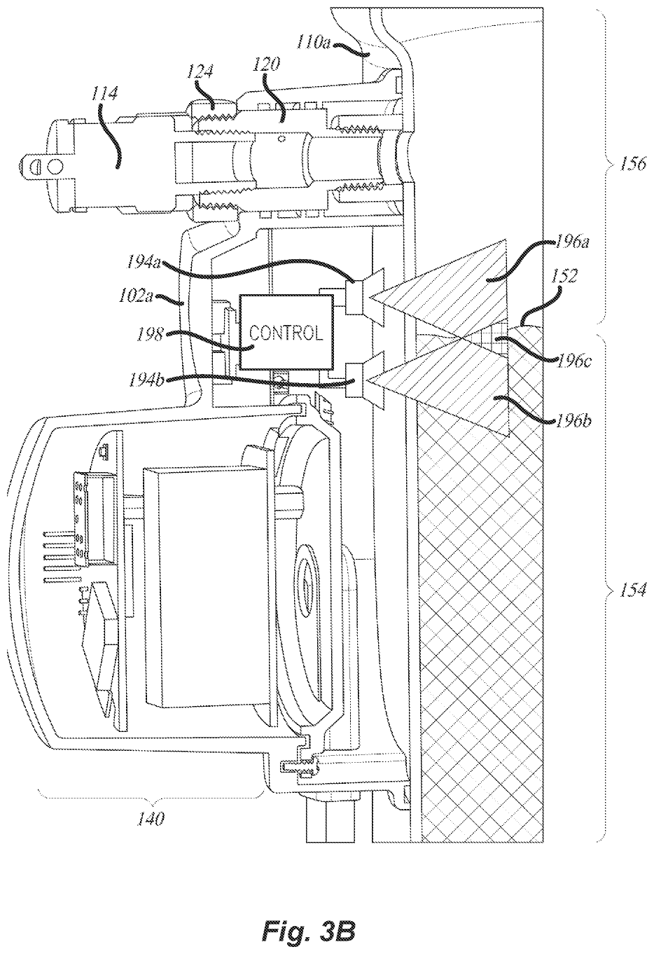

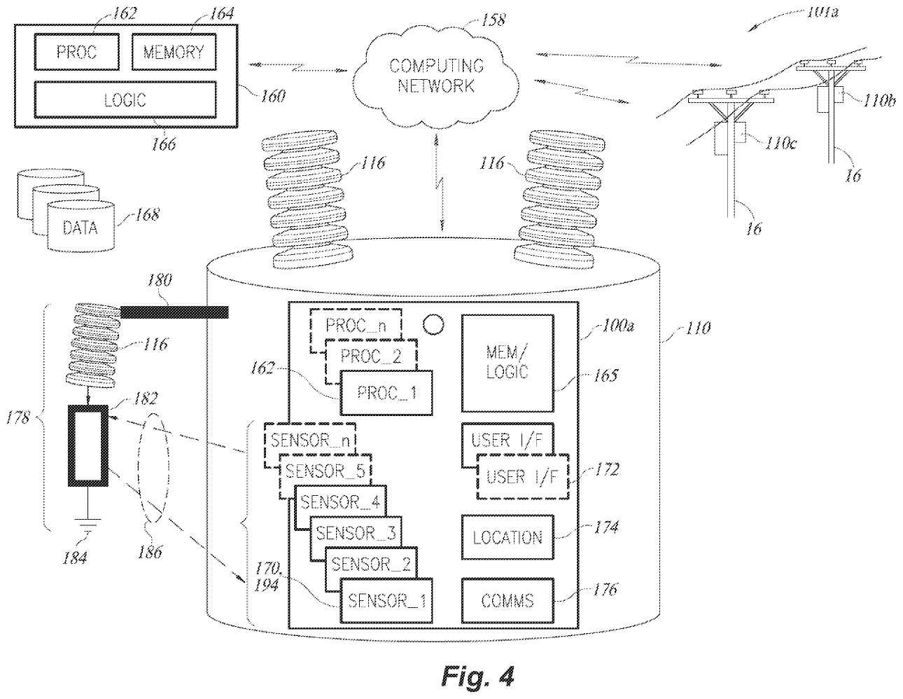

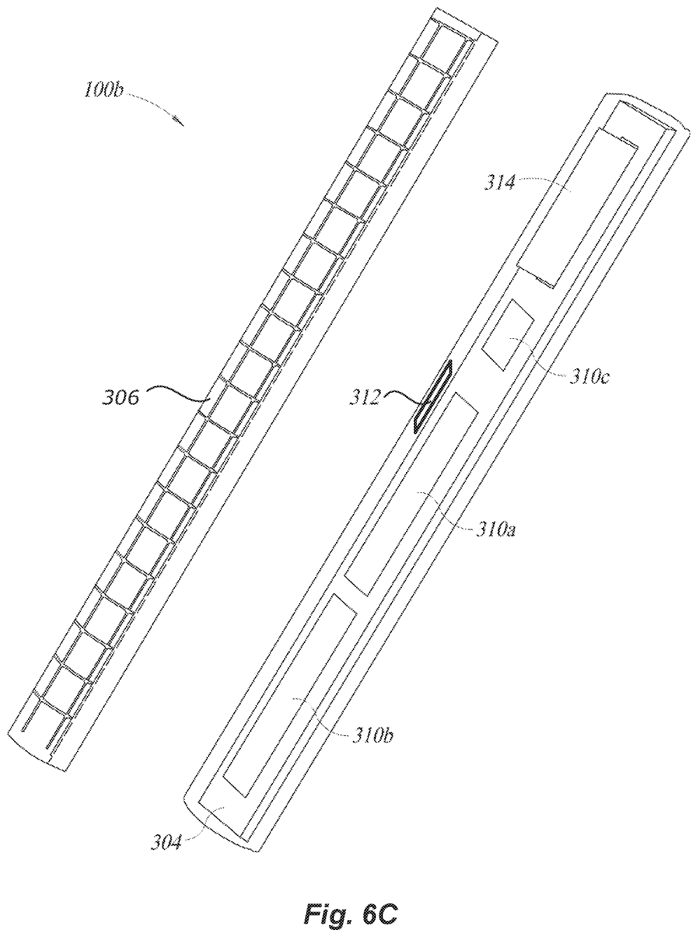

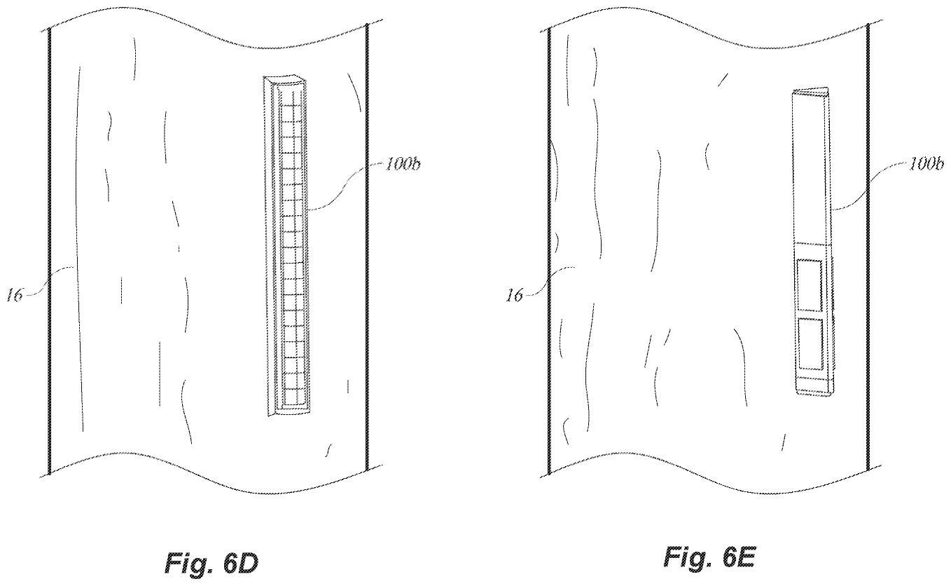

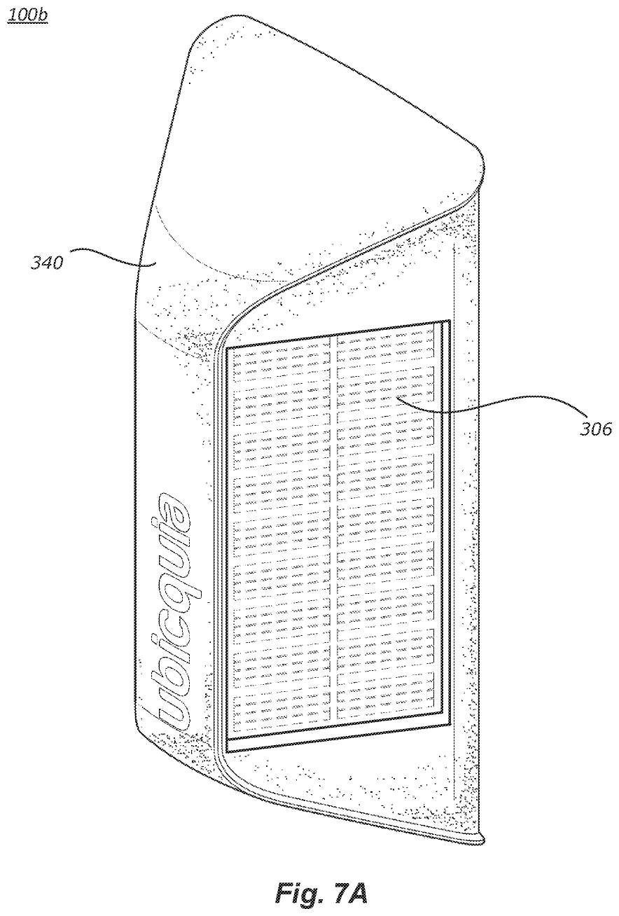

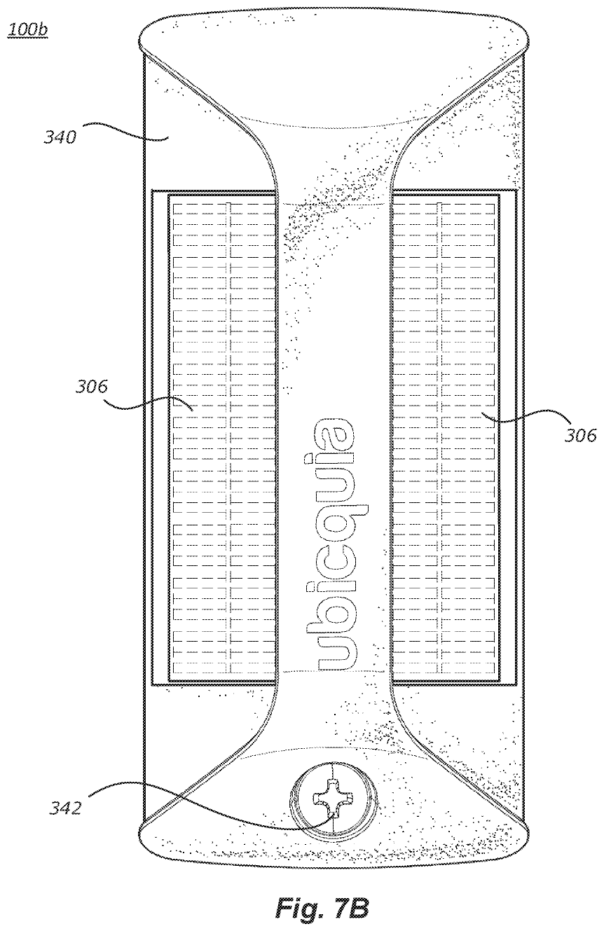

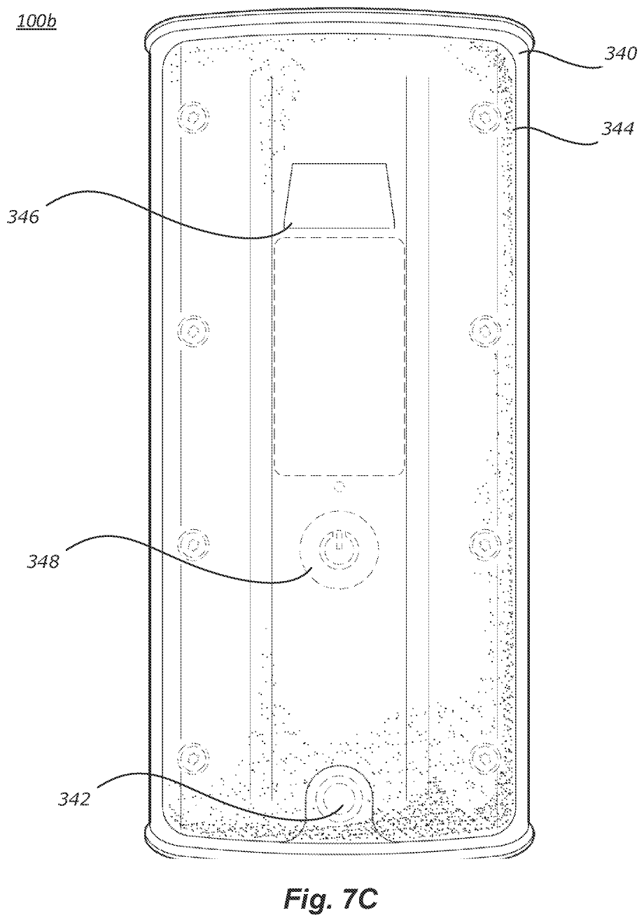

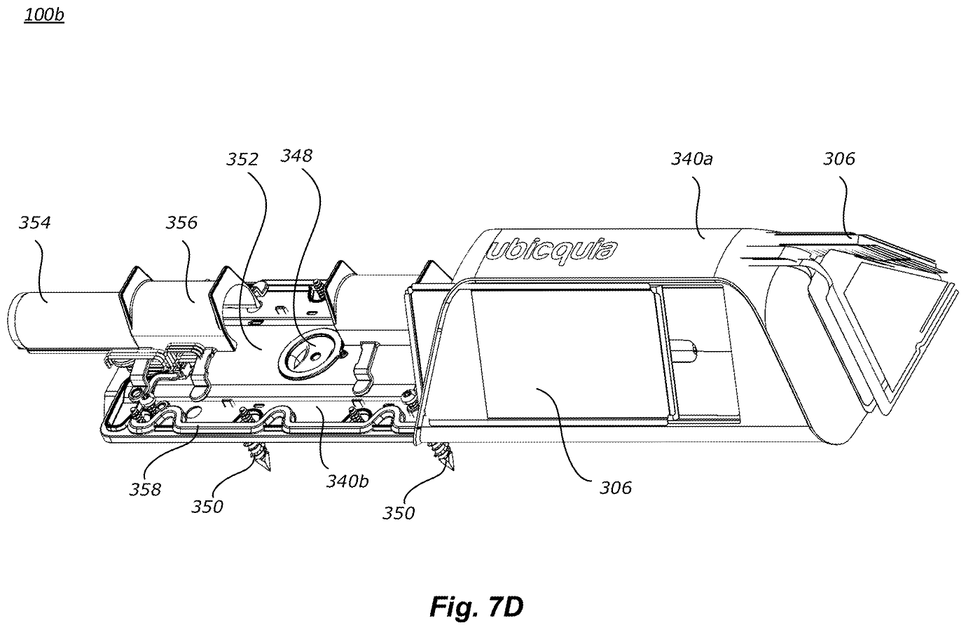

In the present disclosure, for brevity, certain sets of related figures may be referred to as a single, multi-part figure to facilitate a clearer understanding of the illustrated subject matter. For example, FIGS. 1A-1E may be individually or collectively referred to as FIG. 1. FIGS. 2A-2D may be individually or collectively referred to as FIG. 2. FIGS. 3A-3B may be individually or collectively referred to as FIG. 3. FIGS. 6A-6E may be individually or collectively referred to as FIG. 6. FIGS. 7A-7D may be individually or collectively referred to as FIG. 7. Structures earlier identified are not repeated for brevity.

### DETAILED DESCRIPTION

The present disclosure may be understood more readily by reference to this detailed description and the accompanying figures. The terminology used herein is for the purpose of describing specific embodiments only and is not limiting to the claims unless a court or accepted body of competent jurisdiction determines that such terminology is limiting. Unless specifically defined herein, the terminology used herein is to be given its traditional meaning as known in the relevant art.

In the following description, certain specific details are set forth in order to provide a thorough understanding of various disclosed embodiments. However, one skilled in the relevant art will recognize that embodiments may be practiced without one or more of these specific details, or with other methods, components, materials, etc. Also in these instances, well-known structures may be omitted or shown and described in reduced detail to avoid unnecessarily obscuring descriptions of the embodiments.

The device, method, and system embodiments described in this disclosure enable deployment of particular power-pole mountable electric power utility monitors. The monitors described in the present disclosure may in some cases contain small cell electronic circuitry. In some cases, the monitors draw power from the power lines supported by the power pole. In other cases the monitors are electrically isolated from the power lines supported by the power pole.

Electricity transmission from a centralized power generation plant through any number of substations and powerlines to an end point is an inherently dangerous endeavor. Failures in any part of the transmission system (e.g., the electric grid, power grid, grid, or the like) may put lives and property in danger. Storms, wildfires, natural wear and tear of equipment, defective equipment, vandalism, and other such events all contribute toward failures that may occur in the electric power grid.

To prevent harm to lives and damage to property, various means are employed by utilities, governments, businesses, and private individuals to monitor the electric power grid. At least some of these means include electric circuits that are designed to measure power at various points of the electric power grid with a high degree of accuracy. When changes to voltage, current, frequency, or other such parameters of the electricity on the transmission lines is detected, an alert is triggered, and the condition of relevant portions of the electric power grid are checked. In other cases, cameras, unmanned aerial vehicles (UAV's), and humans are all deployed to monitor various portions of the grid.

In still other cases, autonomous sensors of various mechanical, electrical, and electromechanical configurations are arranged to monitor and report on the integrity (e.g., vertical orientation, tilt, deflection, bend, vibration, physical shock, electrification, collapse, and the like) of the power pole to which they are attached. Such sensors may communicate with a central station (e.g., a remote computing server), a local computing device (e.g., a mobile phone, tablet, laptop computer, wearable computer, or other mobile computing device), or even another sensor. In addition to monitoring the integrity of a specific power pole, one or more autonomous sensors described in the present disclosure may also be arranged to measure, collect, capture, or otherwise generate local environmental data (e.g., sustained wind speed, maximum wind gust, temperature, air pressure, humidity, water level, and the like).

The conventional systems to monitor structures of the electric grid are insufficient. The present inventors have recognized that safety in the electric grid may be improved with the devices, methods, and systems to monitor electric power industry structures described herein (i.e., the teaching of this present disclosure).

FIGS. 1A-1E are various embodiments of an electric power grid and portions thereof. In the present disclosure, FIGS. 1A-1E may be collectively referred to as FIG. 1. Structures earlier identified are not repeated for brevity. The conventional power generation and transmission structures and methods previously discussed may, in at least some cases, provide a platform for the electric power industry structure monitor embodiments disclosed herein.

FIG. 1C is a system level deployment 10c of a portion of an electric grid having various electric power industry structure monitor embodiments coupled to corresponding structures of the electric power grid (e.g., power poles, streetlight fixtures, aerially mounted and sub-station housed distribution transformers, and the like). Certain ones and still more of the electric power industry structure monitor embodiments represented in FIG. 1C are illustrated in other figures of the present disclosure and described in greater detail in subsequent portions of the disclosure.

In the system level deployment 10c, a plurality of power poles 16a, 16b are arranged in one or more determined geographic areas. The power poles 16a, 16b of FIG. 1C are generally like the power poles 16, 16a, 16b of FIGS. 1A-1B. In at least some embodiments where the power pole includes a streetlight, the streetlight has at least one light source positioned in a fixture.

Some of the power poles of a power grid may carry power lines 14a, 14b, which are generally like the power lines 14, 14a, 14b of FIGS. 1A-1B. In other cases, a power grid may include underground power lines 14c. As a point of reference, the light fixtures are at least twenty feet above ground level and in at least some cases, the fixtures are between about 20 feet and 40 feet above ground level. In other cases, the streetlight fixtures may of course be lower than 20 feet above the ground or higher than 40 feet above the ground. In other system level deployments according to the present disclosure, there may be 1,000 or more power poles 16a, 16b arranged in one or more determined geographic areas. In these or in still other cases, the power pole and streetlight fixtures 2 may of course be lower than 20 feet above the ground or higher than 40 feet above the ground. Although described as being above the ground, the various fixtures and monitor embodiments shown and contemplated in the present disclosure may also be subterranean. For brevity, one of skill in the art will recognize that not each and every one of the power poles and streetlight fixtures represented in FIG. 1C is specifically identified.

The power grid of streetlight poles, streetlight fixtures, streetlight sources, or the like in the system level deployment 10c may be controlled by a utility, a municipality, a public/private partnership, a government agency, or some other publicly affiliated entity. In other cases, the grid of power poles, streetlight poles, streetlight fixtures, streetlight sources, or the like in the system level deployment 10c is controlled by a private entity (e.g., private property owner, third-party service contractor, or the like). In still other cases, a plurality of entities shares control of the grid of power poles, streetlight poles, streetlight fixtures, streetlight sources, or the like. The shared control may be hierarchical or cooperative in some other fashion. For example, when the system or portion of a power grid is controlled by a municipality or a department of transportation, an emergency services agency (e.g., law enforcement, medical services, fire services) may be able to request or otherwise take control of the system. In still other cases, one or more sub-parts of the grid of power poles, streetlight poles, streetlight fixtures, streetlight sources, or the like can be granted some control such as in a neighborhood, around a hospital or fire department, in a construction area, or in some other manner.

In the system level deployment 10c of FIG. 1C, any number of streetlight fixtures may be arranged with a connector that is compliant with a roadway area lighting standard promoted by a standards body. The connector permits the controlling or servicing authority of the system to competitively and efficiently purchase and install control devices, such as light sensors, on one or more streetlight fixtures. In addition, or in the alternative, the standardized connector in each streetlight fixture permits the controlling or servicing authority to replace conventional light sensors with other devices such as a small cell networking device 2a, a smart sensor device 4a-4h, or some other device.

In the system level deployment 10c, a small cell networking device 2a is electromechanically coupled to a selected light pole 2 wherein the electromechanical coupling is performed via the connector that is compliant with the roadway area lighting standard promoted by a standards body. Stated differently, the system level deployment 10c embodied in FIG. 1C includes at least one power pole and light fixture with a small cell networking device 2a, and a plurality of power poles each having a smart sensor device 4a-4h. In these power poles, each streetlight fixture is equipped with a standalone smart device 2a, 4a-4h that is electromechanically coupled via a respective connector that is compliant with the roadway area lighting standard promoted by the standards body. Each smart device 2a, 4a-4h is further electrically coupled to a processor-based light control circuit. In at least some of these embodiments, electrically coupling the light sensor to the processor-based light control circuit includes passing a signal representing an amount of light detected by the light sensor to the processor-based light control circuit. In at least some of these embodiments, the light sensor is arranged to detect an amount of lux, lumens, or other measurement of luminous flux and generate the signal representing the amount of light detected.

The processor-based light control circuit of each smart device is arranged to provide a light control signal to the respective light source based on at least one ambient light signal generated by its associated the light sensor. In addition, because each smart sensor device 2a, 4a-4h is equipped with communication capabilities, each streetlight having an associated smart device 2a, 4a-4h can be controlled remotely as an independent light source or in combination with other light sources. In these cases, each of the plurality of power poles and light fixtures with a smart sensor device 2a, 4a-4h is communicatively coupled to the power pole and light fixture 2 with a small cell networking device 2a. The communicative relationship from each of the plurality of power poles and light fixtures with a smart sensor device 4a-4h to the power pole and light fixture 2 with a small cell networking device 2a may be a direct communication or an indirect communication. That is, in some cases, one of the plurality of power poles and light fixtures with a smart sensor device 4a-4h may communicate directly to the power pole and light fixture 2 with a small cell networking device 2a, or the one of the plurality of power poles and light fixtures with a smart sensor device 4a-4h may communicate via one or more other ones of the plurality of power poles and light fixtures with a smart sensor device 4a-4h.

In the system level deployment 10c of FIG. 1C, various ones of the high-power poles 16a may be 250 feet apart, 500 feet apart, 1000 feet apart, 1500 feet apart, or some other distance. In the system level deployment 10c of FIG. 1C, various ones of the distribution power poles 16b may be 50 feet apart, 100 feet apart, 250 feet apart, or some other distance. In some cases, the type and performance characteristics of each small cell networking device 2a and each smart sensor device 4a-4h are selected based on their respective distance to other such devices such that wireless communications are acceptable.

In some cases of a power grid, some power poles and light fixtures with a smart sensor device 4b-4e are coupled to a street cabinet 8 or other surface-mounted or subterranean structure that provides utility power (e.g., “the power grid”) in a wired way. In these and other cases of a power grid, some power poles and light fixtures with smart sensor device 4a, 4f-4h or small cell networking devices 2a may be coupled to utility power in other way. The utility power may provide 120VAC, 208VAC, 220VAC, 240VAC, 260VAC, 277VAC, 360VAC, 415VAC, 480VAC, 600VAC, or some other power source voltage.

In some cases, a power pole and light fixture with a small cell networking device 2a, and optionally one or more of the power poles and light fixtures with smart sensor devices 4a-4h, are also coupled to the same street cabinet 8 or another structure that provides a wired telecommunication backhaul connection. It is understood that these wired connections are in some cases separate wired connections (e.g., copper wire, fiber optic cable, industrial Ethernet cable, or the like) and in some cases combined wired connections (e.g., power over Ethernet (PoE), powerline communications, or the like). For simplification of the system level deployment 10c of FIG. 1C, the wired backhaul and power line 14c is illustrated as a single line. The street cabinet 8 is coupled to the power grid, which is administered by a licensed power utility agency, and the street cabinet 8 is coupled to the public switched telephone network (PSTN).

In some embodiments, any number of small cell networking devices 2a and smart sensor devices 4a-4h are arranged to provide utility grade power metering functions. The utility grade power metering functions may be performed with a circuit arranged to apply any one or more of a full load, a partial load, and a load where voltage and current are out of phase (e.g., 60 degrees; 0.5 power factor). Other metering methodologies are also contemplated. In at least some cases, the power metering functions are used to determine where faults have occurred or where faults are imminent. In such cases, the small cell networking devices 2a and smart sensor devices 4a-4h may be deployed to monitor a power grid and communicate appropriate alerts thereby improving safety of the power grid.

Each power pole and light fixture with a smart sensor device 4a-4h may be in direct or indirect wireless communication with the power pole and light fixture 2 that has the small cell networking device 2a. In addition, each power pole and light fixture with a smart sensor device 4a-4h and the power pole and light fixture 2 with the small cell networking device 2a may also be in direct or indirect wireless communication 32 with an optional remote computing device 22. The remote computing device 22 may be controlled by a utility, a municipality, a private entity such as a mobile network operator (MNO), another government agency, another third party, or some other entity. By this optional arrangement, the remote computing device 22 can be arranged to wirelessly communicate light control signals and any other information (e.g., packetized data) between itself and each respective wireless networking device coupled to any of the plurality of power poles.

A user 6 holding a mobile device 24a is represented in the system level deployment 10c of FIG. 1C. A vehicle having an in-vehicle mobile device 24b is also represented. The vehicle may be an emergency service vehicle, a passenger vehicle, a commercial vehicle, a public transportation vehicle, a drone, or some other type of vehicle. The user 6 may use their mobile device 24a to establish a wireless communication session over a cellular-based network controlled by an MNO, wherein packetized wireless data is passed through the power pole and light fixture 2 with a small cell networking device 2a. Concurrently, the in-vehicle mobile device 24b may also establish a wireless communication session over the same or a different cellular-based network controlled by the same or a different MNO, wherein packetized wireless data of the second session is also passed through the power pole and light fixture 2 with a small cell networking device 2a.

Other devices may also communicate through power pole-based devices of the system level deployment 10c. These devices may be internet of things (IoT) devices or some other types of devices. In FIG. 1C, two public information signs 26a, 26b, and a private entity sign 26c are shown, but many other types of devices are contemplated. Each one of these devices may form an unlicensed wireless communication session (e.g., WiFi) or a cellular-based wireless communication session with one or more wireless networks made available by the devices shown in the system level deployment 10c of FIG. 1C.

The sun and moon 28 are shown in FIG. 1C. Light or the absence of light based on time of day, weather, geography, or other causes provide information (e.g., ambient light) to the light sensors of the power pole mounted devices described in the present disclosure. Based on this information, the associated light sources may be suitably controlled.

At least some power poles 16b in the system level deployment 10c of FIG. 1C are arranged with a distribution transformer 110. The distribution transformers 110 may optionally be arranged with a first embodiment of an electric power industry structure monitor 100a or a second embodiment of an electric industry structure monitor 100b. At least some high power poles 16a are arranged with a third embodiment of an electric power industry structure monitor 100c.

FIG. 1D is another partial system level deployment 10d of a power grid, and FIG. 1E is a closer view of one portion of the partial system level deployment 10d of FIG. 1D. A distribution power pole 16b and streetlight fixture with a small cell networking device 2a is shown, and a plurality of power poles 16b and streetlight fixtures with smart sensor devices 4 are shown. Each one of the devices has its own identifier, and all the devices are communicatively coupled to each other. The communication may be in a wired or wireless manner. In at least some cases, one or more distribution power poles 16b may also support a distribution transformer vessel 110, and an electric power industry structure monitor 100a, 100b.

A high power pole 16a is also shown in FIG. 1D and shown in greater detail in FIG. 1E. The high power pole 16a may include an electric power industry structure monitor 100c. Power, backhaul communications, and/or other signals may in some cases be passed via a wire bundle 34 coupled to the power pole 16a. Alternatively, the electric power industry structure monitor 100c may be electrically isolated from any hardwired power sources and in these or other cases, the electric power industry structure monitor 100c may be communicatively isolated from any wired computing devices.

Using the devices of FIGS. 1D and 1E, a user in a vehicle 36 may make a cellular-based call. For example, if the cellular based call is coupled through the macrocell, when the vehicle 35 moves away from the power structure, the call may be passed or seamlessly connected in another way through a cellular-based network enabled by the light pole and fixture with a small cell networking device 2a.

In at least some cases, motion may be detected in proximity to any one of the devices of FIGS. 1D and 1E based on wireless communication activity detected by a small cell networking device 2a or smart sensor device 4. In at least some other cases, motion may be detected by an electric power industry structure monitor 100a, 100b, 100c. That is, a user, mobile device, or some other moving object may be detected as being in proximity to any particular light pole. The motion detection may be based on recognition of previous hand-offs of the communication from one device to another device, based on a prediction of handoff to or from one device to another device, by tracking signal strength from a particular mobile device, by tracking quality of a wireless signal, or based on some other aspect of the wireless communication session. Additionally, motion detection may be based on an analysis of captured audio, video, other multimedia, temperature data, or other sensor data. In some cases, motion may be detected by a wireless signal detected (e.g., “sniffed”) even though the mobile device is not in active wireless communications with the particular smart sensor device 4 or small cell networking device 2a. In this way, motion detection in the systems described herein may be accomplished in the presence or absence of any sound detection devices, infrared sensor devices, camera-based devices, heat detection devices, or the like.

In FIG. 1D, a tree 36 is in close proximity to a particular one of the power poles 16b. In some cases, a smart sensor device 4 of the particular light pole (i.e., ID#3) is arranged to detect the obstruction, directly or indirectly communicate the problem through a small cell networking device 2a, and summon service to clear the obstruction. In other cases, an electric power industry structure monitor 100a-100c is arranged to detect the obstruction and generate an alert. In still other cases, an electric power industry structure monitor 100a-100c is arranged to monitor conditions in the electric power grid and provide alerts on the occurrence, or prior to the formation, of an unsafe condition (e.g., a distribution transformer in danger of exploding, a power pole struck by a vehicle, foliage covering power lines, and many others).

In at least some cases, a first embodiment of an electric power industry structure monitor 100a is arranged as a distribution transformer monitor. In at least some cases, an electric power industry structure monitor 100b is arranged as a tilt sensor monitor. In at least some cases on electric power industry structure monitor 100c is arranged as a high-voltage tower (e.g., power pole) monitor.

FIG. 2A is a perspective view of a first embodiment of an electric power industry structure monitor 100a arranged as a distribution transformer monitor. FIG. 2B is a perspective view of a first portion of the electric power industry structure monitor 100a of FIG. 2A mounted on a distribution transformer vessel 110. FIG. 2C is a front facing view of the first portion of the electric power industry structure monitor 100a of FIG. 2B. FIG. 2D is another perspective view of a second portion of the first embodiment of the electric power industry structure monitor 100a arranged as the distribution transformer monitor of FIG. 2A. Collectively, any of FIGS. 2A-2D may be referred to herein as FIG. 2. Structures earlier identified are not repeated for brevity.

The first embodiment of the electric power industry structure monitor 100a includes four identified portions. A first portion includes a housing 102a, a second portion includes signal conduction means 104a, a third portion includes a securing means 106a, and a fourth portion includes an operational testing means 108a.

The housing 102a of the electric power industry structure monitor 100a may be formed of any suitable shape or combination of shapes. For example, in at least some cases, the housing 102a is between about four inches long (4 in.) and about fourteen inches long (14 in.), the housing 102a is between about two inches wide (2 in.) and about seven inches wide (7 in.), and between about one inch tall (1 in.) and about six inches tall (6 in.). The housing 102a may include one or more chambers to contain any number of electronic circuits and sensors including a processing circuit or two or more processing circuits working cooperatively, one or more cameras, one or more audio circuits (e.g., microphone), one or more accelerometer circuits, one or more temperature (e.g., thermometer) circuits, one or more current detection (e.g., Rogowski) circuits, one or more location (e.g., global positioning system (GPS)) circuits, one or more transceiver circuits, one or more human interface device (HID) circuits, and any other suitable circuits.

The housing 102a may be formed of any suitable material or combination of materials. For example, the housing 102a may be formed from any one or more of a steel-based material, an aluminum-based material, an alloy, fiberglass, plastic resin material, a composite material, a glass-filled material, a nylon material, a polycarbonate material, a heat stabilizing material, a heat conductive material, an electrical insulator material, an ultraviolet (UV) radiation resistant material, or any other metallic and non-metallic materials. In at least some cases, the housing 102a is substantially formed from a material that is substantially non-conductive electrically. In at least some cases, the housing 102a is formed from a material having an operating range that includes at least 140 degrees Fahrenheit (140° F.).

The housing 102a may be internally coated, externally coated, internally and externally coated, or not coated at all. The coating, if applied, may be partial coating or a complete coating, and the coating, if applied, may be arranged as any suitable number of layers. Any coating, if applied, may be a paint, a dye, a polymer, or some other suitable material. The coating may be sprayed, anodized, sputtered, brushed, immersed, layered, baked-on, or formed from some other suitable process. In at least some cases, the coating may be arranged as a protective barrier. In such cases, the coating may be a barrier to protect against weather elements (e.g., low temperature such as below 32 degrees Fahrenheit (32° F.), high temperature such as above 90 degrees Fahrenheit (90° F.), wind, moisture such as by rain, humidity, fog, snow, and the like), animal damage, insect damage, vandalism, and any other physical assaults.

As discussed in the present disclosure, the housing 102a is arranged to contain a plurality of structures that monitor one or more features of an associated distribution transformer.

The signal conduction means 104a is formed in some cases in three identified sections of the electric power industry structure monitor 100a of FIG. 2A. Other electric power industry structure monitor embodiments may have more or fewer sections. In some cases, an electric power industry structure monitor arranged as a distribution transformer monitor embodiment may not have any signal conduction means 104a outside of the housing 102a.

The signal conduction means 104a may conduct power, control signals, or power and control signals. The signal conduction means 104a may have a one, two, or any number of separate and distinct conductors. The individual conductors of the signal conduction means 104a may be formed of solid wire, stranded wire, or some other conduit. Some or all of the conductors of a signal conduction means 104a may have the same structure (e.g., stranded, solid, or the like), the same conductive material (e.g., copper, aluminum, or the like), the same insulative material (e.g., plastic, rubber, silicone, or the like), and the same dimensions (e.g., gauge, diameter, or the like). Some or all of the conductors of a signal conduction means 104a may have different structure, conductive material, insulative material, dimensions, or any other parameters. In at least some cases, some portion of a signal conduction means 104a may be formed with one or more transceivers arranged for wireless communications.

In at least some cases, the signal conduction means 104a includes two separate and distinct conductors arranged to provide power into the housing 102a. In at least some of these cases and other cases, the signal conduction means 104a includes two other or additional separate and distinct conductors to carry signals that represent current flowing through a distribution transformer located in an associated distribution transformer vessel.

A suitable signal conduction means 104a may be any certain and useful length and any certain and useful shape. The signal conduction means 104a of the electric power industry structure monitor 100a is arranged to “wrap” around a substantially cylindrical distribution transformer vessel having certain dimensions. In some cases, each signal conduction means 104a is arranged with defined dimensions and shapes for a particular distribution transformer vessel, and in other cases, signal conduction means are arranged with flexible dimensions and shapes suitable for adaptation to a plurality of distribution transformer vessels.

The electric power industry structure monitor 100a of FIG. 2A includes a single securing means 106a. In other cases, a distribution transformer monitor may have zero, two, or some other number of securing means 106a. The securing means is arranged to fixedly or removably couple one or more structures such as a signal conduction means 104a and an operational testing means 108a to a distribution transformer vessel. The signal securing means 106a in some cases is formed from a magnet or magnetic material. In these and other cases, a signal securing means may be arranged with a chemical adhesive (e.g., glue, epoxy, or the like), a clamp, a weld, screws, bolts, a shaped compartment, or any other suitable bonding structure.

The electric power industry structure monitor 100a of FIG. 2A includes at least one operational testing means 108a. Other distribution transformer monitors may include some other number of operational testing means 108a. Still other electric power industry structure monitors do not include any operational testing means 108a. In some cases, the operational testing means 108a includes a circuit to detect, measure, or otherwise determine the presence and in some cases the amount of electromagnetic energy associated with a distribution transformer. In at least one case, the operational testing means 108a includes a Rogowski coil circuit.

In at least some cases, the same or similar materials and coatings used or otherwise available to form the housing 102a may also be used to form one or more protective structures about the signal conduction means 104a, the securing means 106a, and the operational testing means 108a. Along these lines, the electric power industry structure monitor 100a may be arranged to resist environmental damage, nuisance damage (e.g., animals, insects, human vandalism), and the like. The electric power industry structure monitor 100a may further be arranged via color, shape, texture, and the like to blend with a distribution transformer vessel environment and thereby be unobtrusive, un-noticeable, or otherwise unremarkable. Conversely, the electric power industry structure monitor 100a may be arranged to stand out from an associated distribution transformer vessel and thereby be easily noticed, wherein such notice can signal an observer that the distribution transformer is being monitored.

FIG. 2B is a perspective view of a first portion of the first electric power industry structure monitor 100a embodiment of FIG. 2A mounted on a distribution transformer vessel 110. In particular, FIG. 2B shows the housing 102a and a portion of the signal conduction means 104a of the electric power industry structure monitor 100a arranged as a distribution transformer monitor. The distribution transformer monitor embodiment in FIG. 2A is mounted to a distribution transformer vessel 110. In the embodiment of FIG. 2B, the housing 102a is positioned about a pressure conveyance adapter (See FIG. 3; not shown in FIG. 2B). A locking collar 112 secures the housing 102a of the electric power industry structure monitor 100a to the distribution transformer vessel 110. A pressure relief valve 114 is rotatably positioned in the pressure conveyance adapter.

FIG. 2C is a front facing view of the first portion of the electric power industry structure monitor 100a embodiment of FIG. 2B. The housing 102a, signal conduction means 104a, and distribution transformer vessel 110 are identified. The pressure relief valve 114 is also identified. Two distribution transformer insulators 116 are identified, and a right-angle indicator legend 118 is indicated in FIG. 2C. In some cases, the legend is a virtual legend that is not be visible on the distribution transformer vessel. In other cases, the right-angle indicator legend 118 is a registration feature printed, etched, painted, molded, engraved, adhered, or otherwise present in or on the distribution transformer vessel 110.

The right-angle indicator legend 118 may be useful, in at least some cases, to position the housing 102a of the electric power industry structure monitor 100a in a substantially vertical orientation relative to the distribution transformer vessel 110.

FIG. 2D is another perspective view of a second portion of the first electric power industry structure monitor 100a embodiment of FIG. 2A. In FIG. 2D, the electric power industry structure monitor 100a arranged as a distribution transformer monitor is positioned in proximity to a distribution transformer vessel 110. The housing 102a of the electric power industry structure monitor 100a and the signal conduction means 104a of the electric power industry structure monitor 100a are identified. The securing means 106a and operational testing means 108a are also identified. The distribution transformer vessel 110 includes two distribution transformer insulators 116.

FIG. 3A is a cross-sectional view of the housing 102a of the first embodiment of the electric power industry structure monitor 100a arranged as the distribution transformer monitor of FIG. 2A. A pressure relief valve 114 is removably coupled to a pressure conveyance adapter 120. A sealable aperture 138 of the housing 102a is engaged with the external surface of the central portion of the pressure conveyance adapter 120. The locking collar 124 binds the housing 102a to the distribution transformer vessel 110 in a substantially vertical orientation.

The distribution transformer vessel 110 is filled in a known way to a determined level 152 with a known non-conductive medium 154 such as oil. The non-conductive medium 154 may be used to transfer or dissipate heat from a distribution transformer located in the distribution transformer vessel 110. As is known, operational use of the distribution transformer will produce heat, and the non-conductive medium 154 will transfer at least some of the heat to the wall 110a of the distribution transformer vessel 110 where the heat energy may be further transferred through the wall 110a of the distribution transformer vessel 110. An increase in temperature of the non-conductive medium 154 can cause an accumulation of pressure in the distribution transformer vessel 110. One reason for such an increase in temperature is a loss of some or all of the non-conductive medium 154 from the distribution transformer vessel 110 due to a leak. Another reason for such an increase is a high ambient temperature outside of the distribution transformer vessel 110 that prevents dissipation of heat. Still other reasons for an increase in temperature of the non-conductive medium 154 include a partial or complete failure of certain components of the distribution transformer (e.g., a leak in the distribution transformer vessel 110, a breakdown in insulation of the transformer windings that creates a short circuit in the transformer windings, or the like), an operation of the distribution transformer in excess of certain operating parameters (e.g., over-voltage, excess load, and the like), and a chemical breakdown of the non-conductive medium 154. One of skill in the art will recognize that the temperature of the non-conductive medium 154 may increase for other reasons. If the temperature within the distribution transformer vessel 110 is too high, the distribution transformer or the distribution transformer vessel 110 may fail.

As evident in FIG. 3A, a first sensor module is an infrared (IR) image sensor 142. The module may include electronic circuitry (i.e., hardware), operative software, or circuitry and operative software. The infrared image sensor 142 has an IR field of view cone 150 that is generally aimed at a portion of the wall of the distribution transformer vessel 110. The IR field of view cone 150 is desirably formed to window the determined level 152 of the non-conductive medium 154 as evident in FIG. 3A. Generally, the determined level 152 is not visible from outside the distribution transformer vessel 110, but the determined level 152 may be estimated based on a position of a “fill port” on the sidewall of the distribution transformer vessel 110 and a position of a pressure relief valve on the sidewall of the distribution transformer vessel 110. For example, in many cases, it is reasonably believed that the distribution transformer vessel 110 will be filled with the non-conductive medium 154, via the fill port, to a level at or near the height on the distribution transformer vessel 110 of the fill port.

It has been recognized by the inventors that an IR image sensor 142 may be deployed to detect the determined level 152 of the non-conductive medium 154 based on a difference in temperature of the non-conductive medium 154 and the void or space 156 in the distribution transformer vessel 110 above the non-conductive medium 154. The different temperature values are conducted through the wall 110a of the distribution transformer vessel 110. When the IR image sensor 142 is operated, a plurality of the energy levels within the IR field of view cone 150 are captured. The different energy levels may be analyzed to identify the determined level 152 of the non-conductive medium 154.

Any suitable algorithm may be used to analyze the IR image data generated by the IR image sensor 142. In some cases, for example, a spectra algorithm is applied. In other case, a black-and-white algorithm or iron algorithm is applied. In still other cases, a different algorithm may be applied. The algorithm may arrange or otherwise represent various points (e.g., physical locations) on the wall 110a of the distribution transformer vessel 110 as an array or “window.” Energy levels captured at the points in the array or window are generated as digital information that corresponds to point-by-point temperature values on the wall 110a. In this way, a “map” of the various temperatures may be used to identify the liquid/non-liquid boundary (e.g., the interface) at the surface of the non-conductive medium 154.

In some cases, the determined level 152 is tracked over time. Temperature data readings may, for example, be captured and stored over seconds, minutes, hours, days, weeks, months, years, or any suitable length of time. In this way, the distribution temperature monitor 110A can track the level of non-conductive medium 154 (e.g., a dielectric, a non-conductive oil, an insulating oil, a mineral oil, a vegetable oil, a fluorocarbon-based oil, a silicone-based compound, a pentaerythritol tetra fatty acid natural or synthetic ester, a nanofluid, or some other insulating gas or liquid or gel or solid that is inert and substantially non-conductive) in the distribution temperature vessel 110. If the level crosses a determined threshold, then action can be taken to generate an alert, and the alert may be used to schedule further diagnosis, repair, or some other action for the distribution transformer.

In some cases, the determined level 152 of the non-conductive medium 154 in a plurality of distribution transformer vessels 110 is tracked. The information may be stored in a particular repository (e.g., a database). The accumulation of temperature data for a plurality of distribution transformer vessels 110 may, for example, be used to adjust one or more determined thresholds monitored by electric power industry structure monitor 100a. Such analysis can be used to more efficiently determine when alerts are triggered, and such analysis can additionally or alternatively be used to determine what action is taken when certain determined thresholds are crossed. In this way, a plurality of distribution transformers can be maintained with an increased level of service (e.g., “up-time”) and an increased level of safety (e.g., avoidance of a distribution transformer vessel explosion or other catastrophic failure).

FIG. 3B is another cross-sectional view of the housing 102a of FIG. 3A. Various components identified in FIG. 3B are duplicative of components identified in, and discussed with reference to, FIG. 3B, but for brevity, these components are not further discussed.

A plurality of data recording sensors 194a, 194b are arranged to capture certain data associated with the distribution transformer vessel 110. In the embodiment of FIG. 3B, the data recording sensors are microphones. The microphones may be active microphones, passive microphones, micro electromechanical systems (MEMS) based microphones, or some other type of audio data capturing device. In yet other embodiments, the data recording sensors 194a, 194b are sensors arranged to capture video data, infrared data, temperature data, vibration data, distance data, or the like.

Each of data recording sensors 194a, 194b is arranged to capture data in a data collection area 196a, 196b, respectively. A first data collection area 196a is directed to capture data in a volume of the distribution transformer vessel 110 that is substantially above the determined level 152 of non-conductive medium 154. A second data collection area 196b is directed to capture data in a volume of the distribution transformer vessel 110 that is substantially below the determined level 154 of nonconductive medium 154. The first data collection area 196a, the second data collection area 196b, and an overlapping data collection area 196c are shown in FIG. 3B. In some cases, the first and second data collection areas 196a, 196b do not overlap at all. In some embodiments, the first and second data collection areas 196a, 196b have a conical volumetric shape. In other cases, the first and second data collection areas 196a, 196b have a cuboid shape, a linear shape, a non-linear shape, a planar shape, or some other shape.

In some embodiments, such as in the embodiment of FIG. 3B, the data recording sensors 194a, 194b are in close proximity (e.g., within 1 millimeter (mm), within 2 mm's, within 5 mm's, or some other distance less then 50 mm's) to the wall 110a of the distribution transformer vessel 110, but the data recording sensors 194a, 194b are not in physical contact the wall 110a. Space between the wall 110a of the distribution transformer vessel 110 and the data recording sensors 194a, 194b may protect the sensors from heat, vibration, or other interferences.

A control structure 198 for the data recording sensors 194a, 194b may include any suitable number of substructures for the physical control of the sensors. For example, the control structure 198 may include frames, bezels, brackets, adjustment screws or other adjustment devices, seals, gaskets, or the like.

A control structure 198 for the data recording sensors may alternatively or additionally provide electronic control, mechanical control, or some other type of control. For example, the control structure 198 may include one or more notch filters, cutoff filters, narrow band filters, wideband filters, or filters of another configuration. In this way, for example, desirable audio signals may be captured in the human-sub-audible range below 20 Hz, in the human-audible range of 20 Hz to 20,000 Hz, in the certain range between 30 Hz and 5,000 Hz, or in the human-super-audible range above 20,000 Hz. Other electronic circuitry such as amplifiers, signal selection circuits, channel selection circuits, memories, and the like is also contemplated.

During normal operation, the data recording sensors 194a, 194b may collect data over fractions of seconds, seconds, tens of seconds, minutes, hours, days, or some other period of time. The collected data may be processed locally or remotely. The collected data may be aggregated, compressed, filtered, or processed in any desirable way. The inventors have recognized that in at least some cases, when data collected in the first data collection area 196a is cooperatively combined with data collected in the second data collection area 196b, the combination may be used to produce a signature that represents the determined level 152 of the nonconductive medium 154 within the distribution transformer vessel. As the signature changes, conclusions about the determined level 152 may be deduced.

Powerfully, when a centralized system is arranged to collect data from a plurality of distribution transformer vessels 110, many signatures can be generated or otherwise captured and stored in a repository. When any particular signature is coupled with factual data about the corresponding distribution transformer vessel 110, it can be inferred that a different distribution transformer vessel 110 having a same or similar signature will also share the same factual data. For example, a certain “pre-failure” signature was generated a short time before a particular distribution transformer vessel 110 failed. Subsequently, if a new signature generated from data recorded by sensors 194a, 194b of a different distribution transformer vessel 110 is determined to be the same or similar to the pre-failure signature, then it can be inferred that the distribution transformer vessel 110 will also soon fail unless steps are taken to prevent the failure.

The inventors have further recognized that the process of generating signatures based on data collected by one, two, or any suitable number of data recording sensors is not limited to audio sensors. Instead, the data that is used to generate a signature may be collected from a sensor of any particular type (e.g., audio, video, temperature, vibration, or any other type of energy).

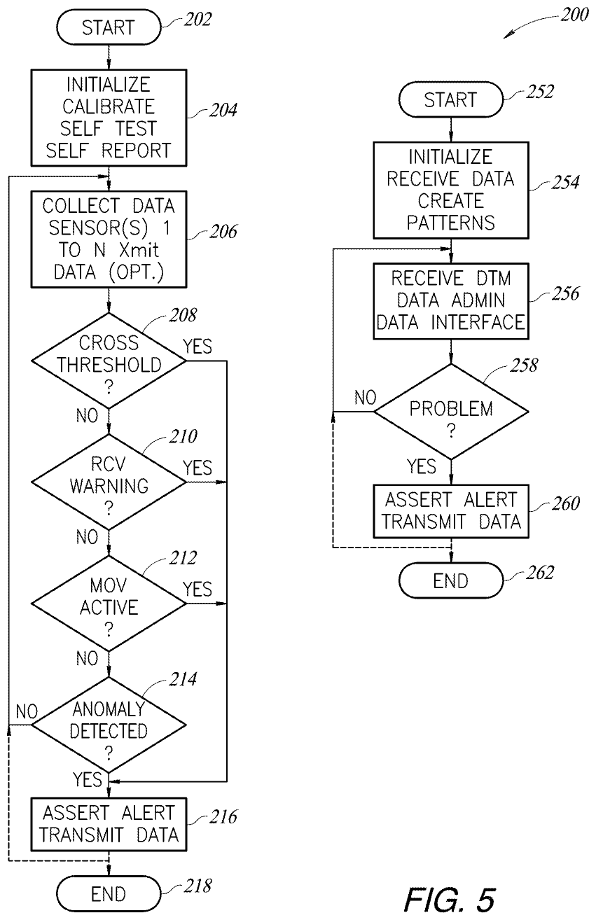

FIG. 4 is a schematic of a system 101a that implements a first embodiment of an electric power industry structure monitor 100a. In this embodiment, the electric power industry structure monitor 100a is configured as a device arranged to monitor a distribution transformer 110. The system 101a includes a plurality of electric power industry structure monitors 100a, each of the plurality of monitors being arranged to monitor a respective distribution transformer.

The distribution transformers 110 in the system 101a of FIG. 4 are represented as aerially mounted distribution transformers 110 mounted to a plurality of power distribution poles, but other arrangements are contemplated. In some cases, distribution power poles have two or more distribution transformers 110, and in some other cases, distribution power poles do not have any distribution transformers. Distribution transformers mounted aerially, distribution transformers mounted at ground level (e.g., mounted in ground-level vaults, mounted on platforms or pads of concrete or other materials, mounted behind fences, mounted in buildings, and the like), and subterranean distribution transformers (e.g., mounted in below ground-level vaults) are all contemplated for monitoring. Distribution transformers submersed in any suitable dielectric-filled vessel are contemplated, and distribution transformers not mounted in such vessels or mounted in vessels without a dielectric are also contemplated.

In FIG. 4, a first transformer vessel 110 is illustrated, and an electric power industry structure monitor 100a is illustrated in detail. For convenience, in FIG. 4, second and third transformer vessels 110b, 110c are illustrated as mounted on respective power poles 16. In addition, each of the second and third transformer vessels 110b, 110c has an electric power industry structure monitor 100a mounted thereon, but to avoid unnecessarily crowding FIG. 4, these additional electric power industry structure monitors 100a are not identified. Power lines (i.e., power distribution electricity conduits), distribution transformer mounting means, and other such structures are illustrated in FIG. 4, but not expressly identified for brevity.

The distribution transformers contemplated in the present disclosure may in some cases each weigh several hundred pounds. For this reason, a strong, reliable, safe mounting means (i.e., brackets, bolts, and the like) will be employed, as known by ones of skill in the art, to secure the distribution transformer to its respective power pole. The present inventors have recognized that due to such weight, the vibration, tilt, torque, substantially lateral pressure (e.g., wind pressure), and other physical forces on a power pole may contribute to a failure of the distribution transformer and put people and property at risk if the distribution transformer fails. Accordingly, at least some of the distribution transformer monitors of the present disclosure may be optionally arranged to monitor any one or more of such forces, and based on the monitoring, at least some of the distribution transformer monitors may optionally direct that one or more corresponding actions be taken.

The system 101a that implements the first embodiment of an electric power industry structure monitor 100a of FIG. 4 may include any number of electric power industry structure monitors 100a arranged to monitor any number of corresponding distribution transformers (e.g., one, ten, one hundred, one thousand, ten thousand, or any other number), and the number of devices in the system 101 may change dynamically. That is, at any time, in real time, or at proscribed times, one or more new transformers may be added to a functioning electric power industry structure monitor system 101, and the electric power industry structure monitor system 101 may stop monitoring distribution transformers that were previously monitored. In some cases, a same distribution transformer may enter and exit the electric power industry structure monitor system 101 any number of times.

In the electric power industry structure monitor system 101a of FIG. 4, a computing network 158 bidirectionally, unidirectionally, or bidirectionally and unidirectionally facilitates communications between any number of computing devices. In some cases, any number of electric power industry structure monitors 100a may communicate with any number of other electric power industry structure monitors 100a. Communications with and between electric power industry structure monitors 100a may be peer-to-peer, broadcast, or via a central computing device such as a computing server 160.

The computing server 160 includes one or more processors 162, memory 164, and functional logic 166. The memory 164 may be arranged to store processor-executable software, data, and any other information. The functional logic 166, as understood by one of skill in the art, may include circuitry, antennas and other communication components, physical structures, software, and still other logic to support the functions of the computing device that are implemented by the processor 162. Accordingly, the logic 166, in cooperation with the processor 162 and the memory 164, may receive user and machine input, direct use and machine output, and perform other expected computing functions as would be known by those of skill in the art.

The computing server 160 may optionally include or cooperate with a data repository 168 (e.g., a database). Data of any type received from any number of electric power industry structure monitors may be stored in the repository 168, and data of any type that is stored in the repository 168 may be communicated to any number of electric power industry structure monitors. One of skill in the art will recognize that in at least some embodiments, the system 101a of FIG. 4 may be managed or otherwise arranged in a distributed computing environment, which may also be referred to as a cloud computing system, a server farm, or some other like term. By exploiting the distributed computing environment, data collected from a plurality of electric power industry structure monitors 100a may be aggregated, parsed, mined, and otherwise combinatorially used to match patterns, form predictions, track environmental and other phenomena, and implement broad based services across a wide geographic area.

The electric power industry structure monitor 100a includes one or more processors 162, memory and logic 165, sensor circuitry 170, 194, user interface circuitry 172, location determination circuitry 174, and communications circuitry 176. Other circuits and operational features such as software are of course contemplated in the electric power industry structure monitors described herein, but such circuits and features are not described so as to avoid unnecessarily obfuscating one or more of the circuits and features of focus in the corresponding figure.

The processor circuitry 162 of the electric power industry structure monitor 100a may be along the lines of the processor 162 of computing server 160.

The memory and logic 165 includes memory arranged to store processor-executable software arranged for execution by the processor circuitry 162. The memory and logic 165 may also be arranged to store data that controls the electric power industry structure monitor 100a (e.g., initialization data, control parameters, and the like), and data generated by other modules of the electric power industry structure monitor 100a (e.g., sensor circuitry 170, data recording sensors 194, user interface circuitry 172, and other modules). In some cases, the memory and logic 165 implements other features of the distribution transformer monitor 100b. For example, in at least some cases the memory and logic, in concert with the communications module 176 expose a control interface (e.g., a configuration management system (CMS)) that provides an application programming interface (API) to selected, selectable, or other remote computing devices, which are permitted to send commands to, and receive data from, any particular electric power industry structure monitor 100a.

In at least one case, the memory and logic 165 implements an optional identity feature in the electric power industry structure monitor 100a. The identity feature may include electronic, mechanical, or electromechanical switch circuitry, memory, a random number, a random number generator, a system-wide unique identifier, a world-wide unique identifier, or other such information. When combined with position information from the location determination circuitry 174, the electric power industry structure monitor 100a may be able to more accurately report its identity and position to another computing device. The identity information can be used diagnostically and for other reasons. In at least some cases, identity information provided by an identity feature in the memory and logic 165 is used as a network identifier for the electric power industry structure monitor 100a. The identity information may be arranged as a 32-bit number, a 64-bit number, another number having a structurally preferable bit-width, a combination of information that further conveys information about the capabilities of the distribution transformer monitor 100b (e.g., date of deployment, year of deployment, hardware version number, software version number, geographic location, or other such information).

In at least one case, the memory and logic 165 implements an optional security feature in the electric power industry structure monitor 100a. The security feature may include one or more of an encryption engine, a decryption engine, a random number generator, a secure memory, a separate processing device, and the like.

The sensor circuitry 170 of FIG. 4 may include any suitable sensors. As evidenced via dashed and solid lines in FIG. 4, the sensor circuitry 170 may include sensors that are partially or completely contained in a housing (e.g., housing 102a). Additionally, or alternatively, some or all of the sensor circuitry may be arranged outside of a housing such as a voltage sensor circuit, a current sensor circuit, a camera, a thermometer, and the like. Some or all of the sensor circuitry 170 may be contained in a single module such as electronics module 140 (FIG. 3). Some or all of the sensor circuitry may be arranged as discrete sensors such as an infrared image sensor 142 (FIG. 3A), a pressure sensor 144, and any other sensor utilized by the electric power industry structure monitors described in the present disclosure. In at least some cases, the data recording sensors 194a, 194b are included in the sensor circuitry 170. A non-limiting, non-exhaustive list of exemplary sensors represented by sensor circuity 170 include accelerometers (e.g., micro-electrical-mechanical sensors (MEMS)) of any number of axes (e.g., single-axis, two-axis, and three-axis accelerometers), IR sensors (e.g., infrared source and infrared detection circuits, object detection sensors, motion sensors, distance sensors, proximity sensors, and the like), IR image sensors (e.g., thermal imaging camera), pressure sensors (e.g., pressure transducers), vibration sensors, thermometers, current and voltage sensors (e.g., Rogowski circuits), humidity sensors, digital image sensors (e.g., cameras to capture still images, cameras to capture video, and the like), microphones, Hall effect sensors (.e.g., magnetic sensors, position sensors, and other sensors based on a Hall effect), magnetometers, load cells (e.g., weight measuring sensors), ultrasonic sensors, light sensors, and the like.

The sensors of the present disclosure may, for example, capture, generate, or otherwise provide data associated with a plurality of properties of the world. A non-limiting, non-exhaustive list of such properties include sensors that provide data associated with sound, vibration, material (i.e., liquid, solid, gas) flow, material (i.e., liquid, solid, gas) presence, chemical properties, electrical properties, environmental properties, climate properties, radiation properties, optical properties, pressure, force, density, and temperature.

In addition to their native functions, data generated by the sensors contemplated in the present disclosure may be used to create geophones, hydrophones, seismometers, sound locators, airflow meters, position sensors, wind speed meters, hurricane detectors, tornado detectors, oxygen meters, carbon dioxide meters, carbon monoxide detectors, natural gas detectors, radiation detectors, torque sensors, flood detection sensors, snow level gauges, tide gauges, ozone monitors, pollen level sensors, gravimeters, and many other types of sensors and devices.

The user interface circuitry 172 may include one or more human interface device (HID) circuits, one or more machine interface circuits, or still other circuits. The user interface circuitry 172 may include, for example, any one or more of keyboards, keypads, computer mice, touch screens, button inputs, microphones, infrared sensors, bar code readers, transceivers, transducers, and the like. The user interface circuitry 172 may alternatively or additionally include, for example, any one or more of light sources (e.g., chips on board (COB) light emitting diodes (LEDs)), audio sources, video screens, vibrators, transceivers, transducers, and the like. As evidenced via dashed and solid lines in FIG. 4, the user interface circuitry 172 may include structures that are partially or completely contained in a housing (e.g., housing 102a). Additionally, or alternatively, some or all of the user interface circuitry 172 may be arranged outside of a housing such as a button, a COB status light, a speaker or other audio output device, a display, and the like.

In some embodiments, the user interface circuitry 172 may include a light source that encodes an output message. The light from the light source, when outputting an encoded message, may or may not be visible to a human observer. In some cases, a human observer is alerted to a problem with a respective distribution transformer based on a visible output of the light source. In other cases, a machine is alerted to a problem based on a light source output that is not visible to a person. The encoded output may include any suitable information such as an identifier of the distribution transformer monitor 100b, a failure code, or some other device status information.

The location determination circuitry 174 may include global positioning system (GPS) circuitry, global navigation satellite system (GLONASS) circuitry, BeiDou navigation satellite system circuitry, or some other location determination circuitry. The location determination circuitry 174 may be a self-contained module, or the location determination circuitry 174 may include antennas, amplifiers, transceivers, or other components distributed elsewhere in the housing or external to the housing. The location determination circuitry 174 permits the electric power industry structure monitor 100a embodiment to accurately report its position to another computing device such as the computing server 160. In some cases, the position may be used to positively identify the particular electric power industry structure monitor 100a embodiment and distinguish data from the electric power industry structure monitor 100a from other electric power industry structure monitors. In some cases, the position may be used to expressly direct service personnel to the site where the electric power industry structure monitor 100a is installed. The position information can be used diagnostically when a distribution transformer is determined to be failing, when a sensor crosses a particular threshold or determines some other sensor information, and for other reasons. The highly accurate time-base of the location determination circuitry 174 may also be used by the distribution transformer monitor 100b for weather data, almanac data, signal triangulation with other devices such as distribution transformer monitors, lighting controllers, motor vehicles, or some other device and for other purposes.

The communications circuitry 176 may include any suitable wired, wireless, or wired and wireless communication circuits. For example, in some cases, the communications circuitry 176 includes optical electronic circuitry to communicate information via a fiber-optic cable. In some cases, the communications circuitry 176 includes network circuitry (e.g., Ethernet transceivers) to communicate via electrically conductive wire. In still other cases, the communications circuitry 176 includes powerline communications circuitry to communicate via a power line. In these or yet other embodiments, the communications circuitry 176 may include a wireless transceiver module to provide wireless communication capability via WiFi, cellular communications, direct peer-to-peer RF communications, or via some other wireless communication protocol.

In some cases, for example, using functionality provided by the communications circuitry 176, the electric power industry structure monitor 100a is arranged to operate as a WiFi access point. In this way, the electric power industry structure monitor 100a permits one or more mobile devices to access the internet. Municipalities or other entities may make internet services available over a determined geographic area (e.g., a neighborhood, a city, an arena, a construction site, a campus, or the like) to remote mobile devices that are in proximity to any one of a plurality of electric power industry structure monitors 100a. For example, if many power poles in a neighborhood or city are equipped with an electric power industry structure monitor 100a, then WiFi service can be provided to a large number of users. What's more, based on seamless communication between a plurality of electric power industry structure monitor 100a embodiments, the WiFi service can be configured as a mesh that permits users to perceive constant internet or other network connectivity even when the mobile device is in motion.

The distribution transformer vessel 110 of FIG. 4 includes a surge arrestor 178. Surge arrestor 178 may conform to a particular standard maintained by a standards setting organization such as the International Electrotechnical Commission (IEC), the American National Standards Institute (ANSI), the American Institute of Electrical and Electronics Engineers (IEEE), or some other organization. Surge arrestor 178 may conform to an exemplary, but not limiting, standard such as IEC 60099-4, ANSI/IEEEC62.11, or some other standard. In some cases, the standards setting body may assign a “type” or “class” rating to particular surge arrestors, which rating may be used to distinguish a range of energy requirements (i.e., operating parameters) of the device.

The surge arrestor 178 may be a Class 1 device (e.g., lightning arrestor), a Class 2 device (e.g., electrical fault arrestor), or a device of some other class arranged to prevent damage caused by an electromagnetic surge energy. Such surge arrestors may be arranged to handle large voltages (e.g., 10,000 volts, 30,000 volts, 50,000 volts, or some other voltage including a voltage over 1,000,000 volts), very large currents, (e.g., 1000 amps, 5000 amps, 50,000 amps, 100,000 amps, or some other current), or very large voltages and currents. Such surge arrestors may be designed to handle large surges for a very short time (e.g. a few seconds, a few hundred milliseconds, a few milliseconds, or some other time duration).

Typically, surge arrestors are coupled from a power carrying structure, such as a power line or a distribution transformer vessel, to earth (i.e., ground). In some cases, the coupling is direct, in other cases, the coupling may be indirect such as across an air gap. When an undesirable energy surge is present on the power carrying structure, the surge arrestor diverts the energy surge signal to ground, which action prevents, in at least most cases, the aberrant condition from damaging the equipment that the surge arrestor is arranged to protect.

Surge arrestors of the types described in the present disclosure may include resistor-capacitor circuits, Zener-type semiconductor circuits, or some other types of circuits. In at least some cases, such surge arrestors are formed using metal oxide varistor (MOV) structures (e.g., structures having one or more sequential of zinc-oxide (ZnO) structures), silicon carbide structures, or structures formed of some other elemental composition. In at least some of these cases, surge arrestor 178 is a MOV device surge arrestor arranged as a stack of ZnO discs encased in an insulator such as silicon. In other cases, surge arrestor 178 is formed in a different way.

Surge arrestor 178 (e.g., a MOV surge arrestor) works, in at least some embodiments, by presenting a very high impedance at normal operating levels and a rapidly decreasing impedance as voltage increases. In this way, normal and expected circuit signals are not affected at all by the surge arrestor, and a surging charge is diverted to ground. The surge condition may be caused by an atmospheric condition such as lightning, a resonance, a ferro-resonance, a system fault, a power line disconnection or short circuit, or by some other condition.

In some cases, a given surge arrestor can repeatedly divert energy for two or more over-tolerance condition events (e.g., multiple lightning strikes). In each of these cases, the equipment under protection remains un-damaged during and after the over-tolerance condition event. In other cases, after repeated over-tolerance condition events (e.g., multiple lightning strikes), the surge arrestor will destruct. In still other cases, after a single, particularly high-energy over-tolerance condition event (e.g., a “massive” lightning strike), the surge arrestor will destruct. In cases where the surge arrestor destructs, the equipment under protection may be spared (i.e., the surge arrestor has performed as designed and has not failed), but the surge arrestor may destruct and then any subsequent over-tolerance condition will be communicated through the equipment to be protected instead of around the equipment to be protected. If the equipment to be protected is exposed to the over-tolerance condition, the equipment may fail. Failure of the equipment may cause damage to living things (e.g., people, animals, plants) and non-living things (e.g., buildings, vehicles, power poles, distribution transformers, and things). In some cases, the damage may be extreme such as when a lightning strike on a power pole causes a distribution transformer vessel to explode and start a massive forest fire.

Many distribution power transformer vessels 110 are equipped with surge arrestors 178. The surge arrestor 178 may include any one or more of an insulator 116 portion, a surge arrestor MOV 182 portion, a surge arrestor support means 180, a ground path 184, and other structures that are not shown in FIG. 4 but are known to one of skill in the art. The structures may be arranged in any suitable way. For example, the surge arrestor support means 180 may arrange to support the insulator 116, the surge arrestor MOV 182 portion, and the ground path 184 in proximity to the distribution transformer vessel 110 (e.g., within two inches, within six inches, within 10 inches, within 20 inches, or within some other distance). The surge arrestor support means 180 may include any one or more of brackets, support arms, frames, welds, bolts, rods, posts, substructures, and any other suitable structures. The surge arrestor support means 180 in at least one case is permanently affixed to the distribution transformer vessel, and other components of the surge arrestor 178 (e.g., an insulator 116, a surge arrestor MOV device 182, a ground path, and other structures) may be permanently affixed, substantially permanently affixed, or removably affixed.

The inventors have recognized that an electric power industry structure monitor 100a may be configured to detect, and in some cases also count, each time an over-tolerance condition event (e.g., a lightning strike) occurs. In these or other cases, the inventors have recognized that an electric power industry structure monitor 100a may be configured to detect when a surge arrestor 178 or a portion of the surge arrestor 178 has been destructed or otherwise damaged. More specifically, the inventors have recognized that one or more sensors 170 may transmit, receive, generate, or otherwise deploy one or more surge arrestor continuity signals 186. The surge arrestor continuity signals 186, alone or in combination with other signals, may be used to count over-tolerance condition events, to determine if a surge arrestor 178 has destructed, or for some other purpose. The arrestor continuity signals 186 may be or otherwise include infrared (IR) signals, audio signals, camera images, or some other type of signals.

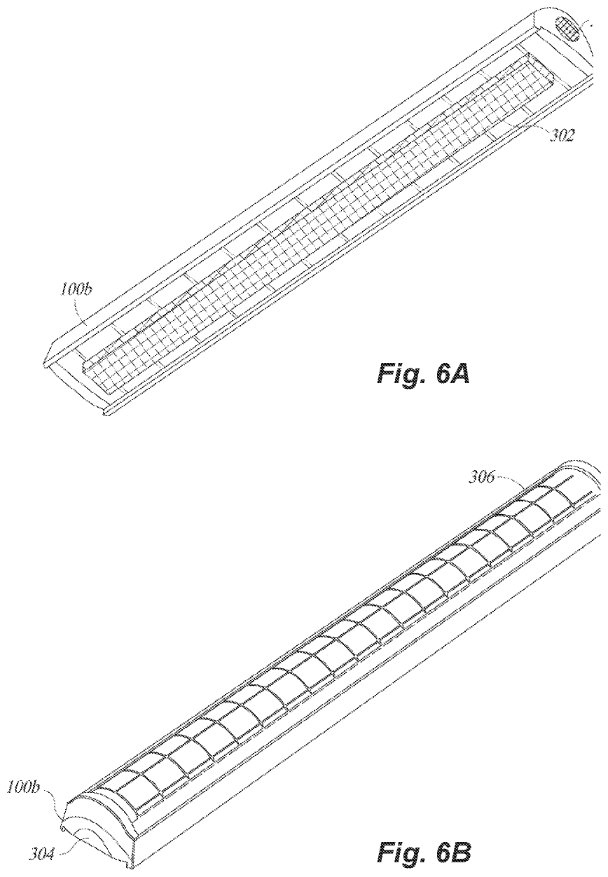

FIG. 5 is a data flow embodiment 200 representing certain operations of a system of electric power industry structure monitors such as the system 101a of computing server 160 and electric power industry structure monitors 100a in FIG. 4. In the dataflow, processing begins in one or more electric power industry structure monitors 100a at 202, and processing begins in a computing server 160 at 252. Processing in the computing server 160 is ongoing. Processing in any one or more of the electric power industry structure monitors 100a may begin and end dynamically, and processing in any one or more of the electric power industry structure monitors 100a may be ongoing, periodic, scheduled, or performed a finite number of one or more times. While processing at a single electric power industry structure monitor 100a is described, one of skill in the art will recognize that one or more electric power industry structure monitors 100a may perform the acts of FIG. 5, and while there may be synchronization (e.g., concurrent operations, simultaneous operations, cooperative operations, or the like) between multiple electric power industry structure monitors 100a, any such synchronization is optional, and no synchronization is required unless otherwise expressly recited or indicated by the context of the relevant description.

At 204, the electric power industry structure monitor 100a performs any one or more of initialization acts, calibration acts, self-testing acts, and self-reporting acts. The initialization, calibration, and self-testing acts may configure any number of sensors 170, data recording sensors 194, and any other sensors to implement the teaching of the present disclosure. In some cases, any number of initialization acts, calibration acts, and self-testing acts are automatic, and in some cases, any number of initialization acts, calibration acts, and self-testing acts are manually interactive or machine interactive. The initialization acts, calibration acts, and self-testing acts may be implemented or supported via the user interface circuitry 172 location determination circuitry, and communications circuitry. The act of self-reporting may include enabling, arranging, or otherwise configuring the electric power industry structure monitor 100a to communicate information to a computing server 160, a user device (e.g., a user computer, a mobile device, or the like), another one or more electric power industry structure monitors 100a, or some other computing device. The information communicated may include sensor information, user command, control information, location information (e.g., street address information, coordinate information (e.g., longitude, latitude, altitude, or the like), or some other location information). Processing advances to 204.

At 206, the electric power industry structure monitor 100a collects data from the logic devices (e.g., circuits, software modules, and the like) of the electric power industry structure monitor 100a. These collection acts may include any number of acts with any number of sensors. In some cases, the sensor processing is sequential, and in these or other cases, the sensor processing may also be concurrent, polled, scheduled, dynamic, or based on any other embedded design paradigm known to those of skill in the art. The data collected, which may include any distribution transformer monitor data taught in the present disclosure, or any derivative data thereof, may be communicated in full or in part to another computing device. In addition, the collection of such data may be performed via any structures or acts expressly taught or otherwise evident from the teaching of the present disclosure. The data may be communicated to a computing server 160, another electric power industry structure monitor 100a, a mobile device, a user device, or some other computing device. Processing at 206 advances to 208.

In at least some cases, the data collected at 206 includes data captured from any number of one or more data recording sensors 194 (e.g., data recording sensors 194a, 194b of FIG. 4). This data in at least one embodiment is used to generate a digital signature that represents a current state of an active distribution transformer that is operating within a particular distribution transformer vessel 110.

In the embodiment discussed here, at least some of the data captured and used to generate the digital signature is acoustic data. One of skill in the art will recognize that many other types of data may also be collected and used to generate the digital signature. For example, temperature data, voltage data, current data, and vibration data may each be used alone or in combination to generate a digital signature in other embodiments.

At the time of processing at 206, the distribution transformer is operating at a particular set of parameters, “P.” The parameters may include a particular voltage, a particular current, a particular power, a particular temperature, and the nonconductive medium within the distribution transformer vessel 110 is that a particular determined level 152. Other parameters are also considered, but for the sake of brevity and describing the present embodiment, power may be considered a first parameter (P1), current may be considered a second parameter (P2), temperature may be considered a third parameter (P3), sound data from a first data recording sensor 194a may be considered a fourth parameter (P4), and sound data from a second data recording sensor 194b may be considered fifth parameter (P5). Data from each of the parameters, P1 to Pn (wherein Pn is P5 in the present embodiment) may be aggregated, normalized, averaged, analyzed, or otherwise processed. Subsequently, data from the fourth and fifth parameters may be mathematically combined to produce a digital signature. The digital signature may be computationally associated with parameters P1 to P3 or other parameters, and the signature and parameters may be recorded. In some cases, the data is recorded locally. Alternatively, or in addition, the data is recorded remotely, such as via the remote computing server 160. By capturing parameters, and by generating and accumulating digital signatures (e.g., acoustic digital signatures) that are associated with one or more sets of parameters, one of skill in the art will recognize that a particular distribution transformer operating in accordance with a corresponding set of parameters may be expected to generate a same or similar digital signature (e.g., a same or similar acoustic digital signature). Along these lines, if particular digital signatures (e.g., particular acoustic signatures) are correlated with known unsafe conditions of a distribution transformer, then recognition of a same or similar digital signature may be used to infer a predicted future unsafe condition for some other distribution transformer. Forewarned and forearmed with an inference of a predicted future unsafe condition, action may be taken to mitigate the unsafe condition. Such action may include reducing electricity in the power lines, taking the distribution transformer off-line, human or mechanical inspection, or some other remedial action.

In processing at 208, 210, 212, and 214, the electric power industry structure monitor 100a may collect any suitable number of further data samples, generate any quantity of additional data, and perform any suitable number of acts of processing to interrogate or otherwise analyze information and determine one or more subsequent courses of action. The processing at 208-214 may be performed in the order demonstrated in FIG. 5, or the processing may be performed in some other order. The processing at 208-214 may be performed in a multi-tasking operating system, an interrupt-driven system, a polling system, a task-loop, or in some other computing architecture.

At 208, as taught in the present disclosure, data from one or more sensors, or data derived therefrom, is interrogated. If it is determined that the data has crossed a threshold, processing is advanced to 216. In at least some cases, a comparison of digital signatures may produce a result that is interpreted as crossing a threshold. Alternatively, processing advances to 210. The data interrogated may include temperature data (e.g., temperature data based on an oil level in a distribution transformer vessel, ambient temperature information), acoustic data (e.g., sound data from microphone data recording sensors 194a, 194b), vibration data, pole-tilt data, pressure data (e.g., pressure data based on a pressure in a distribution transformer vessel), distribution transformer energy data (e.g., charge, voltage, current, or some other energy data), time data, or any other data taught herein.

At 210, as taught in the present disclosure, a determination is made whether or not a warning is received at the electric power industry structure monitor 100a. If a warning is received, processing is advanced to 216. Alternatively, processing advances to 212. The warning received may include impending weather information or information associated with one or more atmospheric conditions, impending electrical information associated with electrical infrastructure coupled to a proximal distribution transformer, or some other information. The warning information may be received from another electric power industry structure monitor 100a, a computing server 160, a mobile device, or some other computing device.

At 212, as taught in the present disclosure, a determination is made whether or not a surge arrestor 178 has been active. If a surge arrestor has been active, processing is advanced to 216. Alternatively, processing advances to 214. The surge arrestor 178 may be active based on an atmospheric condition (e.g., a lightning strike), a systemic condition in the power grid (e.g., a power surge, a switching condition, or some other aberrant electrical activity), or some other condition.

At 214, as taught in the present disclosure, a determination is made as to whether any anomalies have been detected. If any anomalies have been detected, processing advances to 216. Alternatively, processing returns to 206. In at least some cases, an identification of a signature associated with an unsafe condition of a distribution transformer vessel 110 is considered an anomaly.

At 216, any number of crossed thresholds, received warnings, surge arrestor events, and anomalies are processed. In some cases, the processing includes asserting an alert signal (e.g., a human interface device (HID) audible or visual indicator, a wireless leak communicated alert message, an alert message communicated via a wired means). In these and in other cases, the processing may also include transmitting data to a computing device. The transmitted data may include any sensor data or data derived therefrom, location data, device identification data, and the like. The data may be communicated to another electric power industry structure monitor 100a, a computing server 160, a mobile device, a user device, or some other computing device.

After processing at 216, processing may optionally continue and return to 206 or and at 218.

Still referring to FIG. 5, processing at the computing server 160 begins at 252 and advances to 254.

At 254, the computing server 160 performs any number of initialization acts. The computing server 160 may receive data, create patterns, initialize communication sessions with any number of electric power industry structure monitors 100a, initialize information for delivery via a web server, and perform any other actions.

In some cases, the computing server 160 is arranged with one or more artificial intelligence processing engines (e.g., pattern matching engine, machine vision engine, neural network, or the like). The artificial intelligence processing engines may be arranged to detect patterns such as conditions that lead to destruction of a surge arrestor (e.g., patterns of brightness, number of lightning strikes, audio patterns that indicate a lightning strike, and the like). The artificial intelligence processing may additionally all or alternatively be arranged to detect other patterns such as patterns that indicate a condition leading to failure of the distribution transformer or the distribution transformer vessel. Some patterns that may be detected include voltage or current patterns generated by data from a Rogowski circuit, temperature patterns that indicate a catastrophic distribution transformer vessel failure such as an explosion, acoustic signature patterns that indicate an imminent transformer vessel failure, pressure patterns that indicate a catastrophic distribution transformer vessel failure such as an explosion, and the like.

In some cases, training data may be used to initialize an artificial intelligence engine. The training data may be any useful training data set. For example, the inventors have recognized that the distribution transformer monitor system 101 as embodied, for example, in FIG. 4, may collect data from a large number (dozens, hundreds, thousands) of electric power industry structure monitors 100a. The collected data may be from electric power industry structure monitors in the same geographic area or from widely disparate geographic areas. Some or all of the data collected from any number of electric power industry structure monitors 100a may be used to improve the quality of the artificial intelligence engine. Based on the collected data, patterns for any given distribution transformer or distribution transformer vessel may be formed, and data received from a particular distribution transformer monitor may be analyzed against the selected pattern. A determination can then be made by the computing server 160 whether or not additional action should be taken. After data is received and any number of optional patterns are created, processing advances to 256.

At 256, the computing server 160 receives data from any number of electric power industry structure monitors 100a. The data may be received on a schedule, periodically, based on a polling scheme, asynchronously, or in any other way. The computing server 160 may store the data in a repository 168 as the data is received. Additionally, or alternatively, the computing server 160 may process the received data and determine whether or not the processed data will be stored in the repository 168.

In at least some optional cases, in processing at 256, the computing server 160 may administer a data interface. A data interface may be or otherwise include, for example, any number of Internet-based webpages. In such a case, a user (e.g., a representative of a municipality, power utility, distribution transformer maintenance, public safety entity) may observe the status of any one or more distribution transformers in real time. In at least some optional cases, the user may send control information to any one or more distribution transformers in real time. In at least some optional cases, the user may interrogate any one or more distribution transformers for additional information in real time. The processing at 256 further includes optional data aggregation, data mining, data visualization, and other such suitable actions. Processing advances to 258.

At 258, the computing server 160 will determine whether a problem has been detected. One example of a problem is that a pattern indicating that a particular distribution transformer is in need of maintenance is detected. Another example of a problem is that particular surge arrestor 178 has received a determined number of over-tolerance condition events and the determined number exceeds a determined threshold. Yet additional examples of problems include detecting that a level of oil in a particular distribution transformer vessel 110 has fallen below a determined threshold (e.g., based on temperature information, based on pressure information, based on a digital signature matching process, or based on some other information), detecting that distribution transformer electrical parameters are out of a determined tolerance (e.g., based on data from a Rogowski circuit), detecting that a power pole and its particular distribution transformer vessel 110 have tilted past particular threshold, and detecting a level of water at the base of a power pole (e.g., a flooding condition, a storm surge condition, or the like). The detection of other such conditions as described in the teaching of the present disclosure are also contemplated. If no problems are detected at 258, processing returns to 256. If any problems are detected at 258, processing advances to 260.

At 260, action is taken based on one or more discovered problems. The action may include communicating any number and format of alert (e.g., directing an output of an audible or visible signal, directing the communication of one or more messages to one or more users via one or more computing devices, directing the communication of one or more messages via the Internet, directing the communication of one or more messages via a wired or wireless telephone call, or directing some other action). Processing in at least some cases will optionally continue by advancement back to 256. Optionally, in some other cases, processing may complete.

The present inventors have contemplated several real-world embodiments of a first embodiment of an electric power industry structure monitor 100a arranged as a distribution transformer monitor. Monitors of this type may in some cases be referred to as a field-system transformer monitor. A field-system transformer monitor embodiment is now described.

In at least some cases of the field-system transformer monitor embodiment, the monitors 100a are deployed on a plurality of distribution transformers that may be deployed on power poles 16b or other above-ground locations, in surface-vaults or other on-ground locations, and/or in subterranean vaults or other below-ground locations. The first embodiment of electric power industry structure monitors 100a are arranged as a remotely configurable aerial transformer monitoring system that provides Internet of Things (IoT) current and voltage Smart Metering with 99.98% MAINS accuracy and over-the-air (OTA) firmware upgrades. The monitors 100a have solid body housing enclosures, each with an IP67 rating, and each with operating temperature of between about minus forty degrees Celsius (−40° C.) and about one hundred twenty degrees Celsius (+120° C.).

In at least some cases of the field-system transformer monitor embodiment, housing 102a has integrated therein a particularly designed diaphragm assembly that is arranged to sealably mate a variety of National Pipe Thread (NPT) pressure relief valves (e.g., one-quarter inch NPT pressure relief valves, one-half inch NPT pressure relief valves, or pressure relief valves of some other size and/or configuration).

In at least some cases of the field-system transformer monitor embodiment, the first embodiment of electric power industry structure monitors 100a include one or more wireless radio frequency (RF) communication modules configured for LTE communications with mesh capability, LoRa networking, and WiFi connectivity.

In at least some cases of the field-system transformer monitor embodiment, the monitors 100a include features directed toward safe operation of distribution transformers such as threshold compliance measurements for internal pressure, oil level and oil temperature, lightning arrestor fault detection, ambient temperature, photosensor anomaly detection, tilt and vibration detection, and audio sensor event detection. The monitor 100a may further include a deployable data integrator software package that facilitates encoding and processing of operational status data for retrieval at an asset management database system deployed on or via a remote computing server. Further still, the first embodiment of an electric power industry structure monitor 100a arranged as a distribution transformer monitor may capture GPS telemetry data that permits accurate tracking and identification of actually malfunctioning distribution transformers and/or distribution transformers that are predicted to malfunction, which thereby permits timely response planning.

FIG. 6A is a bottom-side perspective view of a second embodiment of an electric power industry structure monitor 100b arranged as a tilt sensor. FIG. 6B is a top-side perspective view of the second embodiment of an electric power industry structure monitor 100b. FIG. 6C is a break-out perspective view of the second embodiment of an electric power industry structure monitor 100b. FIG. 6D is a power pole 16 having one embodiment of an electric power industry structure monitor 100b arranged as a tilt sensor mounted thereon. FIG. 6E is a power pole 16 having another embodiment of an electric power industry structure monitor 100b arranged as a tilt sensor mounted thereon. In the present disclosure, FIGS. 6A-6E may be collectively referred to as FIG. 6. Structures earlier identified are not repeated for brevity.

The second embodiment of an electric power industry structure monitor 100b, which is presented in FIG. 6, is arranged as a tilt sensor. When deployed, the monitor is mounted to a power pole. As contemplated herein, the power pole may be a high-power pole, a distribution power pole, a street light pole, a wind power generation tower, a sign pole, an antenna, a flag pole, a mast, or some other kind of structure arranged as a structure that supports one or more physical things at a determined height above the ground (AGL). The power pole may rise 10 feet AGL, 20 feet AGL, 50 feet AGL, 100 feet AGL, 125 feet AGL, 200 feet AGL, or some other height.

In one nonlimiting embodiment, the second embodiment of an electric power industry structure monitor 100b is between about five inches (5 in.) and about twenty-five inches (25 in.) long and between about one-half inch (0.5 in.) and about five inches (5 in.) wide. The second embodiment of an electric power industry structure monitor 100b has a plurality of over-molded solar cells. In some cases, the solar cells are arranged to generate electricity that is used to power the second embodiment of an electric power industry structure monitor 100b. In some cases, the electrical parameters of the output from the solar cells may be used to determine an amount of ambient light proximal to the second embodiment of an electric power industry structure monitor 100b.

In FIG. 6A, the second embodiment of an electric power industry structure monitor 100b includes a mounting means 302. In some cases the mounting means 302 is or includes a plurality of grooves integrated in a bottom portion of the electric power industry structure monitor 100b. Grooves on the bottom portion surface may be arranged to increase surface area by 50%, 60%, 70%, or some other amount. The increased surface area may be provided to enhance adhesion of the second embodiment of an electric power industry structure monitor 100b to a power pole.

The grooves may be any one or more of horizontal (i.e., running width-wise to the electric power industry structure monitor 100b), vertical (i.e., running lengthwise to the electric power industry structure monitor 100b), running crosswise, at an angle relative to the longest the linear dimension of the electric power industry structure monitor 100b, or formed in some other way. In some cases the mounting means 302 includes a plurality of apertures or any other space or structure arranged to facilitate an adhesive mounting of the electric power industry structure monitor 100b to a power pole. In at least one case, the bottom portion of the electric power industry structure monitor 100b is arranged with a distinctive “footprint” that facilitates adhesion of the electric power industry structure monitor 100b to a power pole.

The various embodiments of the electric power industry structure monitor 100b may include a bottom portion having a shaped profile. The shaped profile may be a partial, simple cylindrical radius arranged to cooperate with a corresponding cylindrical radius of a particular power pole. The shaped profile may be a partial, complex truncated frustum arranged to cooperate with a different profile of a particular power pole.

In some cases, the second embodiment of an electric power industry structure monitor 100b is adhered to a power pole via an adhesive. The adhesive may be a glue, paste, tar, epoxy, or some other form of malleable adhesive. In some embodiments, the mounting means 302 includes or comprises any one or more of a bracket, a screw, a frame, a magnet, a hook and loop material, a nut and bolt, a mounting post an aperture, or some other mounting mechanism.

The second embodiment of an electric power industry structure monitor 100b may include a mounting fixture 304. The mounting fixture 304 is arranged to facilitate mounting of the second embodiment of an electric power industry structure monitor 100b to the power pole. In at least one case, a pole-like device (not shown) of a determined length (e.g., 5 feet, 10 feet; 20 feet, or some other length) is arranged for coupling to the mounting fixture. Once the pole-like device is removably coupled to the mounting fixture 304, a person raises the second embodiment of an electric power industry structure monitor 100b vertically to a desired height and adheres the second embodiment of an electric power industry structure monitor 100b to the power pole at the desired location above the ground. The mounting fixture 304 may include an aperture, a magnet, a hook and loop material, a bracket, or some other mounting fixture means.

In some cases, a top side of the second embodiment of an electric power industry structure monitor 100b is arranged with a particular profile. The profile may be partially rounded, planar, partially triangular, partially hexagonal, partially octagonal, or the profile may have some other suitable shape. The top side surface of the second embodiment of an electric power industry structure monitor 100b may be arranged with an energy harvesting circuit 306, such as a solar power generation means. The solar power generation means may include one or more solar cells arranged to convert light into electricity. Electricity generated by the energy harvesting circuit 306 may be used to power the second embodiment of an electric power industry structure monitor 100b, power some other device, charge a power storage means (e.g., a capacitor, a battery, or the like), or the electricity may be used for another purpose. In at least some cases, when the energy harvesting circuit includes solar cells, for example, the solar cells are flexibly arranged to bend over and cover a printed circuit board or other electronic circuitry provided therebelow. In such cases, a flexible solar cell array maybe he staked to retain its profile shape and silicone potted to a bottom side portion of the second embodiment of an electric power industry structure monitor 100b.

In at least some embodiments, the second embodiment of an electric power industry structure monitor 100b is able to generate power inductively, for example by harvesting power from nearby power lines. In at least some embodiments the second embodiment of an electric power industry structure monitor 100b is arranged to generate power from proximate available heat, a temperature differential, vibration, or some other harvested energy. Alternatively, in many cases, the second embodiment of an electric power industry structure monitor 100b is not physically, electrically wired to any external power source. In any one or more of these cases, the energy harvesting circuit 306 may be arranged with inductive circuitry, magnetic circuitry, micro-electro-mechanical structures (MEMS) and MEMS control circuitry, temperature differential or other thermoelectric circuitry (e.g., a Seebeck generator, Peltier generator, or the like), electromechanical vibration-based power generation circuitry, or other such circuits.

Optionally, the second embodiment of an electric power industry structure monitor 100b includes a connector port 308. In at least some of these embodiments, the electric power industry structure monitor 100b is a modularly arranged to accept a coupling that is physical, electrical, communicative, or any one or more of these by another one or more devices. The second embodiment of an electric power industry structure monitor 100b may, for example, receive a camera, an environmental sensor, a microphone, a speaker, a water detection sensor, a radio module, an infrared distance sensor, or any other one or more suitable devices via the optional connector port 308. In at least some cases, devices that are coupled to the optional connector port 308 also may also include a connector port 308. In this way, a plurality of devices may be cooperatively coupled together in serial, in parallel, or in serial and parallel while also being coupled to the second embodiment of an electric power industry structure monitor 100b.

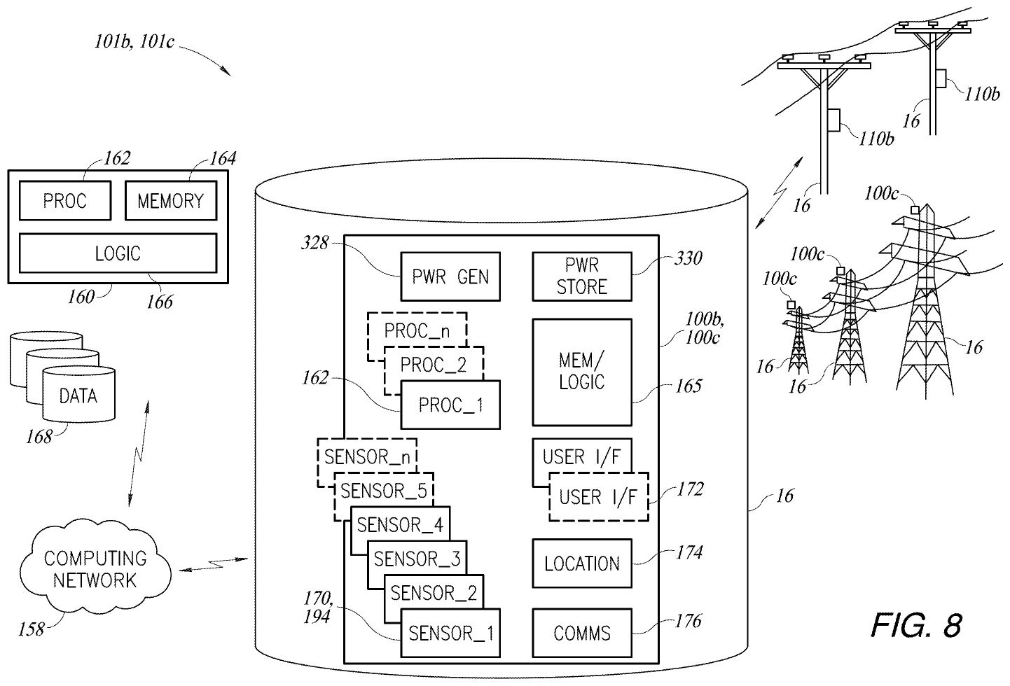

FIG. 6C is a break-out perspective view of the second embodiment of an electric power industry structure monitor 100b, which is arranged as a tilt sensor. The monitor includes energy harvesting circuitry 306 arranged in the embodiment of FIG. 6 as at least one solar cell, electronic control circuitry 310a, electronic communication circuitry 310b, other electronic circuitry 310c, and an energy storage device 314. In at least some cases, the electronic circuitry of the second embodiment of an electric power industry structure monitor 100b is arranged substantially along the lines of the schematic of the system that implements the first embodiment of the electric power industry structure monitor 100a (FIG. 4) and the third embodiment of the electric power industry structure monitor 100c (FIG. 8). For example, the electronic control circuitry may include one or more processors, memory, memory logic, functional logic, location circuitry (e.g., a GPS circuit), accelerometer (e.g., tilt, vibration, impact strike, etc.) circuitry, and other such circuitry. The electronic communication circuitry 310b may be along the lines of the communication circuitry 176 of the first and third embodiments of the electric power industry structure monitors 100a, 100c. That is, the electronic communication circuitry 310b may include a cellular-based radio arranged to communicate via the mobile network of a selected mobile network operator (MNO). The electronic communication circuitry 310b may additionally or alternatively include circuitry that communicates via one or more standardized wireless protocols (e.g., IEEE 802.11, BLUETOOTH, WI-SUN, or the like). In some cases, the electronic communication circuitry 310b includes a transceiver arranged for bidirectional communications. In other cases, the electronic communication circuitry 310b includes a transmitter arranged for unidirectional communications. Communications via the electronic communication circuitry 310b is facilitated via one or more antennas 312.

In some cases, the energy storage device 314 is a capacitive storage device. In some cases, the energy storage device 314 battery. In some cases, the energy storage device 314 may include one or more capacitors, batteries, or other types of electricity storage circuitry. A battery may be a nickel-cadmium-based battery, a lithium-ion-based battery, or a battery having some other chemistry. In at least one case the battery is arranged to provide 25,000 milliamp-hours (mAH) of charge at five volts (5V). The inventors have determined, in at least one case, such a battery will power the second embodiment of an electric power industry structure monitor 100b for five years under a determined set of operating conditions, such as reporting a status one time per day, four times per day, or some other periodic number of times per day. The inventors have further determined, and at least one case, when such a battery is supplemented with electricity provided by solar cells, the second embodiment of an electric power industry structure monitor 100b will remain in powered operation for at least ten years under the determined set of operating conditions.

FIG. 6D is a power pole 16 segment having one embodiment of an electric power industry structure monitor 100b arranged as a tilt sensor mounted thereon. FIG. 6E is another power pole 16 segment having another embodiment of an electric power industry structure monitor 100b arranged as a tilt sensor mounted thereon. In some cases, the power pole 16 of FIG. 6D is a high-voltage power pole. In some cases, the power pole 16 of FIG. 6E is a distribution power pole or a streetlight power pole. Other embodiments of structures on which the electric power industry structure monitor 100b are mounted are of course contemplated.

In at least one embodiment, the second embodiment of an electric power industry structure monitor 100b includes one or more of a thermometer circuit, a humidity sensor circuit, a 3-axis accelerometer circuit, a long-term evolution (LTE) based cellular radio circuit, and a GPS circuit, along with at least one processor and memory storing processor executable instructions arranged to direct operations of the second embodiment of an electric power industry structure monitor 100b. The device is mounted on a power pole (FIGS. 6D, 6E) and operates according to the software instructions. In some embodiments, the 3-axis accelerometer circuit is arranged to detect motion due to tilt, sway, deflection, shock, falling, displacement (e.g., a base the structure (e.g., pole) on which the monitor is mounted is flooded), and the like; wherein such motion may be caused by, among other things, wind, earthquake, impact to the structure (e.g., pole) on which the monitor is mounted, flooding, age-related failure, vandalism, and the like.

Such operations may direct the second embodiment of an electric power industry structure monitor 100b to periodically wake up and take environmental readings (e.g., temperature, humidity, air pressure, pollen counts, particulate counts, and the like) using its onboard or otherwise communicatively coupled sensors. The collected data may be stored, analyzed, processed, or the like. The collected data may be communicated to a remote computing device 160. In at least some cases, data is collected several times in a day, but only communicated once per day. Any suitable data collection rates may be selected. Any suitable data communication rates may be selected. These and other settings of the second embodiment of an electric power industry structure monitor 100b may be user selectable via, for example, control settings communicated from the remote computing device 160.

In at least one embodiment, when a second embodiment of an electric power industry structure monitor 100b is installed, a calibration routine is executed so that accelerometer data is arranged to correspond to a known three-dimensional attitude of the power pole 16. In some cases, the calibration routine is only executed after the second embodiment of an electric power industry structure monitor 100b is first powered up after installation on a power pole 16. In some cases, the calibration routine may be executed only after the second embodiment of an electric power industry structure monitor 100b executes a hard reset function. Due to the functionality of the calibration feature, the electric power industry structure monitor 100b may not need to be oriented in a perfectly normal orientation to the ground (i.e., true vertical in 360 degrees). In some cases, the orientation does not even need to be mounted substantially vertically with respect to the ground. For example, some embodiments of the electric power industry structure monitor 100b permit installation (e.g., mounting of the monitor to a pole or other structure) within five degrees (5°), within ten degrees (10°), within 30 degrees (30°) (i.e., substantially normal), within forty-five degrees (45°), or within some other offset from normal (i.e., true vertical in 360 degrees) to the ground. Subsequent to one or more performances of the calibration feature, the electric power industry structure monitor is able to compensate for a non-vertical positioning of the electric power industry structure monitor on the distribution power pole.

In at least one case, when a second embodiment of an electric power industry structure monitor 100b is installed, a location routine is executed so that GPS data is collected to determine a location of the power pole that the second embodiment of an electric power industry structure monitor 100b is attached to. The inventors have recognized, for example, that the GPS circuitry consumes a lot of power relative to other circuitry on the device. The inventors have further recognized that collecting a limited number of GPS position readings (e.g., 3 readings, five readings, ten readings, or another number of readings), is sufficient to provide a location that will not change until the power pole 16, and its corresponding second embodiment of an electric power industry structure monitor 100b, are decommissioned from service. Accordingly, in at least some cases, a second embodiment of an electric power industry structure monitor 100b is arranged to determine a first location via the location circuitry and then further arranged to shut down the location circuitry (e.g., place the location circuitry in a sleep, standby, or other low-power mode, remove power from the location circuitry, or the like) or other limit the power consumed by the location circuitry after the first location is determined. In some cases, the first location is determined only after performing a hard reset on the second embodiment of an electric power industry structure monitor 100b.

In at least some cases, the second embodiment of an electric power industry structure monitor 100b is arranged to provide data in accordance with the description of the data flow embodiment of FIG. 5. In such cases, the second embodiment of an electric power industry structure monitor 100b is arranged to detect a power pole 16 that has been struck by a vehicle, damaged in a storm, subjected to heavy environmental forces (e.g., extreme wind, extreme temperature, extreme rain or flooding, or the like), which compromise the integrity of the power pole and any portions of an electric grid associated with the power pole. Safety of lives and property is improved when such conditions are detected and mitigated before a catastrophe occurs.

FIGS. 7A-7D present an alternate configuration of the second embodiment of an electric power industry structure monitor 100b. FIG. 7A is a perspective view of an alternate second embodiment of an electric power industry structure monitor 100b. The monitor is formed in a tilt-sensor housing 340 that has a substantially triangular cross-section cut across a line perpendicular to a longest linear dimension. Integrated with the housing, the monitor also includes energy harvesting circuitry 306, which in this embodiment is arranged as one or more solar cells.

FIG. 7B is a front-side view of the alternate second embodiment of an electric power industry structure monitor 100b of FIG. 7A. As evident in FIG. 7B, the embodiment includes at least two energy harvesting circuits 306, which in this case are arranged as solar cells. In other cases, the energy harvesting circuits may include internal circuits, external circuits, or internal and external circuits that generate power by converting energy of any suitable form or mechanism (e.g., light, wind, electric field, radiation (i.e., nuclear reaction), stray radio waves, and vibration, oscillation, or other kinetic sources). These energy harvesting circuits may, for example, include inductors, antennas, turbines, magnets, sealed atmospheric chambers, photovoltaics, piezoelectric crystals, wind beams, pyro-electrics, thermo-electrics, electrostatics, or other integrated and discrete structures.

In the alternate second embodiment of FIG. 7, the energy harvesting circuits 306 are integrated in opposing faces of the housing 340. In some of these cases, two solar cell panels 306 are mounted at an opposing angle of between about 60 degrees and 120 degrees, and in at least one case, the opposing angle between the two solar cell panels is about 90 degrees. In some cases, these electric power industry structure monitors 100b of the alternate second embodiment may be mounted on a northern or southern face of a selected power pole.

A single mounting means 342 is arranged through a front-side face of the housing 340. In at least some embodiments, a bracket (not shown in FIG. 7B) is arranged on a power pole, and the alternate configuration of the second embodiment of an electric power industry structure monitor 100b is secured to the bracket via the single mounting means 342. The single mounting means may include a screw, a bolt, a nut, a grommet, a latch, a pressure fit aperture, a pressure fit plug or boss, an adhesive, or some other means. When so arranged, mounting the monitor 100b may be easily performed by a single person or even a machine-automated process.

FIG. 7C is a back-side view of the alternate second embodiment of an electric power industry structure monitor 100b of FIG. 7A. A visible edge of the housing 340 is identified, and a hidden, dashed-line representation of the single mounting means 342 is also identified. An edge of the mounting bracket 344 is identified in FIG. 7C along with a mounting latch 346 that supports the electric power industry structure monitor 100b. A hidden, dashed-line representation of a power button 348 identifies a single, external user interface control of the monitor.

FIG. 7D is a breakout view of the alternate second embodiment of an electric power industry structure monitor 100b of FIG. 7A. A housing top 340a and a housing bottom 340b are each portions of the housing 340 visible in FIGS. 7A-7C. The mounting bracket 344 shown in FIG. 7C is not visible, but portions of mounting bracket screws 350 are visible. The mounting bracket screws 350 are useful for mounting this alternate configuration of the second embodiment of an electric power industry structure monitor 100b to a wood power pole or other penetrable structure. In other embodiments, straps, bolts, latches, or other mounting means are deployed.

The power button 348 is identified in FIG. 7D. An optional level bubble may also be incorporated with the power button 348. In other cases, the optional level bubble may be integrated in another structure of the monitor or in the mounting bracket 344. In still other cases, a different leveling mechanism may be employed for the electric power industry structure monitor 100b. By performing an initial leveling of the monitor, the monitor may perform with a uniform range of tilt or deflection in any direction. If the electric power industry structure monitor 100b is not mounted at or near normal to the ground (i.e., true vertical in 360 degrees), a calibration routine is arranged to correct data readings to true vertical in 360 degrees and determine a vertical orientation of the power pole, but the range of tilt, sway, or other deflection may be limited.

A main circuit board 352 of the alternate second embodiment of an electric power industry structure monitor 100b is identified in FIG. 7D. An energy storage means 354 and an energy storage means holder 356 are mounted to the main circuit board 352. The energy storage means 354 may be a battery, capacitor, or some other energy storage device and its associated circuitry. An antenna structure 358 is mounted inside the tilt sensor housing 340 and communicatively coupled to electronic communication circuitry. The electronic communication circuitry and other electronic control circuitry is not identified to avoid unnecessarily cluttering the figure, but such circuitry in this case is mounted on the main circuit board 352. Such circuitry will include discrete components (e.g., resistors, capacitors, inductors, transistors and other electronic switching devices, clocking circuitry such as a crystal, and the like), integrated components (e.g., at least one processor, at least one memory, clocking circuitry such as a timer, MEMS devices such as a multi-axis accelerometer(s), and the like), and optional components. The optional components may include temperature measurement circuits (e.g., a thermometer), humidity sensors, wind sensors, pressure sensors, microphones, and the like.

FIG. 8 is a schematic of a system that implements a second embodiment of an electric power industry structure monitor 101b. Additionally, or alternatively, the structures of FIG. 8 may be a system that implements a third embodiment of an electric power industry structure monitor 101c.

In at least some cases, the system that implements the second embodiment of an electric power industry structure monitor 101b may be arranged as a tilt sensor. In FIG. 8, a plurality of power poles 16, which are along the lines of the distribution power poles 16b (FIG. 1A), are each arranged with a second embodiment of an electric power industry structure monitor 100b.

In at least some other cases, the system that implements the third embodiment of an electric power industry structure monitor 101c may be arranged as a high-voltage tower monitor. In FIG. 8, a plurality of power poles 16, which are along the lines of the high-voltage power poles 16a (FIG. 1A), are each arranged with a third embodiment of an electric power industry structure monitor 100c.

The second and third embodiments of electric power industry structure monitors 100b, 100c share similar electronic structures to the first embodiment of an electronic power industry structure monitor 100a (FIG. 4). In the schematic of FIG. 8, structures having a same reference number to corresponding structures in FIG. 4 are not further discussed for brevity.

The second and third embodiments of electric power industry structure monitors 100b, 100c are mounted in a suitable way to a power pole 16. Second embodiments of electric power industry structure monitors 100b may be mounted on the power pole 16 at between about 8 feet AGL and about 20 feet AGL, wherein in at least one case, some second embodiments of electric power industry structure monitors 100b are mounted on the power pole 16 at between about 10 feet AGL and about 12 feet AGL. Differently, but along the same lines, third embodiments of electric power industry structure may be mounted on the power pole 16 at between about 50 feet AGL and about 200 feet AGL, wherein in at least one case, some third embodiments of electric power industry structure monitors 100c are mounted on the power pole 16 at between about 50 feet AGL and about 75 feet AGL.

The second and third embodiments of electric power industry structure monitors 100b, 100c may be arranged as self-powering devices. In these cases, the monitors 100b, 100c are electromechanically isolated from a fixed power source. Embodiments may include, for example, power generation structures 328 and power storage structures 330.

In one or more embodiments, the power generation structures 328 may include one or more solar cells, one or more power induction coils, one or more Bismuth Telluride-based thermoelectric modules that generate power based on a temperature differential, and/or one or more modules that generate power based on motion, vibration, moving water, or some other medium. The amount of power generated by the power generation structures 328 may be sufficient to operate other circuitry of the monitors 100b, 100c. Alternatively, or in addition, the amount of power generated may be sufficient to recharge the one or more power storage structures 330 (e.g., capacitors, batteries, and the like).

The present inventors have contemplated several real-world embodiments of a second embodiment of an electric power industry structure monitor 100b arranged as a tilt sensor. A field-system tilt sensor embodiment is now described.

In at least some cases of the field-system tilt sensor embodiment, the monitors 100b are deployed on a plurality (e.g., tens, hundreds, thousands) of power poles 16 or other above-ground-level (AGL) locations. The second embodiment of electric power industry structure monitors 100b are arranged as remotely configurable, solar-powered pole tilt sensors that provide electrical fixture tilt and vibration alerts, real-time status critical operations monitoring, and over-the-air (OTA) firmware upgrades that can be used in an electric power grid on power poles having high-voltage or distribution power voltage power lines (e.g., 10 kV, 50 kV, 500 kV or some other voltage) or lower transmission lines (e.g., 110V, 240V, 480V, or some other voltage).

In at least some cases of the field-system tilt sensor embodiment, the monitors 100b are formed with a solid body housing enclosure that has an IP67 rating. In at least some of these and other cases, the housing is arranged with a small form and fit that permits rapid mounting deployment with multiple attachment options (e.g., adhesives, brackets, magnets, or the like) that provide easily permanent or semi-permanent affixation to wood, metal, and concrete power poles 16.

In at least some cases of the field-system tilt sensor embodiment, the second embodiment of electric power industry structure monitors 100b include a solar power-based power supply that is backed-up with a daylight rechargeable battery. The monitors 100b include an adaptable design that accommodates sensor plug-in connections for devices such as air quality monitors (PM1, PM2.5, and PM10), sound detection sensors, and one or more cameras (e.g., infrared, still image, multimedia motion, or the like having any suitable resolution (e.g., two megapixel resolution)).

In at least some cases of the field-system tilt sensor embodiment, the monitors 100b include wireless radio communication circuitry that supports any desirable number of LTE bands. In at least some cases, the monitors 100b may permit additional radio communication circuitry that comports with a particular protocol such as WISUN mesh networking.

In at least some cases of the field-system tilt sensor embodiment, the monitors 100b include a fixed or configurable reporting and alert package that includes threshold compliance measurements for tilt and vibration detection, photosensor anomaly detection, power management, battery voltage detection, and solar cell health detection. The monitors 100b may optionally include a deployable data integrator software package that facilitates encoding and processing of operational status data for retrieval at an asset management database system deployed on or via a remote computing server. Further still, monitors 100b include analytical data that permits a remote map display of monitor 100b nodes at their GPS coordinates, asset tracking/client authentication, and parameter filtering of device alerts. The monitors 100b may further capture accurate (e.g., within two meters; within three meters, within 10 meters, or some other level of accuracy) GPS telemetry data that permits accurate tracking and identification of damaged or improperly inclined power poles 16, which thereby permits timely response planning.

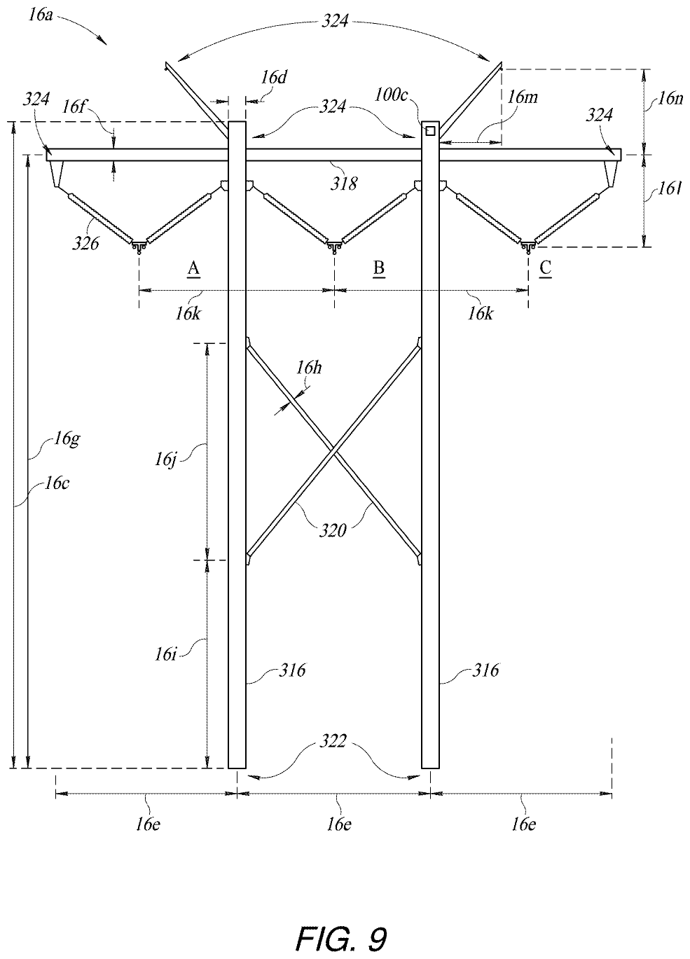

FIG. 9 is an embodiment of a high-voltage power pole 16a. The power pole 16a may be formed substantially of wood, galvanized steel, aluminum, or some other element or combination of elements. The power pole 16a may be installed on a foundation of concrete or another foundational material. Various vertical and other support means of the high-voltage power pole 16a may be fixedly attached, in part, to the ground or sunk into the earth below the ground.

A plurality of dimensions and other features of the high-voltage power pole 16a of FIG. 9 are discussed. A third embodiment of an electric power industry structure monitor 100c, which is arranged as a high-voltage power pole (e.g., tower) monitor, is attached to the high-voltage power pole 16a. The monitor 100c is illustrated at substantially the top of a vertical mast 316 of the high-voltage power pole 16a, but one of skill in the art will recognize that one or more electric power industry structure monitors 100c may be placed at a different location.

In many cases, locations where a third embodiment of an electric power industry structure monitor 100c is mounted on the high-voltage power pole are bathed in a high volume of electromagnetic energy. Accordingly, in some cases, the third embodiment of an electric power industry structure monitor 100c will include additional shielding to prevent disruption or mis-operation of wireless communication circuitry, accelerometer circuitry, inductive circuitry, and other circuitry. The additional or extra shielding may be, for example, thick (e.g., greater than 100 microns). The additional or extra shielding may be, for example, formed of selected metals, metal-alloys, magnetic materials, polymers, and the like. In some cases, the thickness and materials selected for the additional or extra shielding may be tuned to protect against energy fields a selected frequency range as may be found proximal to the electric power passing through wires or cables proximate the third embodiment of an electric power industry structure monitor 100c.

In at least some cases, the additional or extra shielding is selected with a desired permeability. Permeability relates to the ability of any particular material used in the shielding to support the formation of a magnetic field within itself and contain magnetic flux. By containing an increased level of magnetic flux, the extra shielding is able to reduce the amount of undesirable radiated magnetic that reaches the sensitive areas of the monitor circuity.

In at least some cases, the high-voltage power pole 16d includes 2 or more vertically arranged masts 316, each of the vertically arranged masts having a height 16c of between about 50 feet and about 100 feet, with a height of about 105 feet in at least one embodiment. The vertically arranged masts 316 may have a same diameter 16d from top to bottom. Alternatively, in other embodiments, the vertically arranged masts 316 have a larger diameter 16d at the bottom. A diameter 16d at the bottom of the vertically arranged masts may be between about 30 and about 50 inches, and a diameter 16d at the top of the vertically arranged masts 316 may be between about 30 and about 40 inches. In at least one embodiment, the diameter 16d at the bottom of a vertically arranged mast 316 is about 40 inches, and a diameter 16d at the top of the vertically arranged mast 316 is about 34 inches.

In at least some cases the high-voltage power pole 16a includes at least one horizontal crossmember 318 having three suspended sections of the same nominal length 16e, which may be between about 20 feet and about 50 feet, with a nominal length 16e of about 35 feet in at least one embodiment. In at least some cases, the at least one horizontal crossmember 318 has a diameter 16f or width, as the case may be, of between about 12 inches and about 36 inches, with a diameter 16f of about 24 inches in one embodiment.

In at least some cases, the at least one horizontal crossmember is arranged at a height 16g of between about 75 feet and about 125 feet AGL, with a height 16g of about 100 feet in at least one embodiment.

To provide additional stability to the high-voltage power pole 16a, one or more support beams 320 may be arranged in any suitable orientation such as a crossed beam support structure. The support beams 320 may have a diameter 16h or width, as the case may be, of between about six inches and about 18 inches, with a diameter 16h of about 12 inches in one embodiment. In such embodiments, where a crossed beam support structure is employed, first coupling points of the support beams may be at a first support beam height 16i of between about 25 feet and about 45 feet AGL. A first support beam height 16i in one embodiment is about 33 feet. Also in such embodiments, where crossed beam support structures are employed, second coupling points of the support beams may be at a second support beam height 16j of between about 25 feet and about 45 feet above the first support beam height 16i. A second support beam height 16j in one embodiment is about 35 feet above the first support beam height 16i.

In some cases, the high-voltage power pole 16a is arranged to support high-voltage power lines. the high-voltage power lines may carry electricity having a voltage that meets or exceeds 10,000 volts (10 kV), 50,000 volts (50 kV), 100,000 volts (100 kV), 250,000 volts (250 kV), 500,000 volts (500 kV), 1,000,000 volts (1 MV), or some other voltage. The high-voltage power lines may be suspended from the upper portions of the high-voltage power pole 16a at, for example, points A, B, C, where large insulators 326 (e.g., surge arrestors) form mounting points for the high-voltage power lines. The insulators 326 may be coupled to the vertical masts 316, the horizontal crossmember 318, or in any other suitable locations. For safety, and to reduce the likelihood that electricity from one high power line arcs to another high power line or otherwise finds a conduction path through a horizontal crossmember 318 and/or vertical mast 316, the mounting points A, B, C are arranged to provide a safety margin of separation. In at least some embodiments, each mounting point A, B, C, is separated from another mounting point A, B, C, by a first safety distance 16k of between about 30 feet to about 40 feet. In at least one embodiment, the first safety distance 16k is about 35 feet. Correspondingly, in at least some cases, each mounting point A, B, C is separated from the horizontal crossmember 318 by a second safety distance 16l of between about 10 feet and about 20 feet. In at least one embodiment, the second safety distance 16l is about 15 feet.

In some embodiments of the high-voltage power pole 16a, deflection sensors 324 are arranged atop overhead ground wire (OHGW) masts. Such deflection sensors 324 in some embodiments are arranged at a first linear safety distance 16m from the vertical mast 316 of between about five feet and about 15 feet. In one case, the first linear safety distance 16m is about 11 feet. The deflection sensors 324 in these or other embodiments are arranged at a second linear safety distance 16n from the horizontal crossmember 318 of between about 10 feet and about 20 feet. In one case, the second linear safety distance 16n is about 15 feet. In at least some embodiments additional deflection sensors 324 are arranged at opposing ends of the horizontal crossmember 318.

In some embodiments, flood sensors 322 are arranged at the bottom of each vertical mast 316. It has been recognized by the inventors that the provision of safety sensors, such as deflection sensors 324 and flood sensors 322, may provide safety benefits in an electric power grid but the powering and operation of such sensors is sufficiently challenging that these types of sensors are inconsistently deployed and monitored.

To combat known issues with sensors on high-voltage power poles 16a, and to provide even further measures of safety to lives and property, the present inventors have conceived of at least one third embodiment of an electric power industry structure monitor 100c, which is arranged as a high-voltage power pole (e.g., tower) monitor.

The electric power industry structure monitor 100c is arranged to capture vibration information, tilt information, water saturation information associated with the area under the high-voltage power pole 16a, and other information. In at least some cases, the other information may include vandalism information, gunshot detection information, weather information (e.g., temperature, wind, humidity, etc.), environmental condition information (e.g., pollen count, particulate count, avian count, insect count, wild animal count, human being count, vehicle count, etc.), and many more types of information.

In at least some embodiments, the electric power industry structure monitor 100c is powered only by solar energy. That is, the electric power industry structure monitor 100c is void of any physical electrical connection to an external wired power source. An energy storage device, such as a capacitor or a battery, may be integrated within the electric power industry structure monitor 100c to provide power in the absence of light.

In at least one field deployed high-voltage tower monitor embodiment, a plurality of electric power industry structure monitors 100c are installed on a plurality of tens, hundreds, or thousands of high-voltage power poles 16a. The system of high-voltage power poles 16a may be arranged as a 500 kV system of power generation and transport to a network of substations and other end points (FIG. 1A). Any number of the high-voltage power poles 16a may be located in remote areas that do not have any available low power source. Hence, the electric power industry structure monitor 100c, which may be power via solar energy, inductive energy, or some other harvested wireless power source, provides a practical and workable solution to improve public safety (e.g., reliable power delivery, reduced likelihood of wildfires, and the like).

In the field deployed high-voltage tower monitor embodiment under discussion, any number of high-voltage power poles 16a are installed between about 500 feet and about 2500 feet from an adjacent power pole 16a. In such cases, at least some power poles 16a are installed between about 1000 feet and 1500 feet (e.g., about 1300 feet or one-quarter mile) adjacent power pole 16a. In such cases, communications and conductivity presents a challenge. Long-term evolution (LTE) cellular radio may be used to implement one communication solution for the electric power industry structure monitors 100c, and in this case, each monitor 100c will require a subscriber identity module (SIM) card provision for a particular cellular network. In at least some cases, an EC25 based system is implemented by the electric power industry structure monitors 100c wherein an LTE WiFi mesh network is deployed having gateways installed only on some high-voltage power poles 16a (e.g., every other power pole 16a, every five or six power poles 16a, or at some other desired density). In at least some of these or other cases, a citizens broadband radio service (CBRS) architecture is provided (e.g., at a 3.5 GHz frequency that is non-interfering with traditional WiFi), which enables secure point-to-point delivery of wireless digital communications.

In the field deployed high-voltage tower monitor embodiment, the inventors have determined that negative effects of electromagnetic interference (EMI) can be reduced or avoided by implementing particular proposed wireless communication schemes. The inventors have further determined that along these lines, the electric power industry structure monitors 100c can be installed at any desirable location, or a plurality of locations, on a high-voltage power pole 16a. When so deployed, the electric power industry structure monitors 100c may include one or more multimedia sensors that capture optical video information, infrared video information, audio information, and the like at any desire resolution (e.g., 480p, 720p, “hi-def,” 2k, 4k, 8k; 30 frames per second (fps), 60 fps, or some other resolution values). The monitors 100c may further include sensors to capture low power (e.g., less than 1 hour of remaining operable power, less than 20 minutes, less than 5 minutes, less than one minute, or some other indication of low power), accelerometer readings (e.g., to capture tilt information, vibration information, rate of change information, and other information), tilt (e.g., amount of deflection from true vertical in 360 degrees), vibration, weather information (e.g., rainfall, windspeed, humidity, flooding conditions proximal the power pole 16a, and the like), gunshot detection, fire detection, environmental information (e.g., pollen count, particulate count, carbon count, air quality, and the like). In at least some cases, any number of electric power industry structure monitors 100c are arranged with one or more triggerable digital camera devices (e.g., one or more of manually triggered, schedule triggered, event triggered, etc.) and active, once triggered, for a user desirable time (e.g., 5 seconds, 15 seconds, 30 seconds, or some other time frame, which in some cases is configurable).

Having now set forth certain embodiments, further clarification of certain terms used herein may be helpful to providing a more complete understanding of that which is considered inventive in the present disclosure.

Mobile network operators (MNOs) provide wireless cellular-based services in accordance with one or more cellular-based technologies, and in accordance with one or more cellular telecom protocols. As used in the present disclosure, “cellular-based” should be interpreted in a broad sense to include any of the variety of technologies that implement wireless or mobile communications. Exemplary cellular-based systems and protocols include, but are not limited to, time division multiple access (“TDMA”) systems, code division multiple access (“CDMA”) systems, and Global System for Mobile communications (“GSM”) systems. Some others of these technologies are conventionally referred to as UMTS, WCDMA, 4G, 5G, and LTE. Still other cellular-based technologies are also known now or will be known in the future. The underlying cellular-based technologies and corresponding protocols are mentioned here for a clearer understanding of the present disclosure, but the inventive aspects discussed herein are not limited to any particular cellular-based technology unless expressly stated as such.

A mobile device, or mobile computing device, as the terms are used interchangeably herein, is an electronic device provisioned by at least one mobile network operator (MNO) to communicate data through the MNO's cellular-based network. The data may be voice data, short message service (SMS) data, electronic mail, world-wide web or other information conventionally referred to as “internet traffic,” or any other type of electromagnetically communicable information. The data may be digital data or analog data. The data may be packetized or non-packetized. The data may be formed or passed at a particular priority level, or the data may have no assigned priority level at all. A non-comprehensive, non-limiting list of mobile devices is provided to aid in understanding the bounds of the term, “mobile device,” as used herein. Mobile devices (i.e., mobile computing devices) include cell phones, smart phones, flip phone, tablets, phablets, handheld computers, laptop computers, body-worn computers, and the like. Certain other electronic equipment in any form factor may also be referred to as a mobile device when this equipment is provisioned for cellular-based communication on an MNO's cellular-based network. Examples of this other electronic equipment include in-vehicle devices, medical devices, industrial equipment, retail sales equipment, wholesale sales equipment, utility monitoring equipment, and other such equipment used by private, public, government, and other entities.

Mobile devices further have a collection of input/output ports for passing data over short distances to and from the mobile device. For example, serial ports, USB ports, WiFi ports, Bluetooth ports, IEEE 1394 FireWire, and the like can communicatively couple the mobile device to other computing apparatuses.

Mobile devices have a battery or other power source, and they may or may not have a display. In many mobile devices, a signal strength indicator is prominently positioned on the display to provide network communication connectivity information to the mobile device user.

A cellular transceiver is used to couple the mobile device to other communication devices through the cellular-based communication network. In some cases, software and data in a file system are communicated between the mobile device and a computing server via the cellular transceiver. That is, bidirectional communication between a mobile device and a computing server is facilitated by the cellular transceiver. For example, a computing server may download a new or updated version of software to the mobile device over the cellular-based communication network. As another example, the mobile device may communicate any other data to the computing server over the cellular-based communication network.

Each mobile device client has electronic memory accessible by at least one processing unit within the device. The memory is programmed with software that directs the one or more processing units. Some of the software modules in the memory control the operation of the mobile device with respect to generation, collection, and distribution or other use of data. In some cases, software directs the collection of individual datums, and in other cases, software directs the collection of sets of data.

Software may include a fully executable software program, a simple configuration data file, a link to additional directions, or any combination of known software types. When the computing server updates the software of a mobile device, the update may be small or large. For example, in some cases, a computing server downloads a small configuration data file to a mobile device as part of software, and in other cases, the computing server completely replaces all of the present software on the mobile device with a fresh version. In some cases, software, data, or software and data is encrypted, encoded, and/or otherwise compressed for reasons that include security, privacy, data transfer speed, data cost, or the like.

Database structures, if any are present in the distribution transformer monitoring systems described herein, may be formed in a single database or multiple databases. In some cases, hardware or software storage repositories are shared amongst various functions of the particular system or systems to which they are associated. A database may be formed as part of a local system or local area network. Alternatively, or in addition, a database may be formed remotely, such as within a distributed “cloud” computing system, which would be accessible via a wide area network or some other network.

Processing devices, which may also be referred to in the present disclosure as “processing circuits,” “processors,” or another like term, include central processing units (CPU's), microprocessors, microcontrollers (MCU), digital signal processors (DSP), application specific integrated circuits (ASIC), state machines, and the like. One or more processors working cooperatively may be referred to in the singular (e.g., as a processor) without departing from the inventive concepts disclosed herein. Accordingly, a processor as described herein includes any device, system, or part thereof that controls at least one operation, and such a device may be implemented in hardware, firmware, or software, or some combination of at least two of the same. The functionality associated with any particular processor may be centralized or distributed, whether locally or remotely. A processor may interchangeably refer to any type of electronic control circuitry configured to execute programmed software instructions. The programmed instructions may be high-level software instructions, compiled software instructions, assembly-language software instructions, object code, binary code, micro-code, or the like. The programmed instructions may reside in internal or external memory or may be hard-coded as a state machine or set of control signals. According to methods and devices referenced herein, one or more embodiments describe software executable by the processor or processing circuit, which when executed, carries out one or more of the method acts taught in the present disclosure.

The present application discusses several embodiments that include or otherwise cooperate with one or more computing devices. It is recognized that these computing devices are arranged to perform one or more algorithms to implement various concepts taught herein. Each of said algorithms is understood to be a finite sequence of steps for solving a logical or mathematical problem or performing a task. Any or all of the algorithms taught in the present disclosure may be demonstrated by formulas, flow charts, data flow diagrams, narratives in the specification, and other such means as evident in the present disclosure. Along these lines, the structures to carry out the algorithms disclosed herein include at least one processing device executing at least one software instruction retrieved from at least one memory device. The structures may, as the case may be, further include suitable input circuits known to one of skill in the art (e.g., keyboards, buttons, memory devices, communication circuits, touch screen inputs, and any other integrated and peripheral circuit inputs (e.g., accelerometers, thermometers, light detection circuits and other such sensors)), suitable output circuits known to one of skill in the art (e.g., displays, light sources, audio devices, tactile devices, control signals, switches, relays, and the like), and any additional circuits or other structures taught in the present disclosure. To this end, every invocation of means or step plus function elements in any of the claims, if so desired, will be expressly recited.

In some cases, the processor or processors described in the present disclosure, and additionally more or fewer circuits of the exemplary computing devices described in the present disclosure, may be provided in an integrated circuit. In some embodiments, all of the elements shown in the processors of the present figures (e.g., processors 162 of FIGS. 4, 8) may be provided in an integrated circuit. In alternative embodiments, one or more of the arrangements depicted in the present figures may be provided by two or more integrated circuits. Some embodiments may be implemented by one or more dies. The one or more dies may be packaged in the same or different packages. Some of the depicted components may be provided outside of an integrated circuit or die.

The processors shown in the present figures and described herein may be fixed at design time in terms of one or more of topology, maximum available bandwidth, maximum available operations per unit time, maximum parallel execution units, and other such parameters. Some embodiments of the processors may provide re-programmable functionality (e.g., reconfiguration of embedded processor modules and features to implement an artificial intelligence engine as taught herein) at run-time. Some or all of the re-programmable functionality may be configured during one or more initialization stages. Some or all of the re-programmable functionality may be configured, re-configured, or otherwise configured in real time with no latency, maskable latency, or an acceptable level of latency.

As known by one skilled in the art, a computing device, including a mobile computing device, has one or more memories, and each memory may comprise any combination of volatile and non-volatile computer-readable media for reading and writing. Volatile computer-readable media includes, for example, random access memory (RAM). Non-volatile computer-readable media includes, for example, any one or more of read only memory (ROM), magnetic media such as a hard-disk, an optical disk, a flash memory device, a CD-ROM, and the like. In some cases, a particular memory is separated virtually or physically into separate areas, such as a first memory, a second memory, a third memory, etc. In these cases, it is understood that the different divisions of memory may be in different devices or embodied in a single memory. Some or all of the stored contents of a memory may include software instructions executable by a processor to carry out one or more particular acts.

In the present disclosure, memory may be used in one configuration or another. The memory may be configured to store data. In the alternative or in addition, the memory may be a non-transitory computer readable medium (CRM) wherein the CRM is configured to store instructions executable by a processor. The instructions may be stored individually or as groups of instructions in files. The files may include functions, services, libraries, and the like. The files may include one or more computer programs or may be part of a larger computer program. Alternatively, or in addition, each file may include data or other computational support material useful to carry out the computing functions of the systems, methods, and apparatus described in the present disclosure.

The computing devices illustrated herein may further include operative software found in a conventional computing device such as an operating system or task loop, software drivers to direct operations through I/O circuitry, networking circuitry, and other peripheral component circuitry. In addition, the computing devices may include operative application software such as network software for communicating with other computing devices, database software for building and maintaining databases, and task management software where appropriate for distributing the communication and/or operational workload amongst various processors. In some cases, the computing device is a single hardware machine having at least some of the hardware and software listed herein, and in other cases, the computing device is a networked collection of hardware and software machines working together in a server farm to execute the functions of one or more embodiments described herein. Some aspects of the conventional hardware and software of the computing device are not shown in the figures for simplicity.

Amongst other things, at least certain ones of the exemplary computing devices of the present disclosure (e.g., computing server 160 and certain portions of the distribution transformer monitor 100b in FIG. 8) may be configured in any type of mobile or stationary computing device such as a remote cloud computer, a computing server, a smartphone, a tablet, a laptop computer, a wearable device (e.g., eyeglasses, jacket, shirt, pants, socks, shoes, other clothing, hat, helmet, other headwear, wristwatch, bracelet, pendant, other jewelry), vehicle-mounted device (e.g., train, plane, helicopter, unmanned aerial vehicle, unmanned underwater vehicle, unmanned land-based vehicle, automobile, motorcycle, bicycle, scooter, hover-board, other personal or commercial transportation device), industrial device (e.g., factory robotic device, home-use robotic device, retail robotic device, office-environment robotic device), or the like. Accordingly, the computing devices include other components and circuitry that is not illustrated, such as, for example, a display, a network interface, memory, one or more central processors, camera interfaces, audio interfaces, and other input/output interfaces. In some cases, the exemplary computing devices may also be configured in a different type of low-power device such as a mounted video camera, an Internet-of-Things (IoT) device, a multimedia device, a motion detection device, an intruder detection device, a security device, a crowd monitoring device, or some other device.

Input/output (I/O) circuitry and user interface (UI) modules include serial ports, parallel ports, universal serial bus (USB) ports, IEEE 802.11 transceivers and other transceivers compliant with protocols administered by one or more standard-setting bodies, displays, projectors, printers, keyboards, computer mice, microphones, micro-electro-mechanical (MEMS) devices such as accelerometers, and the like.

Buttons, keypads, computer mice, memory cards, serial ports, bio-sensor readers, touch screens, and the like may individually or in cooperation be useful to a user installing, maintaining, operating, overseeing, managing, or otherwise interested in the distribution transformer monitors of the present disclosure. The devices may, for example, input control information into the system. Displays, printers, memory cards, LED indicators, temperature sensors, audio devices (e.g., speakers, piezo device, etc.), vibrators, and the like are all useful to present output information to users of the distribution transformer monitors taught in the present disclosure. In some cases, the input and output devices are directly coupled to one or more processors 162 (FIGS. 4, 8) and electronically coupled to a processor or other operative circuitry. In other cases, the input and output devices pass information via one or more communication ports (e.g., RS-232, RS-485, infrared, USB, etc.).

In at least one embodiment, devices such as the computing server 160 and electric power industry structure monitors 100a, 100b, 100c may communicate with other devices via communication over a network. The network may involve an Internet connection or some other type of local area network (LAN) or wide area network (WAN). Non-limiting examples of structures that enable or form parts of a network include, but are not limited to, an Ethernet, twisted pair Ethernet, digital subscriber loop (DSL) devices, wireless LAN, Wi-Fi, 4G, LTE, 5G, or the like.

FIG. 5 is a data flow diagram 200 illustrating one or more non-limiting processes that may be used by embodiments of computing devices such as the electric power industry structure monitors 100a, 100b, 100c deployed on a light pole, power pole, in a vault, or in some other setting. In this regard, each described process may represent a module, segment, or portion of code, which comprises one or more executable instructions for implementing the specified logical function(s). It should also be noted that in some implementations, the functions noted in the process may occur in a different order, may include additional functions, may occur concurrently, and/or may be omitted.

The figures in the present disclosure illustrate portions of one or more non-limiting computing device embodiments such as one or more components of computing servers 160 and one or more components of the particular electric power industry structure monitor 100a, 100b, 100c. The computing devices may include operative hardware found in conventional computing device apparatuses such as one or more processors, volatile and non-volatile memory, serial and parallel input/output (I/O) circuitry compliant with various standards and protocols, wired and/or wireless networking circuitry (e.g., a communications transceiver), one or more user interface (UI) modules, logic, and other electronic circuitry.

The present application discusses several embodiments that include or otherwise cooperate with one or more computing devices. It is recognized that these computing devices are arranged to perform one or more algorithms to implement the inventive concepts taught herein. Each of said algorithms is understood to be a finite sequence of steps for solving a logical or mathematical problem or performing a task. Any or all of the algorithms taught in the present disclosure may be demonstrated by formulas, flow charts, data flow diagrams, narratives in the specification, and other such means as evident in the present disclosure. Along these lines, the structures to carry out the algorithms disclosed herein include at least one processor executing at least one software instruction retrieved from at least one memory device. The structures may, as the case may be, further include suitable input circuits known to one of skill in the art (e.g., keyboards, buttons, memory devices, communication circuits, touch screen inputs, and any other integrated and peripheral circuit inputs (e.g., accelerometers, thermometers, light detection circuits and other such sensors)), suitable output circuits known to one of skill in the art (e.g., displays, light sources, audio devices, tactile devices, control signals, switches, relays, and the like), and any additional circuits or other structures taught in the present disclosure. To this end, every invocation of means or step plus function elements in any of the claims, if so desired, will be expressly recited.

As used in the present disclosure, the term “module” refers to an application specific integrated circuit (ASIC), an electronic circuit, a processor and a memory operative to execute one or more software or firmware programs, combinational logic circuitry, or other suitable components (hardware, software, or hardware and software) that provide the functionality described with respect to the module.

The terms, “real-time” or “real time,” as used herein and in the claims that follow, are not intended to imply instantaneous processing, transmission, reception, or otherwise as the case may be. Instead, the terms, “real-time” and “real time” imply that the activity occurs over an acceptably short period of time (e.g., over a period of microseconds or milliseconds), and that the activity may be performed on an ongoing basis (e.g., recording and reporting the collection of utility grade power metering data, recording and reporting IoT data, crowd control data, anomalous action data, and the like). An example of an activity that is not real-time is one that occurs over an extended period of time (e.g., hours or days)] or that occurs based on intervention or direction by a person or other activity.

In the absence of any specific clarification related to its express use in a particular context, where the terms “substantial” or “about” in any grammatical form are used as modifiers in the present disclosure and any appended claims (e.g., to modify a structure, a dimension, a measurement, or some other characteristic), it is understood that the characteristic may vary by up to 30 percent. For example, a distribution transformer monitor housing may be described as being mounted “substantially vertical,” In these cases, a device that is mounted exactly vertical is mounted along an “X” axis and a “Y” axis that is normal (i.e., 90 degrees or at right angle) to a plane or line formed by a “Z” axis. Different from the exact precision of the term, “vertical,” and the use of “substantially” or “about” to modify the characteristic permits a variance of the particular characteristic by up to 30 percent. As another example, a distribution transformer monitor housing having a particular linear dimension of between about five (5) inches and fourteen (14) inches includes such devices in which the linear dimension varies by up to 30 percent. Accordingly, the particular linear dimension of the distribution transformer monitor housing may be between 0.8 inches and 18.2 inches.

Where a range of values is provided, it is understood that each intervening value, to the tenth of the unit of the lower limit unless the context clearly dictates otherwise, between the upper and lower limit of that range and any other stated or intervening value in that stated range is encompassed within the invention. The upper and lower limits of these smaller ranges may independently be included in the smaller ranges is also encompassed within the invention, subject to any specifically excluded limit in the stated range. Where the stated range includes one or both of the limits, ranges excluding either or both of those included limits are also included in the invention.

Unless defined otherwise, the technical and scientific terms used herein have the same meaning as commonly understood by one of ordinary skill in the art to which this invention belongs. Although any methods and materials similar or equivalent to those described herein can also be used in the practice or testing of the present invention, a limited number of the exemplary methods and materials are described herein.

In the present disclosure, when an element (e.g., component, circuit, device, apparatus, structure, layer, material, or the like) is referred to as being “on,” “coupled to,” or “connected to” another element, the elements can be directly on, directly coupled to, or directly connected to each other, or intervening elements may be present. In contrast, when an element is referred to as being “directly on,” “directly coupled to,” or “directly connected to” another element, there are no intervening elements present.

The terms “include” and “comprise” as well as derivatives and variations thereof, in all of their syntactic contexts, are to be construed without limitation in an open, inclusive sense, (e.g., “including, but not limited to”). The term “or,” is inclusive, meaning and/or. The phrases “associated with” and “associated therewith,” as well as derivatives thereof, can be understood as meaning to include, be included within, interconnect with, contain, be contained within, connect to or with, couple to or with, be communicable with, cooperate with, interleave, juxtapose, be proximate to, be bound to or with, have, have a property of, or the like.

Unless the context requires otherwise, throughout the specification and claims which follow, the word “comprise” and variations thereof, such as, “comprises” and “comprising,” are to be construed in an open, inclusive sense, e.g., “including, but not limited to.”

Reference throughout this specification to “one embodiment” or “an embodiment” and variations thereof means that a particular feature, structure, or characteristic described in connection with the embodiment is included in at least one embodiment. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

In the present disclosure, the terms first, second, etc., may be used to describe various elements, however, these elements are not be limited by these terms unless the context clearly requires such limitation. These terms are only used to distinguish one element from another. For example, a first machine could be termed a second machine, and, similarly, a second machine could be termed a first machine, without departing from the scope of the inventive concept.

As used in this specification and the appended claims, the singular forms “a,” “an,” and “the” include plural referents unless the content and context clearly dictates otherwise. It should also be noted that the conjunctive terms, “and” and “or” are generally employed in the broadest sense to include “and/or” unless the content and context clearly dictates inclusivity or exclusivity as the case may be. In addition, the composition of “and” and “or” when recited herein as “and/or” is intended to encompass an embodiment that includes all of the associated items or ideas and one or more other alternative embodiments that include fewer than all of the associated items or ideas.

In the present disclosure, conjunctive lists make use of a comma, which may be known as an Oxford comma, a Harvard comma, a serial comma, or another like term. Such lists are intended to connect words, clauses or sentences such that the thing following the comma is also included in the list.

As described herein, for simplicity, a user is in some case described in the context of the male gender. For example, the terms “his,” “him,” and the like may be used. It is understood that a user can be of any gender, and the terms “he,” “his,” and the like as used herein are to be interpreted broadly inclusive of all known gender definitions.

As the context may require in this disclosure, except as the context may dictate otherwise, the singular shall mean the plural and vice versa; all pronouns shall mean and include the person, entity, firm or corporation to which they relate; and the masculine shall mean the feminine and vice versa.

When so arranged as described herein, each computing device may be transformed from a generic and unspecific computing device to a combination device comprising hardware and software configured for a specific and particular purpose. When so arranged as described herein, to the extent that any of the inventive concepts described herein are found by a body of competent adjudication to be subsumed in an abstract idea, the ordered combination of elements and limitations are expressly presented to provide a requisite inventive concept by transforming the abstract idea into a tangible and concrete practical application of that abstract idea.

The embodiments described herein use computerized technology to improve the monitoring and safety of electric power industry structure such as power poles and distribution transformers, but other techniques and tools remain available to monitor such structures. Therefore, the claimed subject matter does not foreclose the whole or even substantial electric power industry structure monitoring technological area. The innovation described herein uses both new and known building blocks combined in new and useful ways along with other structures and limitations to create something more than has heretofore been conventionally known. The embodiments improve on computing systems which, when un-programmed or differently programmed, cannot perform or provide the specific electric power industry structure monitor features claimed herein. The embodiments described in the present disclosure improve upon known electrical device monitoring processes and techniques. The computerized acts described in the embodiments herein are not purely conventional and are not well understood. Instead, the acts are new to the industry. Furthermore, the combination of acts as described in conjunction with the present embodiments provides new information, motivation, and business results that are not already present when the acts are considered separately. There is no prevailing, accepted definition for what constitutes an abstract idea. To the extent the concepts discussed in the present disclosure may be considered abstract, the claims present significantly more tangible, practical, and concrete applications of said allegedly abstract concepts. And said claims also improve previously known computer-based systems that perform electrical device monitoring operations.

The headings and Abstract of the Disclosure provided herein are for convenience only and do not limit or interpret the scope or meaning of the embodiments.

The various embodiments described above can be combined to provide further embodiments. Aspects of the embodiments can be modified, if necessary, to employ concepts of the various patents, application and publications to provide yet further embodiments.

In the embodiments of present disclosure, one or more particular sensors are arranged to generate data associated with certain conditions that exist in and around electric power industry structures such as a distribution transformer. The various components and devices of the embodiments are interchangeably described herein as “coupled,” “connected,” “attached,” and the like. It is recognized that once assembled, the system may be suitably sealed and suitably arranged to detect pressure in a distribution transformer vessel, to prevent oil from escaping a distribution transformer vessel, or to provide other determined features. The materials and the junctions formed at the point where two or more structures meet in the present embodiments are sealed or otherwise joined to a mechanically, electrically, or otherwise industrially acceptable level.

The electric power industry structure monitoring systems described in the present disclosure provide several technical effects and advances to the field of electrical device monitoring.

Technical effects and benefits include the ability to improve the reliability and safety of the power grid by monitoring the internal and external operations of a distribution transformer in real time. For example, in at least one embodiment, sensors, such as infrared sensors, can be arranged outside of a distribution transformer vessel to monitor the internal temperature of various portions of the vessel. By monitoring the internal temperature, it can be learned in real time whether or not there is sufficient oil in a distribution transformer vessel and thereby prevent an explosion of the distribution transformer vessel if the oil level drops to low. In at least one embodiment, a pressure sensor can be arranged to monitor the internal pressure of a distribution transformer vessel. Monitoring the internal pressure is enabled via a pressure conveyance adapter. In at least one embodiment, sensors, such as audio sensors or infrared sensors, can be arranged to monitor operation of a surge arrestor. If the surge arrestor is used beyond a threshold number of times, and alert can be sent that indicates a possible future failure of the surge arrestor. In addition, or in the alternative, if the continuity of a surge arrestor is determined to have been broken, and more urgent alert can be sent that indicates that an imminent failure of the surge arrestor is possible.

The present disclosure sets forth details of various structural embodiments that may be arranged to carry the teaching of the present disclosure. By taking advantage of the flexible circuitry, mechanical structures, computing architecture, and communications means described herein, a number of exemplary devices and systems are now disclosed.

Example A-1 is an electric power industry structure monitor, comprising: a housing arranged for positioning on an electric power industry structure; a sensor arranged in the housing, the sensor positioned to generate digital data associated with at least one environmental condition that exists proximal to the electric power industry structure monitor; and a processing circuit arranged to determine from the generated digital data that the at least one environmental condition has crossed a threshold.

Example A-2 may include the subject matter of Example A-1, and alternatively or additionally any other example herein, wherein the electric power industry structure is a distribution transformer.

Example A-3 may include the subject matter of Example A-1 or A-2, and alternatively or additionally any other example herein, wherein the electric power industry structure is a distribution power pole, the distribution power pole arranged to support electric power transmission lines that carry electricity having a voltage of 600 volts (600V) or less.

Example A-4 may include the subject matter of Example A-1 to A-3, and alternatively or additionally any other example herein, wherein the electric power industry structure is a distribution power pole, the distribution power pole arranged to support electric power transmission lines that carry electricity having a voltage of 480 volts (480V) or less.

Example A-5 may include the subject matter of Example A-1 to A-4, and alternatively or additionally any other example herein, wherein the electric power industry structure is a distribution power pole, the distribution power pole arranged to support electric power transmission lines that carry electricity having a voltage of 240 volts (240V) or less.

Example A-6 may include the subject matter of Example A-1 to A-5, and alternatively or additionally any other example herein, wherein the electric power industry structure is a high-voltage power pole, the high-voltage power pole arranged to support electric power transmission lines that carry electricity having a voltage of ten thousand volts (10 kV) or more.

Example A-7 may include the subject matter of Example A-1 to A-6, and alternatively or additionally any other example herein, wherein the electric power industry structure is a high-voltage power pole, the high-voltage power pole arranged to support electric power transmission lines that carry electricity having a voltage of fifty thousand volts (50 kV) or more.

Example A-8 may include the subject matter of Example A-1 to A-7, and alternatively or additionally any other example herein, wherein the electric power industry structure is a high-voltage power pole, the high-voltage power pole arranged to support electric power transmission lines that carry electricity having a voltage of one hundred thousand volts (100 kV) or more.

Example A-9 may include the subject matter of Example A-1 to A-8, and alternatively or additionally any other example herein, wherein the electric power industry structure is a high-voltage power pole, the high-voltage power pole arranged to support electric power transmission lines that carry electricity having a voltage of two hundred fifty thousand volts (250 kV) or more.

Example A-10 may include the subject matter of Example A-1 to A-9, and alternatively or additionally any other example herein, wherein the electric power industry structure is a high-voltage power pole, the high-voltage power pole arranged to support electric power transmission lines that carry electricity having a voltage of five hundred thousand volts (500 kV) or more.

Example A-11 may include the subject matter of Example A-1 to A-10, and alternatively or additionally any other example herein, wherein the electric power industry structure monitor is arranged as a distribution transformer monitor.

Example A-12 may include the subject matter of Example A-1 to A-11, and alternatively or additionally any other example herein, wherein the electric power industry structure monitor is arranged as a tilt sensor.

Example A-13 may include the subject matter of Example A-1 to A-12, and alternatively or additionally any other example herein, wherein the electric power industry structure monitor is a high-voltage power pole monitor.

Example B-1 is a distribution transformer monitor system, comprising: a housing arranged for positioning on a distribution transformer; a first audio recording device positioned within the housing to capture first sound samples about a first wall portion of the distribution transformer, the first wall portion being a portion of the distribution transformer below a top level of nonconductive medium located in the distribution transformer; a second audio recording device positioned within the housing to capture second sound samples about a second wall portion of the distribution transformer, the second wall portion being a portion of the distribution transformer above a top level of the nonconductive medium located in the distribution transformer; and a controller arranged to aggregate the first sound samples and aggregate the second sound samples, the controller further arranged to generate a digital signature based on the aggregated first and second sound symbols.

Example B-2 may include the subject matter of Example B-1, and alternatively or additionally any other example herein, wherein the controller is arranged to: generate third sound samples and fourth sound samples, generate a second digital signature based on the third and fourth sound samples, and compare the generated digital signature to the generated second digital signature.

Example C-1 is an electric power industry structure monitor, comprising: a housing; a signal conduction means; a securing means; and an operational testing means.

Example C-3 may include the subject matter of Example C-1 to C-2, and alternatively or additionally any other example herein, wherein the electric power industry structure monitor is.

Example C-4 may include the subject matter of Example C-1 to C-3, and alternatively or additionally any other example herein, wherein the housing is between about four inches long (4 in.) and about fourteen inches long (14 in.).

Example C-5 may include the subject matter of Example C-1 to C-4, and alternatively or additionally any other example herein, wherein the housing is between about two inches wide (2 in.) and about seven inches wide (7 in.).

Example C-6 may include the subject matter of Example C-1 to C-5, and alternatively or additionally any other example herein, wherein the housing is between about one inch tall (1 in.) and about six inches tall (6 in.).

Example C-7 may include the subject matter of Example C-1 to C-6, and alternatively or additionally any other example herein, wherein the housing may include one or more chambers to contain any number of electronic circuits.

Example C-8 may include the subject matter of Example C-1 to C-7, and alternatively or additionally any other example herein, wherein the housing may include one or more chambers to contain any number of sensors.

Example C-9 may include the subject matter of Example C-1 to C-8, and alternatively or additionally any other example herein, wherein the housing may include a processing circuit or two or more processing circuits working cooperatively.

Example C-10 may include the subject matter of Example C-1 to C-9, and alternatively or additionally any other example herein, wherein the housing may include one or more cameras, and/or one or more audio circuits (e.g., microphone), and/or one or more accelerometer circuits, and/or one or more temperature (e.g., thermometer) circuits, and/or one or more current detection (e.g., Rogowski) circuits, and/or one or more location (e.g., global positioning system (GPS)) circuits, and/or one or more transceiver circuits, and/or one or more human interface device (HID) circuits, and/or any other suitable circuits.

Example C-11 may include the subject matter of Example C-1 to C-10, and alternatively or additionally any other example herein, wherein the housing may be formed of any suitable material or combination of materials.

Example C-12 may include the subject matter of Example C-1 to C-11, and alternatively or additionally any other example herein, wherein the housing may be formed from any one or more of a steel-based material, an aluminum-based material, an alloy, fiberglass, plastic resin material, a composite material, a glass-filled material, a nylon material, a polycarbonate material, a heat stabilizing material, a heat conductive material, an electrical insulator material, an ultraviolet (UV) radiation resistant material, or any other metallic and non-metallic materials.

Example C-13 may include the subject matter of Example C-1 to C-12, and alternatively or additionally any other example herein, wherein the housing is substantially formed from a material that is substantially non-conductive electrically.

Example C-14 may include the subject matter of Example C-1 to C-13, and alternatively or additionally any other example herein, wherein the housing is formed from a material having an operating range that includes at least 140 degrees Fahrenheit.

Example C-15 may include the subject matter of Example C-1 to C-14, and alternatively or additionally any other example herein, wherein the housing may be internally coated, externally coated, internally and externally coated, or not coated at all

Example C-16 may include the subject matter of Example C-1 to C-15, and alternatively or additionally any other example herein, wherein the housing may include a coating and the coating, if applied, may be partial coating or a complete coating, and the coating, if applied, may be arranged as any suitable number of layers, and the coating, if applied, may be a paint, a dye, a polymer, or some other suitable material, and the coating, if applied, may be sprayed, anodized, sputtered, brushed, immersed, layered, baked-on, or formed from some other suitable process, and the coating, if applied, may be arranged as a protective barrier, and the barrier, if so arranged, may be a barrier to protect against weather elements (e.g., low temperature such as below 32 degrees Fahrenheit, high temperature such as above 90 degrees Fahrenheit, wind, moisture such as by rain, humidity, fog, snow, and the like), animal damage, insect damage, vandalism, and any other physical assaults.

Example C-17 may include the subject matter of Example C-1 to C-16, and alternatively or additionally any other example herein, wherein the signal conduction means is formed in some cases in three distinct sections.

Example C-18 may include the subject matter of Example C-1 to C-17, and alternatively or additionally any other example herein, wherein the signal conduction means has more than three distinct sections.

Example C-19 may include the subject matter of Example C-1 to C-18, and alternatively or additionally any other example herein, wherein the signal conduction means has fewer than three distinct sections.

Example C-20 may include the subject matter of Example C-1 to C-19, and alternatively or additionally any other example herein, wherein the signal conduction means is arranged entirely within the housing.

Example C-21 may include the subject matter of Example C-1 to C-20, and alternatively or additionally any other example herein, wherein the signal conduction means may conduct power, control signals, or power and control signals.

Example C-22 may include the subject matter of Example C-1 to C-21, and alternatively or additionally any other example herein, wherein the signal conduction means may have a one, two, or any number of separate and distinct conductors.

Example C-23 may include the subject matter of Example C-1 to C-22, and alternatively or additionally any other example herein, wherein individual conductors of the signal conduction means may be formed of solid wire, stranded wire, or some other conduit.

Example C-24 may include the subject matter of Example C-1 to C-23, and alternatively or additionally any other example herein, wherein some or all of the conductors of a signal conduction means may have the same structure (e.g., stranded, solid, or the like), the same conductive material (e.g., copper, aluminum, or the like), the same insulative material (e.g., plastic, rubber, silicone, or the like), and the same dimensions (e.g., gauge, diameter, or the like).

Example C-25 may include the subject matter of Example C-1 to C-24, and alternatively or additionally any other example herein, wherein some or all of the conductors of a signal conduction means may have different structure, conductive material, insulative material, dimensions, or any other parameters.

Example C-26 may include the subject matter of Example C-1 to C-25, and alternatively or additionally any other example herein, wherein some portion of a signal conduction means 104a may be formed with one or more transceivers arranged for wireless communications.

Example C-27 may include the subject matter of Example C-1 to C-26, and alternatively or additionally any other example herein, wherein the signal conduction means includes two separate and distinct conductors arranged to provide power into the housing.

Example C-28 may include the subject matter of Example C-1 to C-27, and alternatively or additionally any other example herein, wherein the signal conduction means includes two other or additional separate and distinct conductors to carry signals that represent current flowing through a distribution transformer located in an associated distribution transformer vessel.

Example C-29 may include the subject matter of Example C-1 to C-28, and alternatively or additionally any other example herein, wherein the signal conduction means may be any certain and useful length and any certain and useful shape.

Example C-30 may include the subject matter of Example C-1 to C-29, and alternatively or additionally any other example herein, wherein the signal conduction means is arranged to “wrap” around a substantially cylindrical distribution transformer vessel having certain dimensions.

Example C-31 may include the subject matter of Example C-1 to C-30, and alternatively or additionally any other example herein, wherein the signal conduction means is arranged with defined dimensions and shapes for a particular distribution transformer vessel

Example C-32 may include the subject matter of Example C-1 to C-31, and alternatively or additionally any other example herein, wherein the signal conduction means is arranged with flexible dimensions and shapes suitable for adaptation to a plurality of distribution transformer vessels.

Example C-33 may include the subject matter of Example C-1 to C-32, and alternatively or additionally any other example herein, wherein the electric power industry structure monitor includes a single securing means 106a.

Example C-34 may include the subject matter of Example C-1 to C-33, and alternatively or additionally any other example herein, wherein the electric power industry structure monitor includes zero, two, or some other number of securing means

Example C-35 may include the subject matter of Example C-1 to C-34, and alternatively or additionally any other example herein, wherein the securing means is arranged to fixedly or removably couple one or more structures such as a signal conduction means and an operational testing means to a distribution transformer vessel.

Example C-36 may include the subject matter of Example C-1 to C-35, and alternatively or additionally any other example herein, wherein the signal securing means in some cases is formed from a magnet or magnetic material.

Example C-37 may include the subject matter of Example C-1 to C-36, and alternatively or additionally any other example herein, wherein the signal securing means may be arranged with a chemical adhesive (e.g., glue, epoxy, or the like), a clamp, a weld, screws, bolts, a shaped compartment, or any other suitable bonding structure.

Example C-38 may include the subject matter of Example C-1 to C-37, and alternatively or additionally any other example herein, wherein the at least one operational testing means includes a circuit to detect, measure, or otherwise determine the presence and in some cases the amount of electromagnetic energy associated with a distribution transformer. In at least one case, the operational testing means 108a includes a Rogowski coil circuit.

Example C-39 may include the subject matter of Example C-1 to C-38, and alternatively or additionally any other example herein, wherein the at least one operational testing means includes a Rogowski coil circuit.

Example C-40 may include the subject matter of Example C-1 to C-39, and alternatively or additionally any other example herein, wherein materials and coatings used or otherwise available to form the housing may also be used to form one or more protective structures about the signal conduction means, the securing means, and the operational testing means.

Example C-41 may include the subject matter of Example C-1 to C-40, and alternatively or additionally any other example herein, wherein the housing of the electric power industry structure monitor may be arranged to resist environmental damage, nuisance damage (e.g., animals, insects, human vandalism), and the like.

Example C-42 may include the subject matter of Example C-1 to C-41, and alternatively or additionally any other example herein, wherein the housing of the electric power industry structure monitor may be arranged via color, shape, texture, and the like to blend with a distribution transformer vessel environment and thereby be unobtrusive, un-noticeable, or otherwise unremarkable.

Example C-43 may include the subject matter of Example C-1 to C-42, and alternatively or additionally any other example herein, wherein the housing of the electric power industry structure monitor may be arranged to stand out from an associated distribution transformer vessel and thereby be easily noticed, wherein such notice can signal to an observer that the distribution transformer is being monitored.

Example C-44 may include the subject matter of Example C-1 to C-43, and alternatively or additionally any other example herein, wherein the housing of the electric power industry structure monitor is magnetically mounted to a distribution transformer vessel

Example C-45 may include the subject matter of Example C-1 to C-44, and alternatively or additionally any other example herein, wherein the housing of the electric power industry structure monitor is positioned about a pressure conveyance adapter

Example C-46 may include the subject matter of Example C-1 to C-45, and alternatively or additionally any other example herein, wherein a locking collar secures the housing of the electric power industry structure monitor to the distribution transformer vessel.

Example C-47 may include the subject matter of Example C-1 to C-46, and alternatively or additionally any other example herein, wherein a locking collar secures the housing of the electric power industry structure monitor to the distribution transformer vessel and a pressure relief valve 114 is rotatably positioned in the pressure conveyance adapter.

Example C-48 may include the subject matter of Example C-1 to C-47, and alternatively or additionally any other example herein, wherein a right-angle indicator legend is provided to facilitate placement of the electric power industry structure monitor.

Example C-49 may include the subject matter of Example C-1 to C-48, and alternatively or additionally any other example herein, wherein a right-angle indicator legend provided to facilitate placement of the electric power industry structure monitor is a virtual legend that is not be visible on the distribution transformer vessel.

Example C-50 may include the subject matter of Example C-1 to C-49, and alternatively or additionally any other example herein, wherein a right-angle indicator legend provided to facilitate placement of the electric power industry structure monitor is a registration feature printed, etched, painted, molded, engraved, adhered, or otherwise present in or on the distribution transformer vessel.

Example C-51 may include the subject matter of Example C-1 to C-50, and alternatively or additionally any other example herein, wherein a right-angle indicator legend is provided to facilitate placement of the electric power industry structure monitor in a substantially vertical orientation relative to the distribution transformer vessel.

Example C-52 may include the subject matter of Example C-1 to C-51, and alternatively or additionally any other example herein, wherein the electric power industry structure monitor includes a first sensor module having at least one infrared (IR) image sensor.

Example C-53 may include the subject matter of Example C-1 to C-52, and alternatively or additionally any other example herein, wherein the electric power industry structure monitor includes a first sensor module having at least one infrared (IR) image sensor, electronic circuitry, and operative software.

Example C-54 may include the subject matter of Example C-1 to C-53, and alternatively or additionally any other example herein, wherein the electric power industry structure monitor includes a first sensor module having at least one infrared (IR) image sensor, electronic circuitry, and operative software, the at least one IR image sensor having an IR field of view that is generally aimed at a portion of the wall of the distribution transformer vessel.

Example C-55 may include the subject matter of Example C-1 to C-54, and alternatively or additionally any other example herein, wherein the electric power industry structure monitor includes a first sensor module having at least one infrared (IR) image sensor, electronic circuitry, and operative software, the at least one IR image sensor having an IR field of view cone that is generally aimed at a portion of the wall of the distribution transformer vessel, the IR field of view cone formed to window a determined level of the non-conductive medium.

Example C-56 may include the subject matter of Example C-1 to C-55, and alternatively or additionally any other example herein, wherein an IR image sensor may be deployed to detect the determined level of the non-conductive medium based on a difference in temperature of the non-conductive medium and the void or space in the distribution transformer vessel above the non-conductive medium.

Example C-57 may include the subject matter of Example C-1 to C-56, and alternatively or additionally any other example herein, wherein an IR image sensor may be deployed to detect the determined level of the non-conductive medium based on a difference in temperature of the non-conductive medium and the void or space in the distribution transformer vessel above the non-conductive medium.

Example C-58 may include the subject matter of Example C-1 to C-57, and alternatively or additionally any other example herein, wherein an IR image sensor may be deployed to detect the determined level of the non-conductive medium based on a difference in temperature of the non-conductive medium and the void or space in the distribution transformer vessel above the non-conductive medium, wherein when the IR image sensor is operated, a plurality of the energy levels within an IR field of view cone are captured, the different energy levels analyzed by the processing circuit to identify the determined level of the non-conductive medium 154.

Example C-59 may include the subject matter of Example C-1 to C-58, and alternatively or additionally any other example herein, wherein the processing circuit is arranged to execute an algorithm to analyze the IR image data generated by an IR image sensor.

Example C-60 may include the subject matter of Example C-1 to C-59, and alternatively or additionally any other example herein, wherein the processing circuit is arranged to execute a spectra algorithm, a black-and-white algorithm, or iron algorithm to analyze the IR image data generated by an IR image sensor.

Example C-61 may include the subject matter of Example C-1 to C-60, and alternatively or additionally any other example herein, wherein the processing circuit is arranged to execute an algorithm to analyze the IR image data generated by an IR image sensor, the algorithm arranged to represent various points on a wall of the distribution transformer vessel as an array or “window.”

Example C-62 may include the subject matter of Example C-1 to C-61, and alternatively or additionally any other example herein, wherein the processing circuit is arranged to execute an algorithm to analyze the IR image data generated by an IR image sensor, the IR image data representing energy levels captured at various points on a wall of the distribution transformer vessel, and the algorithm further arranged to identify a liquid/non-liquid boundary at a surface of non-conductive medium inside the distribution transformer vessel.

Example C-63 may include the subject matter of Example C-1 to C-62, and alternatively or additionally any other example herein, wherein the processing circuit is arranged to execute an algorithm to analyze the IR image data generated by an IR image sensor, the IR image data representing energy levels captured at various points on a wall of the distribution transformer vessel, and the algorithm further arranged to identify and track over time a liquid/non-liquid boundary at a surface of non-conductive medium inside the distribution transformer vessel, the temperature data readings captured and stored over seconds, minutes, hours, days, weeks, months, years, or any suitable length of time.

Example C-64 may include the subject matter of Example C-1 to C-63, and alternatively or additionally any other example herein, wherein a determined level of non-conductive medium in a plurality of distribution transformer vessels is tracked and stored in a repository, and wherein the accumulation of temperature data for a plurality of distribution transformer vessels is used to adjust one or more determined thresholds monitored by at least one electric power industry structure monitor, such analysis used to more efficiently determine when alerts are triggered, and such analysis additionally or alternatively used to determine action to take when certain determined thresholds are crossed.

Example C-65 may include the subject matter of Example C-1 to C-64, and alternatively or additionally any other example herein, wherein the sensor includes a plurality micro electromechanical systems (MEMS) devices such as microphones arranged to capture data in a respective plurality of data collection areas, a first data collection area representing a first volume of a distribution transformer vessel that is substantially above a determined level of non-conductive medium and a second data collection area representing a second volume of the distribution transformer vessel that is substantially below the determined level of nonconductive medium; wherein the processing circuit is arranged to produce a signature that represents the determined level of the nonconductive medium within the distribution transformer vessel. As the signature changes, conclusions about the determined level may be deduced.

Example C-66 may include the subject matter of Example C-1 to C-65, and alternatively or additionally any other example herein, wherein the sensor includes a plurality micro electromechanical systems (MEMS) devices such as microphones arranged to capture data in a respective plurality of data collection areas, a first data collection area representing a first volume of a distribution transformer vessel that is substantially above a determined level of non-conductive medium and a second data collection area representing a second volume of the distribution transformer vessel that is substantially below the determined level of nonconductive medium; wherein the processing circuit is arranged to produce a signature that represents the determined level of the nonconductive medium within the distribution transformer vessel; and wherein the processing circuit is further arranged to infer conclusions about the determined level based on changes to the signature over time.

Example D-1 is an electric power industry structure monitor, comprising: a housing arranged for positioning on an electric power industry structure; a sensor arranged in the housing, the sensor positioned to generate digital data associated with at least one environmental condition that exists proximal to the electric power industry structure monitor; and a processing circuit arranged to determine from the generated digital data that the at least one environmental condition has crossed a threshold, wherein the electric power industry structure is a distribution power pole, the distribution power pole is arranged to support electric power transmission lines that carry electricity having a voltage of 600 volts (600V) or less, and the electric power industry structure monitor is arranged to monitor a tilt of the distribution power pole.

Example D-2 may include the subject matter of Example D-1, and alternatively or additionally any other example herein, wherein the electric power industry structure is high-power pole, a distribution power pole, a street light pole, a wind power generation tower, a sign pole, an antenna, a flag pole, a mast, or some other kind of structure arranged as a structure that supports one or more physical things at a determined height above the ground (AGL).

Example D-3 may include the subject matter of Example D-1, and alternatively or additionally any other example herein, wherein the electric power industry structure rises at least 10 feet AGL, 20 feet AGL, 50 feet AGL, 100 feet AGL, 125 feet AGL, or 200 feet.

Example D-4 may include the subject matter of Example D-1 to D-3, and alternatively or additionally any other example herein, wherein the housing is between about between about five inches (5 in.) and about twenty-five inches (25 in.) long and between about one-half inch (0.5 in.) and about five inches (5 in.) wide.

Example D-5 may include the subject matter of Example D-1 to D-4, and alternatively or additionally any other example herein, wherein the housing is at least one over-molded solar cell integrated therein.

Example D-6 may include the subject matter of Example D-1 to D-5, and alternatively or additionally any other example herein, wherein the housing is at least two over-molded solar cells integrated therein.

Example D-7 may include the subject matter of Example D-1 to D-6, and alternatively or additionally any other example herein, further comprising a mounting means, wherein examples of the mounting means or portions thereof include a plurality of grooves, an aperture, an adhesive, a bracket, a screw, a flexible band, and a clamp.

Example D-8 may include the subject matter of Example D-1 to D-7, and alternatively or additionally any other example herein, wherein a housing of the electric power industry structure monitor includes a bottom portion having a shaped profile, wherein the shaped profile has a partial, simple cylindrical radius arranged to cooperate with a corresponding cylindrical radius of the electric power industry structure, and wherein the shaped profile is a partial, complex truncated frustum arranged to cooperate with a different profile of a particular power pole.

Example D-9 may include the subject matter of Example D-1 to D-8, and alternatively or additionally any other example herein, further comprising a mounting mechanism to secure the electric power industry structure monitor to the electric power industry structure, wherein the mounting mechanism includes at least one of an adhesive, a glue, a paste, a tar, an epoxy, or some other form of malleable adhesive.

Example D-10 may include the subject matter of Example D-1 to D-9, and alternatively or additionally any other example herein, further comprising a mounting mechanism to secure the electric power industry structure monitor to the electric power industry structure, wherein the mounting mechanism includes at least one of a bracket, a screw, a frame, a magnet, a hook and loop material, a nut and bolt, a mounting post an aperture, or some other mounting mechanism.

Example D-11 may include the subject matter of Example D-1 to D-10, and alternatively or additionally any other example herein, wherein the housing includes at least a top side and a bottom side, and in some cases, the top side of the second embodiment of an electric power industry structure monitor is arranged with a particular profile, which profile may be partially rounded, planar, partially triangular, partially hexagonal, partially octagonal, or the profile may have some other suitable shape.

Example D-12 may include the subject matter of Example D-1 to D-11, and alternatively or additionally any other example herein, wherein the housing includes at least a top side and a bottom side, and in some cases, the top side is arranged with a solar power generation means.

Example D-13 may include the subject matter of Example D-1 to D-12, and alternatively or additionally any other example herein, wherein the housing includes at least a top side and a bottom side, and in some cases, the top side is arranged with one or more solar cells arranged to convert light into electricity, and wherein electricity generated by the one or more solar cells is used to: power the electric power industry structure monitor, power some other device, or charge a power storage means (e.g., a capacitor, a battery, or the like).

Example D-14 may include the subject matter of Example D-1 to D-13, and alternatively or additionally any other example herein, wherein the housing includes at least a top side and a bottom side, and in some cases, the top side is arranged with one or more solar cells flexibly arranged to bend over and cover a printed circuit board or other electronic circuitry provided therebelow.

Example D-15 may include the subject matter of Example D-1 to D-14, and alternatively or additionally any other example herein, further comprising at least one energy harvesting means arranged to generate power from light, generate power inductively, generate power from proximate available heat, generate power from a temperature differential, or generate power from vibration.

Example D-16 may include the subject matter of Example D-1 to D-15, and alternatively or additionally any other example herein, further comprising at least one energy harvesting inductive circuit, at least one energy harvesting photo-electric circuit, or at least one energy harvesting accelerometer-based circuit.

Example D-17 may include the subject matter of Example D-1 to D-16, and alternatively or additionally any other example herein, wherein the electric power industry structure monitor is not physically, electrically wired to any external power source

Example D-18 may include the subject matter of Example D-1 to D-17, and alternatively or additionally any other example herein, further comprising at least one energy harvesting circuit arranged to power the electric power industry structure monitor, wherein once deployed, the electric power industry structure monitor is not physically, electrically wired to any external power source.

Example D-19 may include the subject matter of Example D-1 to D-18, and alternatively or additionally any other example herein, wherein the at least one energy harvesting circuit includes at least one solar cell and at least one rechargeable storage circuit electrically coupled to the at least one solar cell.

Example D-20 may include the subject matter of Example D-1 to D-19, and alternatively or additionally any other example herein, further comprising a connection port, the connection port arranged to physically, electrically, and communicatively receive at least one of a camera, an environmental sensor, a microphone, a speaker, a water detection sensor, a radio module, and an infrared distance sensor.

Example D-21 may include the subject matter of Example D-1 to D-20, and alternatively or additionally any other example herein, further comprising electronic control circuitry arranged to determine a tilt of the electric power industry structure; electronic communication circuitry arranged to communicate tilt information from the electric power industry structure monitor; at least one antenna coupled to the electronic communication circuitry; at least one rechargeable energy storage device; and at least one energy harvesting circuit electrically coupled to the at least one rechargeable energy storage device, wherein power generated by the at least one energy harvesting circuit is arranged to power the electric power industry structure monitor, and wherein once deployed, the electric power industry structure monitor is not physically, electrically wired to any external power source

Example D-22 may include the subject matter of Example D-1 to D-21, and alternatively or additionally any other example herein, further comprising at least one accelerometer circuit; a processor; and memory coupled to the processor, said memory storing instructions that, when executed by the processor, cause the electric power industry structure monitor to: produce shock information based on data generated by the at least one accelerometer circuit; produce the tilt information based on data generated by the at least one accelerometer circuit; and direct the electronic communication circuitry to communicate at least one of the shock information and the tilt information to a remote computing device.

Example D-23 may include the subject matter of Example D-1 to D-22, and alternatively or additionally any other example herein, further comprising at least one thermometer circuit arranged to generate temperature measurement data, the least one thermometer circuit communicatively coupled to the processor.

Example D-24 may include the subject matter of Example D-1 to D-23, and alternatively or additionally any other example herein, further comprising at least one energy storage device, such as a battery or a super-capacitor circuit.

Example D-25 may include the subject matter of Example D-1 to D-24, and alternatively or additionally any other example herein, wherein a battery is arranged to provide 25,000 milliamp-hours (mAH) of charge at five volts (5V).

Example D-26 may include the subject matter of Example D-1 to D-25, and alternatively or additionally any other example herein, wherein an energy storage device such as a battery is arranged to power the electric power industry structure monitor for five years under a determined set of operating conditions, such as reporting a status one time per day, four times per day, or some other periodic number of times per day.

Example D-27 may include the subject matter of Example D-1 to D-26, and alternatively or additionally any other example herein, wherein an energy storage device such as a battery is arranged to power the electric power industry structure monitor for ten years under a determined set of operating conditions, such as reporting a status one time per day, four times per day, or some other periodic number of times per day.

Example D-28 may include the subject matter of Example D-1 to D-27, and alternatively or additionally any other example herein, further comprising at least one thermometer circuit arranged to generate temperature measurement data, the least one thermometer circuit communicatively coupled to the processor, wherein the memory further stores instructions that, when executed by the processor, cause the electric power industry structure monitor to direct communication of at least some of the temperature measurement data to the remote computing device.

Example D-29 may include the subject matter of Example D-1 to D-28, and alternatively or additionally any other example herein, wherein the processor is arranged to periodically wake up and take environmental readings (e.g., temperature, humidity, air pressure, pollen counts, particulate counts, and the like) using its onboard or otherwise communicatively coupled sensors, and wherein the collected data may be stored, analyzed, processed, or the like, and wherein the collected data may be communicated to a remote computing device, and wherein in at least some cases, data is collected several times in a day, but only communicated once per day, and wherein in at least some cases, the data communication rate and other settings of the electric power industry structure monitor are be user selectable.

Example D-30 may include the subject matter of Example D-1 to D-29, and alternatively or additionally any other example herein, further comprising at least one multi-axis accelerometer circuit arranged to detect motion due to tilt, sway, deflection, shock, falling, or displacement caused by at least one of wind, earthquake, structural impact, flooding, age-related failure, and vandalism.

Example D-31 may include the subject matter of Example D-1 to D-30, and alternatively or additionally any other example herein, wherein a calibration feature is executed so that accelerometer data is arranged to correspond to a known three-dimensional attitude of the power pole, wherein in some cases, the calibration feature is only executed after the electric power industry structure monitor is first powered up after installation on a power pole, and in some cases, the calibration feature is executed only after the electric power industry structure monitor executes a hard reset function.

Example D-32 may include the subject matter of Example D-1 to D-31, and alternatively or additionally any other example herein, wherein due to the functionality of a calibration feature, the electric power industry structure monitor may not need to be oriented in a perfectly normal orientation to the ground; for example, in some cases, the orientation does not even need to be mounted substantially vertically with respect to the ground; wherein some embodiments of the electric power industry structure monitor permit installation (e.g., mounting of the monitor to a pole or other structure) within five degrees (5°), within ten degrees (10°), within 30 degrees (30°) (i.e., substantially normal), within forty-five degrees (45°), or within some other offset from normal to the ground.

Example D-33 may include the subject matter of Example D-1 to D-32, and alternatively or additionally any other example herein, wherein memory further stores instructions of a calibration routine that, when executed by the processor, cause the electric power industry structure monitor to compensate for a non-vertical positioning of the electric power industry structure monitor on the distribution power pole.

Example D-34 may include the subject matter of Example D-1 to D-33, and alternatively or additionally any other example herein, wherein a location routine is executed in some cases so that GPS data is collected to determine a location of the power pole that the electric power industry structure monitor is attached to.

Example D-35 may include the subject matter of Example D-1 to D-34, and alternatively or additionally any other example herein, wherein a only limited number of GPS position readings (e.g., 3 readings, five readings, ten readings, or another number of readings) are determined after the electric power industry structure monitor is booted.

Example D-36 may include the subject matter of Example D-1 to D-35, and alternatively or additionally any other example herein, wherein after the electric power industry structure monitor is booted, and after a first location is determined by the location circuitry, the location circuitry is decommissioned from service (e.g., placed in a sleep, standby, or other low-power mode, removed from a power source, or the like).

Example D-37 may include the subject matter of Example D-1 to D-36, and alternatively or additionally any other example herein, wherein a first location of the electric power industry structure monitor is determined only after performing a hard reset on the electric power industry structure monitor.

Example E-1 is an electric power industry structure monitor, comprising: a housing arranged for positioning on an electric power industry structure; a sensor arranged in the housing, the sensor positioned to generate digital data associated with at least one environmental condition that exists proximal to the electric power industry structure monitor; and a processing circuit arranged to determine from the generated digital data that the at least one environmental condition has crossed a threshold, wherein the electric power industry structure is a high-voltage power pole, the high-voltage power pole arranged to support electric power transmission lines that carry electricity having a voltage of ten thousand volts (10 kV) or more.

Example E-2 may include the subject matter of Example E-1, and alternatively or additionally any other example herein, wherein the electric power industry structure monitor is arranged for mounting at between about 50 and 200 feet above ground level (AGL).

Example E-3 may include the subject matter of Example E-1 to E-2, and alternatively or additionally any other example herein, wherein the electric power industry structure monitor is a self-powering device further comprising one or more solar cells, one or more power induction coils, or one or more thermoelectric modules arranged to generate power sufficient to operate the electric power industry structure monitor.

Example E-4 may include the subject matter of Example E-1 to E-3, and alternatively or additionally any other example herein, wherein the electric power industry structure monitor is electromechanically isolated from a fixed power source.

Example E-5 may include the subject matter of Example E-1 to E-4, and alternatively or additionally any other example herein, wherein the electric power industry structure monitor includes a fixed or configurable reporting and alert package that includes threshold compliance measurements for tilt and vibration detection, photosensor anomaly detection, power management, battery voltage detection, and solar cell health detection, and wherein the electric power industry structure monitor optionally includes a deployable data integrator software package that facilitates encoding and processing of operational status data for retrieval at an asset management database system deployed on or via a remote computing server.

Example E-6 may include the subject matter of Example E-1 to E-5, and alternatively or additionally any other example herein, wherein the electric power industry structure monitor includes analytical data that permits a remote map display of electric power industry structure monitor nodes at their GPS coordinates, asset tracking/client authentication, and parameter filtering of device alerts, and wherein the electric power industry structure monitor optionally captures accurate (e.g., within two meters; within three meters, within 10 meters, or within some other level of accuracy) GPS telemetry data that permits accurate tracking and identification of damaged or improperly inclined power poles.

Example E-7 may include the subject matter of Example E-1 to E-6, and alternatively or additionally any other example herein, wherein the electric power industry structure monitor is arranged to capture vibration information, tilt information, and water saturation information associated with an area under the high-voltage power pole.

Example E-8 may include the subject matter of Example E-1 to E-7, and alternatively or additionally any other example herein, wherein the electric power industry structure monitor is arranged to capture vandalism information, gunshot detection information, weather information, and environmental condition information proximate the high-voltage power pole.

Example F-1 is a system comprising two or more electric power industry structure monitors and at least one remote computing device, each electric power industry structure monitor arranged as a remotely configurable, solar-powered pole tilt sensor that provides electrical fixture tilt and vibration alerts, real-time status critical operations monitoring, and over-the-air (OTA) firmware upgrades.

Example F-2 may include the subject matter of Example F-1, and alternatively or additionally any other example herein, wherein each electric power industry structure monitor is mounted to a power poles having high-voltage or distribution power voltage power lines carrying at least ten thousand volts (10 kV).

Example F-3 may include the subject matter of Example F-1 to F-2, and alternatively or additionally any other example herein, wherein each electric power industry structure monitor is mounted to a power poles having high-voltage or distribution power voltage power lines carrying less than six hundred volts (600V).

The various embodiments described above can be combined to provide further embodiments. Aspects of the embodiments can be modified, if necessary to employ concepts of the various patents, application and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. An electric power industry structure monitor, comprising:
a housing arranged for positioning on an electric power industry structure;
a sensor arranged in the housing, the sensor positioned to generate digital data associated with at least one environmental condition that exists proximal to the electric power industry structure monitor; and
a processing circuit arranged to determine from the generated digital data that the at least one environmental condition has crossed a threshold.

2. The electric power industry structure monitor of claim 1 wherein the electric power industry structure is a distribution transformer, and wherein the electric power industry structure monitor is arranged to monitor pressure within a vessel that contains the distribution transformer.

3. The electric power industry structure monitor of claim 2 wherein the housing is formed from an ultraviolet (UV) radiation resistant material having an operating range that includes 140 degrees Fahrenheit.

4. The electric power industry structure monitor of claim 2 wherein the housing includes a coating arranged as a protective barrier to protect against animal damage, insect damage, and vandalism.

5. The electric power industry structure monitor of claim 2 wherein the sensor includes at least one infrared (IR) image sensor having an IR field of view cone arranged to be aimed at a portion of a wall of the distribution transformer vessel when the electric power industry structure monitor is deployed, the IR field of view cone formed to window a determined level of non-conductive medium contained in the distribution transformer vessel.

6. The electric power industry structure monitor of claim 2 wherein the sensor is an infrared (IR) image sensor deployed to detect a determined level of non-conductive medium in the distribution transformer vessel based on a difference in temperature of the non-conductive medium and temperature of a void in the distribution transformer vessel above the non-conductive medium.

7. The electric power industry structure monitor of claim 2 wherein the sensor includes a plurality micro electromechanical systems (MEMS) microphones arranged to capture data in a respective plurality of data collection areas, a first data collection area representing a first volume of the distribution transformer vessel that is substantially above a determined level of non-conductive medium in the distribution transformer vessel, and a second data collection area representing a second volume of the distribution transformer vessel that is substantially below the determined level of nonconductive medium, and wherein the processing circuit is arranged to produce a signature that represents a determined level of the nonconductive medium within the distribution transformer vessel.

8. The electric power industry structure monitor of claim 1 wherein the electric power industry structure is a distribution power pole, the distribution power pole is arranged to support electric power transmission lines that carry electricity having a voltage of 600 volts (600V) or less, and the electric power industry structure monitor is arranged to monitor a tilt of the distribution power pole.

9. The electric power industry structure monitor of claim 8, further comprising:
at least one energy harvesting circuit arranged to power the electric power industry structure monitor, wherein once deployed, the electric power industry structure monitor is not physically, electrically wired to any external power source.

10. The electric power industry structure monitor of claim 9 wherein the at least one energy harvesting circuit includes at least one solar cell and at least one rechargeable storage circuit electrically coupled to the at least one solar cell.

11. The electric power industry structure monitor of claim 8, further comprising:
electronic control circuitry arranged to determine a tilt of the electric power industry structure;
electronic communication circuitry arranged to communicate tilt information from the electric power industry structure monitor;
at least one antenna coupled to the electronic communication circuitry;
at least one rechargeable energy storage device; and
at least one energy harvesting circuit electrically coupled to the at least one rechargeable energy storage device, wherein power generated by the at least one energy harvesting circuit is arranged to power the electric power industry structure monitor, and wherein once deployed, the electric power industry structure monitor is not physically, electrically wired to any external power source.

12. The electric power industry structure monitor of claim 11, wherein the electronic control circuitry further comprises:
at least one accelerometer circuit;
a processor; and
memory coupled to the processor, said memory storing instructions that, when executed by the processor, cause the electric power industry structure monitor to:
produce shock information based on data generated by the at least one accelerometer circuit;
produce the tilt information based on data generated by the at least one accelerometer circuit; and
direct the electronic communication circuitry to communicate at least one of the shock information and the tilt information to a remote computing device.

13. The electric power industry structure monitor of claim 12, wherein the electronic control circuitry further comprises:
at least one thermometer circuit arranged to generate temperature measurement data, the least one thermometer circuit communicatively coupled to the processor, wherein the memory further stores instructions that, when executed by the processor, cause the electric power industry structure monitor to:
direct communication of at least some of the temperature measurement data to the remote computing device.

14. The electric power industry structure monitor of claim 12 wherein the at least one accelerometer circuit includes at least one 3-axis accelerometer circuit arranged to detect motion due to tilt, sway, deflection, shock, falling, or displacement caused by at least one of wind, earthquake, structural impact, flooding, age-related failure, or vandalism.

15. The electric power industry structure monitor of claim 12, wherein the memory further stores instructions of a calibration routine that, when executed by the processor, cause the electric power industry structure monitor to:
compensate for a non-vertical positioning of the electric power industry structure monitor on the distribution power pole.

16. The electric power industry structure monitor of claim 1 wherein the electric power industry structure is a high-voltage power pole, the high-voltage power pole arranged to support electric power transmission lines that carry electricity having a voltage of ten thousand volts (10 kV) or more.

17. The electric power industry structure monitor of claim 16 wherein the electric power industry structure is arranged for mounting at least 50 feet above ground level.

18. The electric power industry structure monitor of claim 16, wherein the electric power industry structure monitor is a self-powering device further comprising:
at least one harvested wireless power source, the at least one harvested wireless power source including one or more solar cells, one or more power induction coils, or one or more thermoelectric modules arranged to generate power sufficient to operate circuitry of the electric power industry structure monitor.

19. The electric power industry structure monitor of claim 16 wherein the electric power industry structure monitor is arranged to capture vibration information, tilt information, and water saturation information associated with an area under the high-voltage power pole.

20. The electric power industry structure monitor of claim 16 wherein the electric power industry structure monitor is arranged to capture vandalism information, gunshot detection information, weather information, and environmental condition information proximate the high-voltage power pole.
